(19) United States
(12) Patent Application Publication
(10) Pub. No.: US 2018/0248145 A1
(43) Pub. Date: Aug. 30, 2018

(54) ORGANIC LIGHT-EMITTING DEVICE

(71) Applicant: Samsung Electronics Co., Ltd., Suwon-si (KR)

(72) Inventors: Sooghang IHN, Hwaseong-si (KR); Wonjoon SON, Yongin-si (KR); Hosuk KANG, Suwon-si (KR); Myungsun SIM, Suwon-si (KR); Sunghan KIM, Seongnam-si (KR); Masaki NUMATA, Hwaseong-si (KR); Hiroshi MIYAZAKI, Hwaseong-si (KR); Saeyoun LEE, Suwon-si (KR); Soonok JEON, Suwon-si (KR)

(21) Appl. No.: 15/908,150

(22) Filed: Feb. 28, 2018

(30) Foreign Application Priority Data
Feb. 28, 2017 (KR) 10-2017-0026476
Feb. 26, 2018 (KR) 10-2018-0022853

(51) Int. Cl. H01L 51/50; H01L 51/52; H01L 51/56; H01L 51/00; C09K 11/06

(52) U.S. Cl. CPC H01L 51/508; H01L 51/5203; H01L 51/5056; H01L 51/5092; H01L 51/5012; H01L 51/56; C09K 2211/1033; H01L 51/0073; C09K 11/06; C09K 2211/1077; C09K 2211/1051; C09K 2211/1037; H01L 51/0072

(57) ABSTRACT

An organic light-emitting device including a first electrode, a second electrode facing the first electrode, and an organic layer disposed between the first electrode and the second electrode, wherein the organic layer includes an emission layer, wherein the emission layer includes a thermally activated delayed fluorescence (TADF) emitter and a host and the TADF emitter is different from the host, and wherein the TDAF emitter is capable of satisfying certain conditions disclosed in the specification.

### CROSS-REFERENCE TO RELATED APPLICATION

This application claims priority to Korean Patent Application Nos. 10-2017-0026476, filed on Feb. 28, 2017 and 10-2018-0022853, filed on Feb. 26, 2018, in the Korean Intellectual Property Office, and all the benefits accruing therefrom under 35 C.F.R. § 119, the content of which is incorporated herein in its entirety by reference.

### BACKGROUND

### 1. Field

One or more embodiments relate to an organic light-emitting device.

### 2. Description of the Related Art

Organic light-emitting devices (OLEDs) are self-emission devices that produce full-color images, and also have wide viewing angles, high contrast ratios, short response times, as well as excellent characteristics in terms of brightness, driving voltage, and response speed.

An example of such organic light-emitting devices may include an anode, a cathode, and an organic layer that is disposed between the anode and the cathode, wherein the organic layer includes an emission layer. A hole transport region may be disposed between the anode and the emission layer, and an electron transport region may be disposed between the emission layer and the cathode. Holes provided from the anode may move toward the emission layer through the hole transport region, and electrons provided from the cathode may move toward the emission layer through the electron transport region. Carriers, such as holes and electrons, recombine in an emission layer to produce excitons. These excitons transit from an excited state to a ground state, thereby generating light.

Various types of organic light emitting devices are known. However, there still remains a need in OLEDs having low driving voltage, high efficiency, high brightness, and long lifespan.

### SUMMARY

One or more embodiments include an organic light-emitting device that includes a host and a dopant satisfying a certain condition and has excellent characteristics in terms of external quantum efficiency and roll-off ratio.

Additional aspects will be set forth in part in the description which follows and, in part, will be apparent from the description, or may be learned by practice of the presented embodiments.

According to one or more embodiments, an organic light-emitting device includes:
a first electrode;
a second electrode facing the first electrode; and
an organic layer that is disposed between the first electrode and the second
electrode, wherein the organic layer includes an emission layer,
wherein the emission layer includes a thermally activated delayed fluorescence (TADF) emitter and a host and the TADF emitter is different from the host, and
the TADF emitter satisfies Condition 1-1 or Condition 1-2:
Condition 1-1
a condition that n1 is one, and
Condition 1-2
a condition that, when n1 is two or more, (I₁/I₂)×100(%) is less than 110%.

In Condition 1-1 and Condition 1-2,
I₁ (arbitrary units) is emission intensity at the shortest peak emission wavelength in a photoluminescence spectrum 1,
1) when n2 is one, I₂ (arbitrary units) is emission intensity at the same emission wavelength as the shortest peak emission wavelength of the photoluminescence spectrum 1 in the photoluminescence spectrum 2, and 2) when n2 is two or more, I₂ (arbitrary units) is emission intensity at the shortest peak emission wavelength in a photoluminescence spectrum 2,
the photoluminescence spectrum 1 is a photoluminescence spectrum of a film 1 that is doped with 15 percent by volume of the TADF emitter in a matrix with the host included in the emission layer and has a thickness of 50 nanometers, and
the photoluminescence spectrum 2 is a photoluminescence spectrum of a film 2 that is doped with 15 percent by volume of the TADF emitter in a matrix with DPEPO and has a thickness of 50 nanometers:

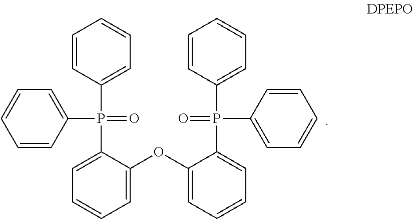 [SMILES: O=P(c1ccccc1)(c1ccccc1)c1ccccc1Oc1ccccc1P(=O)(c1ccccc1)c1ccccc1]

n1 is the number of distinguishable emission peaks in the photoluminescence spectrum 1, and n2 is the number of distinguishable emission peaks in the photoluminescence spectrum 2.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view of an organic light-emitting device according to an embodiment;

FIGS. 2 to 7 are graphs of intensity (arbitrary units, a.u.) versus wavelength (nanometers, nm), which illustrate photoluminescence spectra of film 1, 2, 3, 4, A, and B;

FIGS. 8 to 13 are tables showing attachment-detachment overlap densities of rotamers (10x°) of Compounds 1, 2, 3, 4, A, and B;

FIG. 14 is a graph showing rotational conformational energy (electron volts, eV), CTosc (electron volts, eV), LEosc (electron volts, eV), a charge transfer state (CT) energy level (electron volts, eV), and a locally excited state (LE) energy level (electron volts, eV) with respect to each rotamer (10x°) of Compound 1;

FIG. 15 is a graph showing rotational conformational energy (electron volts, eV), CTosc (electron volts, eV), LEosc (electron volts, eV), a CT energy level (electron volts, eV), and an LE energy level (electron volts, eV) with respect to each rotamer (10x°) of Compound 2;

FIG. 16 is a graph showing rotational conformational energy (electron volts, eV), CTosc (electron volts, eV), LEosc (electron volts, eV), a CT energy level (electron volts, eV), and an LE energy level (electron volts, eV) with respect to each rotamer (10x°) of Compound 4;

FIG. 17 is a graph showing rotational conformational energy (electron volts, eV), CTosc (electron volts, eV), LEosc (electron volts, eV), a CT energy level (electron volts, eV), and an LE energy level (electron volts, eV) with respect to each rotamer (10x°) of Compound A; and

FIG. 18 is a graph showing rotational conformational energy (electron volts, eV), CTosc (electron volts, eV), LEosc (electron volts, eV), a CT energy level (electron volts, eV), and an LE energy level (electron volts, eV) with respect to each rotamer (10x°) of Compound B.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

In an embodiment, an organic light-emitting device is provided. The organic light-emitting device, according to an embodiment, may include:
a first electrode;
a second electrode facing the first electrode; and
an organic layer that is disposed between the first electrode and the second electrode, wherein the organic layer includes an emission layer,
wherein the emission layer includes a thermally activated delayed fluorescence (TADF) emitter and a host and the TADF emitter is different from the host, provided that the TADF emitter satisfies Condition 1-1 or Condition 1-2:
Condition 1-1
a condition that n1 is one, and
Condition 1-2
a condition that, when n1 is two or more, (I₁/I₂)×100(%) is less than 110%.

In Condition 1-1 and Condition 1-2,
I₁ (a.u.) is emission intensity at the shortest peak emission wavelength in a photoluminescence spectrum 1, wherein “a.u.” denotes “arbitrary units”,
1) when n2 is one, I₂ (a.u.) is emission intensity at the same emission wavelength as the shortest peak emission wavelength of the photoluminescence spectrum 1 in the photoluminescence spectrum 2, and 2) when n2 is two or more, I₂ (a.u.) is emission intensity at the shortest peak emission wavelength in a photoluminescence spectrum 2,
the photoluminescence spectrum 1 is a photoluminescence spectrum of a film 1 that is doped with 15 percent by volume (vol %) of the TADF emitter in a matrix with the host included in the emission layer and has a thickness of 50 nanometers (nm), and
the photoluminescence spectrum 2 is a photoluminescence spectrum of a film 2 that is doped with 15 vol % of the TADF emitter in a matrix with DPEPO and has a thickness of 50 nm:

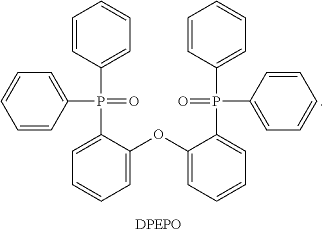 [SMILES: O=P(c1ccccc1)(c1ccccc1)c1ccccc1Oc1ccccc1P(=O)(c1ccccc1)c1ccccc1]

n1 is the number of distinguishable emission peaks in the photoluminescence spectrum 1, and n2 is the number of distinguishable emission peaks in the photoluminescence spectrum 2.

For example, the I₁ and the I₂ may have the same unit.

For example, the host may not include DPEPO.

When the TADF emitter satisfies Condition 1-1 or Condition 1-2, the TADF emitter may have excellent delayed fluorescence characteristics without severe dual fluorescence.

In an embodiment, the TADF emitter may be a compound represented by Formula 1:

R₁-(D₂)_{d1}-D₁-(L₁)ₐ₁-A₁. Formula 1

In Formula 1,
L₁ may be selected from:
a single bond, a cyclopentane group, a cyclohexane group, a cycloheptane group, a cyclooctane group, a cyclopentene group, a cyclohexene group, a cycloheptene group, a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an iso-indole group, an indole group, an indazole group, a purine group, a quinoline group, an isoquinoline group, a benzoquinoline group, a quinoxaline group, a quinazoline group, a cinnoline group, a phenanthroline group, a benzimidazole group, a benzofuran group, a benzothiophene group, a benzoxazole group, an isobenzoxazole group, a triazole group, a tetrazole group, an oxadiazole group, a triazine group, a dibenzofuran group, a dibenzothiophene group, a benzocarbazole group, a dibenzocarbazole group, an imidazopyridine group, an imidazopyrimidine group, an azaindole group, an azaindene group, an azabenzofuran group, an azabenzothiophene group, an azacarbazole group, an azafluorene group, an azadibenzofuran group, and an azadibenzothiophene group; and
a cyclopentane group, a cyclohexane group, a cycloheptane group, a cyclooctane group, a cyclopentene group, a cyclohexene group, a cycloheptene group, a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an iso-indole group, an indole group, an indazole group, a purine group, a quinoline group, an isoquinoline group, a benzoquinoline group, a quinoxaline group, a quinazoline group, a cinnoline group, a phenanthroline group, a benzimidazole group, a benzofuran group, a benzothiophene group, a benzoxazole group, an isobenzoxazole group, a triazole group, a tetrazole group, an oxadiazole group, a triazine group, a dibenzofuran group, a dibenzothiophene group, a benzocarbazole group, a dibenzocarbazole group, an imidazopyridine group, an imidazopyrimidine group, an azaindole group, an azaindene group, an azabenzofuran group, an azabenzothiophene group, an azacarbazole group, an azafluorene group, an azadibenzofuran group, and an azadibenzothiophene group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a tri(C₁-C₂₀ alkyl)phenyl group, a (C₆-C₂₀ aryl)phenyl group, a di(C₆-C₂₀ aryl)phenyl group, a tri(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group,
a1 may be an integer from 1 to 5,
D₁ and D₂ may each be an electron donor group,
d1 may be an integer from 0 to 5,
A₁ may be an electron acceptor group, and
R₁ may be selected from:
hydrogen, deuterium, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, and a π electron-depleted nitrogen-free C₂-C₆₀ heterocyclic group; and
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, and a π electron-depleted nitrogen-free C₂-C₆₀ heterocyclic group, each substituted with at least one selected from deuterium, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a (C₁-C₁₀ alkyl)C₅-C₆₀ carbocyclic group, a di(C₁-C₁₀ alkyl)C₅-C₆₀ carbocyclic group, a (phenyl)C₅-C₆₀ carbocyclic group, a di(phenyl)C₅-C₆₀ carbocyclic group, a (biphenyl)C₅-C₆₀ carbocyclic group, a di(biphenyl)C₅-C₆₀ carbocyclic group, a π electron-depleted nitrogen-free C₂-C₆₀ heterocyclic group, a (C₁-C₁₀ alkyl) π electron-depleted nitrogen-free C₂-C₆₀ heterocyclic group, a di(C₁-C₁₀ alkyl) π electron-depleted nitrogen-free C₂-C₆₀ heterocyclic group, a (phenyl) π electron-depleted nitrogen-free C₂-C₆₀ heterocyclic group, a di(phenyl) π electron-depleted nitrogen-free C₂-C₆₀ heterocyclic group, a (biphenyl) π electron-depleted nitrogen-free C₂-C₆₀ heterocyclic group, and a di(biphenyl) π electron-depleted nitrogen-free C₂-C₆₀ heterocyclic group,
provided that,
i) d1 is an integer from 1 to 5; or
ii) when d1 is zero, A₁ is selected from groups represented by Formulae 3-6(1), 3-10(8), and 3-12(24):

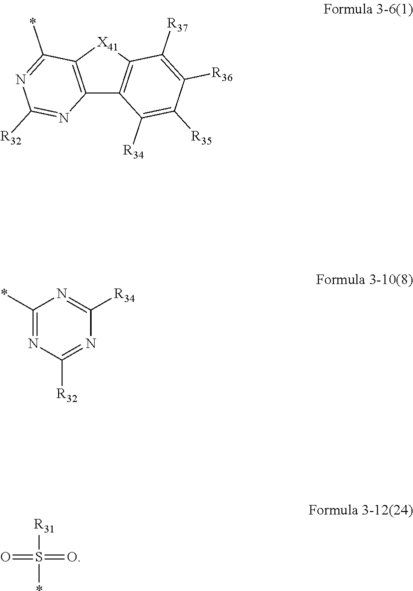

In Formulae 3-6(1), 3-10(8), and 3-12(24),
X₄₁ may be N(R₄₁), C(R₄₂)(R₄₃), O, or S,
R₃₁, R₃₂, R₃₄ to R₃₇, and R₄₁ to R₄₃ may each independently be selected from hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a tri(C₁-C₂₀ alkyl)phenyl group, a (C₆-C₂₀ aryl)phenyl group, a di(C₆-C₂₀ aryl)phenyl group, a tri(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
* indicates a binding site to a neighboring atom.

Formula 1 may be understood by referring to the description provided below.

In an embodiment, the TADF emitter, which is a compound represented by Formula 1, may satisfy Condition 2-1, when assuming that rotamer (0°) is a molecular structure that the TADF emitter has in a gas-phase isolated molecular state, a constant α is an angle between a first plane including D₁ and a second plane including A₁ in the rotamer (0°), rotamer (10x°) is a molecular structure that the TADF emitter has in a state in which the angle between the first plane and the second plane is changed to α+10x°, and x is an integer satisfying −18≤x≤18:
Condition 2-1
a condition that attachment-detachment overlap densities of the rotamer (10x°) are all less than 0.65.

In one or more embodiments, the TADF emitter, which is a compound represented by Formula 1, may satisfy Condition 2-2, when assuming that rotamer (0°) is a molecular structure that the TADF emitter has in a gas-phase isolated molecular state, a constant α is an angle between a first plane including D₁ and a second plane including A₁ in the rotamer (0°), rotamer (10x°) is a molecular structure that the TADF emitter has in a state in which the angle between the first plane and the second plane is changed to α+10x°, and x is an integer satisfying −18≤x≤18:
Condition 2-2
a condition that at least one 10x, of which an attachment-detachment overlap density of the rotamer (10x°) is 0.65 or more, is present, and rotamer (10x°) for all values 10x, of which an attachment-detachment overlap density of rotamer (10x°) is 0.65 or more, have i) rotational conformational energy of 0.15 eV or more, ii) CTosc greater than LEosc, or iii) rotational conformational energy of 0.15 eV or more and CTosc greater than LEosc.

In Condition 2-2, LEosc is oscillator strength in a locally excited state of the corresponding rotamer (10x°), and CTosc is oscillator strength in a charge transfer state of the corresponding rotamer (10x°).

When the TADF emitter satisfies Condition 2-1 or Condition 2-2, light emission from the locally excited state, which reduces delayed fluorescence, is minimized, and thus, the organic light-emitting device may emit excellent delayed fluorescence.

In Condition 2-1 and Condition 2-2,
1) the attachment-detachment overlap density,
2) the rotational conformational energy,
3) LEosc (oscillator strength in the locally excited state of the rotamer (10x°)), and
4) CTosc (oscillator strength in the charge transfer state of the rotamer (10x°))
were evaluated by density functional theory (DFT) and time-dependent DFT (TD-DFT) methods of a Gaussian program in which a structure was optimized at a CAM-B3LYP/6-31G(d,p).

Hereinafter, Formula 1 will be described.

L₁ in Formula 1 may be selected from:
a single bond, a benzene group, a naphthalene group, a fluorene group, a pyridine group, a pyrazine group, a pyrimidine group, a pyridazine group, a quinoline group, an isoquinoline group, a benzoquinoline group, a quinoxaline group, a quinazoline group, and a triazine group; and
a benzene group, a naphthalene group, a fluorene group, a pyridine group, a pyrazine group, a pyrimidine group, a pyridazine group, a quinoline group, an isoquinoline group, a benzoquinoline group, a quinoxaline group, a quinazoline group, and a triazine group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a (C₆-C₂₀ aryl)phenyl group, a di(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
a1 may be 1 or 2.

In one or more embodiments, L₁ in Formula 1 may be selected from:
a single bond, a benzene group, a pyridine group, a pyrimidine group, and a triazine group; and
a benzene group, a pyridine group, a pyrimidine group, and a triazine group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a (C₆-C₂₀ aryl)phenyl group, a di(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
a1 may be 1 or 2, but embodiments of the present disclosure are not limited thereto.

D₁ and D₂ in Formula 1 may each independently be selected from groups represented by Formulae 11-1 to 11-4:

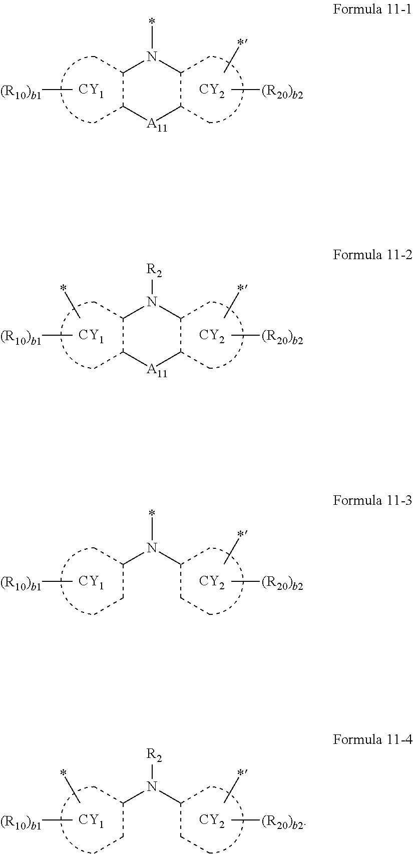

In Formulae 11-1 to 11-4,
CY₁ and CY₂ may each independently be a C₅-C₆₀ carbocyclic group or a C₂-C₆₀ heterocyclic group,
A₁₁ may be selected from:
a single bond, a C₁-C₄ alkylene group, and a C₂-C₄ alkenylene group; and
a C₁-C₄ alkylene group and a C₂-C₄ alkenylene group, each substituted with at least one selected from deuterium, a cyano group, a C₁-C₆₀ alkyl group, a C₁-C₆₀ alkoxy group, a phenyl group, a fluorenyl group, a carbazolyl group, a dibenzofuranyl group, and a dibenzothiophenyl group,
R₂, R₁₀, and R₂₀ may each independently be selected from:
hydrogen, deuterium, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a furanyl group, a thiophenyl group, an indolyl group, a benzofuranyl group, a benzothiophenyl group, a carbazolyl group, a dibenzofuranyl group, a dibenzothiophenyl group, a benzocarbazolyl group, a naphthobenzofuranyl group, a naphthobenzothiophenyl group, a dibenzocarbazolyl group, a dinaphthofuranyl group, a dinaphthothiophenyl group, an indolocarbazolyl group, an indolodibenzofuranyl group, and an indolodibenzothiophenyl group; and
a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a furanyl group, a thiophenyl group, an indolyl group, a benzofuranyl group, a benzothiophenyl group, a carbazolyl group, a dibenzofuranyl group, a dibenzothiophenyl group, a benzocarbazolyl group, a naphthobenzofuranyl group, a naphthobenzothiophenyl group, a dibenzocarbazolyl group, a dinaphthofuranyl group, a dinaphthothiophenyl group, an indolocarbazolyl group, an indolodibenzofuranyl group, and an indolodibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, a fluorenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group,
b1 and b2 may each independently be an integer from 0 to 3, and
* and *′ each indicate a binding site to a neighboring atom.

For example, CY₁ and CY₂ may each independently be selected from a benzene group, a naphthalene group, an indene group, an indole group, a benzofuran group, a benzothiophene group, a fluorene group, a carbazole group, a dibenzofuran group, and a dibenzothiophene group, but embodiments of the present disclosure are not limited thereto.

In an embodiment, at least one of CY₁ and CY₂ may be a benzene group, but embodiments of the present disclosure are not limited thereto.

In an embodiment, D₁ and D₂ in Formula 1 may each independently be selected from groups represented by Formulae 11(1) to 11(19):

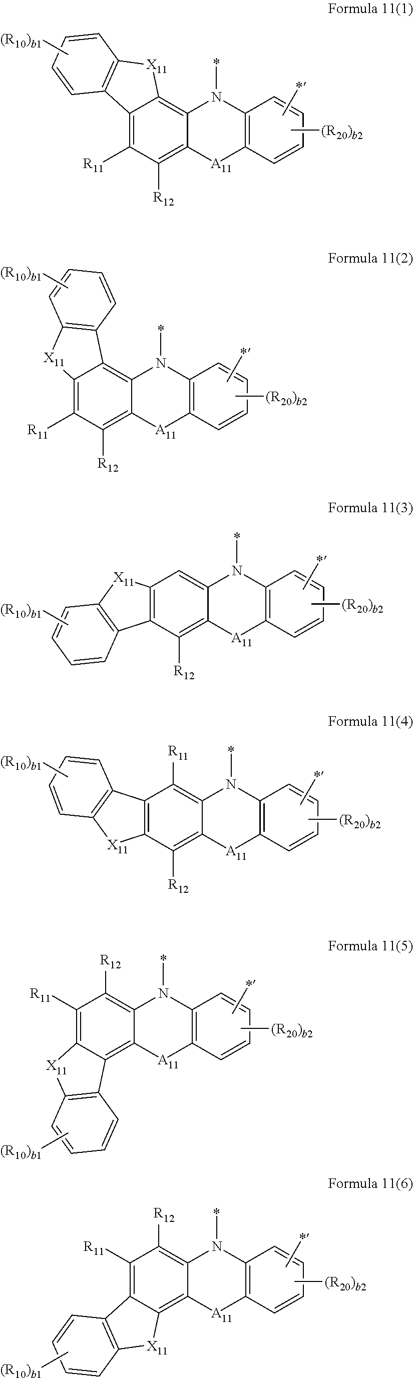

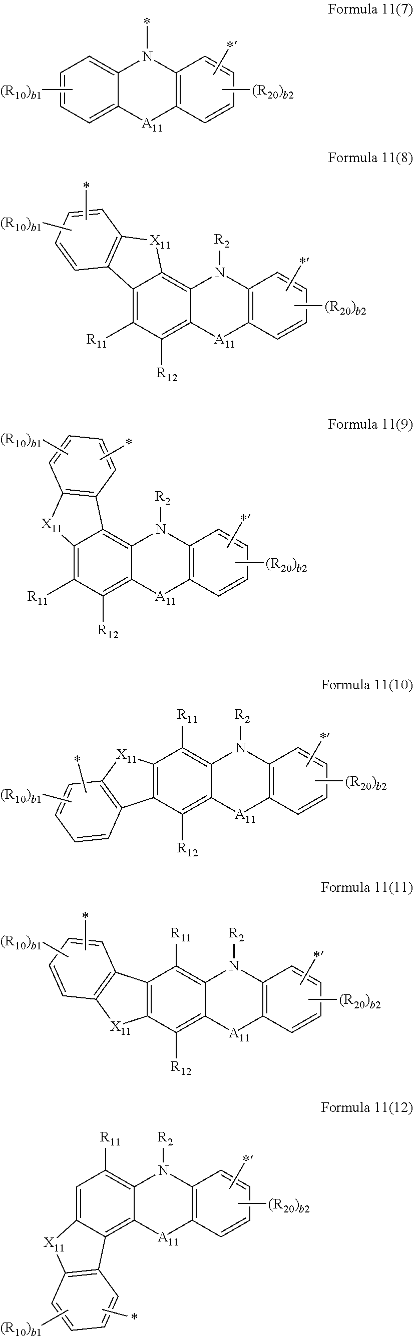

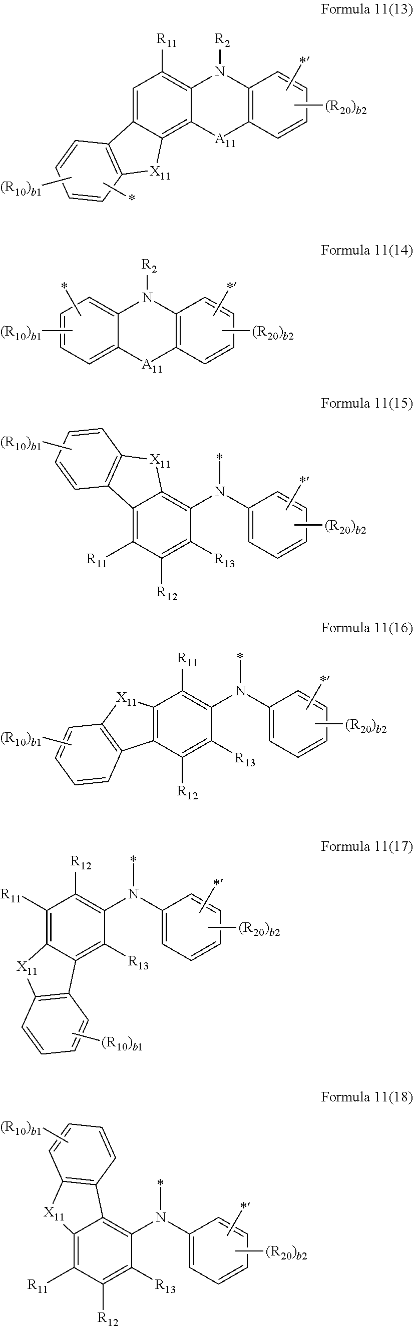

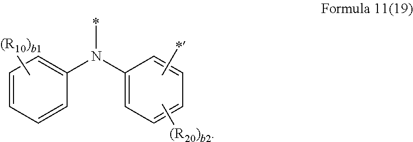

In Formulae 11(1) to 11(19),
X₁₁ may be O, S, C(R₁₄), or N(R₁₅)(R₁₆),
Au, R₂, R₁₀, R₂₀, b1, and b2 are each independently the same as described herein,
R₁₁ to R₁₆ are each independently the same as described in connection with R₁₀, and
* and *′ each indicate a binding site to a neighboring atom.

For example, R₁₀ to R₁₆ and R₂₀ in Formulae 11(1) to 11(19) may each independently be selected from hydrogen, deuterium, a cyano group, a C₁-C₂₀ alkyl group, a C₁-C₂₀ alkoxy group, a phenyl group, a biphenyl group, a terphenyl group, a naphthyl group, a fluorenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group, but embodiments of the present disclosure are not limited thereto.

d1 in Formula 1 may 0, 1, or 2.

In an embodiment, d1 in Formula 1 may be 0 or 1.

In one or more embodiments, d1 in Formula 1 may be 1, but embodiments of the present disclosure are not limited thereto.

A₁ in Formula 1 may be a substituted or unsubstituted π electron-depleted nitrogen-containing C₂-C₆₀ heterocyclic group or a sulphonyl-containing group.

For example, A₁ in Formula 1 may be selected from groups represented by Formulae 3-1 to 3-14 and a sulphonyl-containing group, but embodiments of the present disclosure are not limited thereto:

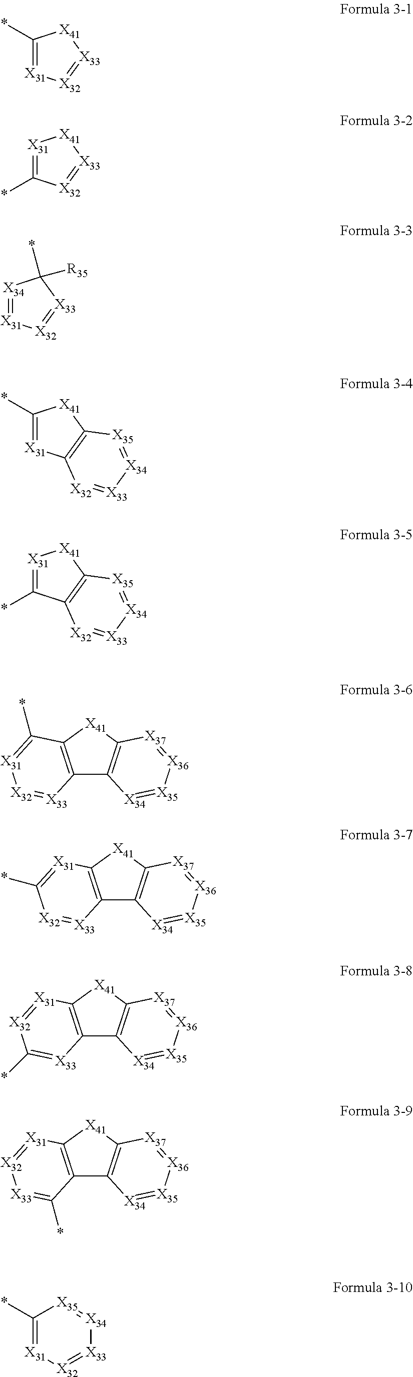

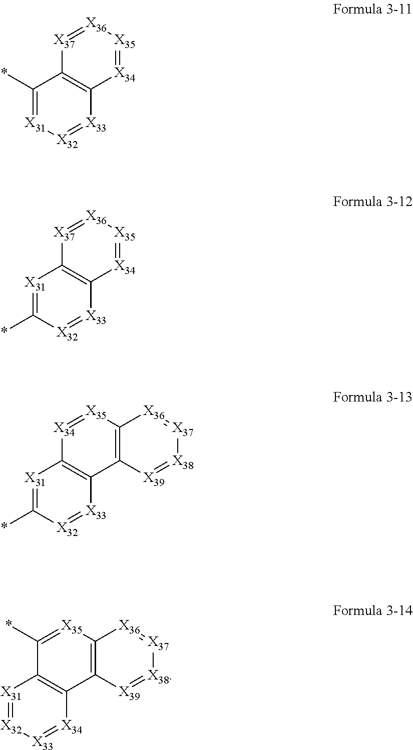

In Formulae 3-1 to 3-14, X₃₁ may be N or C(R₃₁), X₃₂ may be N or C(R₃₂), X₃₃ may be N or C(R₃₃), X₃₄ may be N or C(R₃₄), X₃₅ may be N or C(R₃₅), X₃₆ may be N or C(R₃₆), X₃₇ may be N or C(R₃₇), X₃₈ may be N or C(R₃₈), and X₃₉ may be N or C(R₃₉),
X₄₁ in Formulae 3-1, 3-2, and 3-4 to 3-9 may be N(R₄₁), C(R₄₂)(R₄₃), O, or S,
at least one of X₃₁ to X₃₃ in Formulae 3-1 and 3-2 may be N, at least one of X₃₁ to X₃₄ in Formula 3-3 may be N, at least one of X₃₁ to X₃₅ in Formulae 3-4, 3-5, and 3-10 may be N, at least one of X₃₁ to X₃₇ in Formulae 3-6 to 3-9, 3-11, and 3-12 may be N, and at least one of X₃₁ to X₃₉ in Formulae 3-13 and 3-14 may be N,
R₃₁ to R₃₉ and R₄₁ to R₄₃ may each independently be selected from hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a tri(C₁-C₂₀ alkyl)phenyl group, a (C₆-C₂₀ aryl)phenyl group, a di(C₆-C₂₀ aryl)phenyl group, a tri(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
* indicates a binding site to a neighboring atom.

In one or more embodiments, A₁ in Formula 1 may be selected from groups represented by Formulae 3-4(1) to 3-4(4), 3-5(1) to 3-5(4), 3-6(1), 3-7(1), 3-8(1), 3-9(1), 3-10(1) to 3-10(8), 3-11(1) to 3-11(23), and 3-12(1) to 3-12(24):

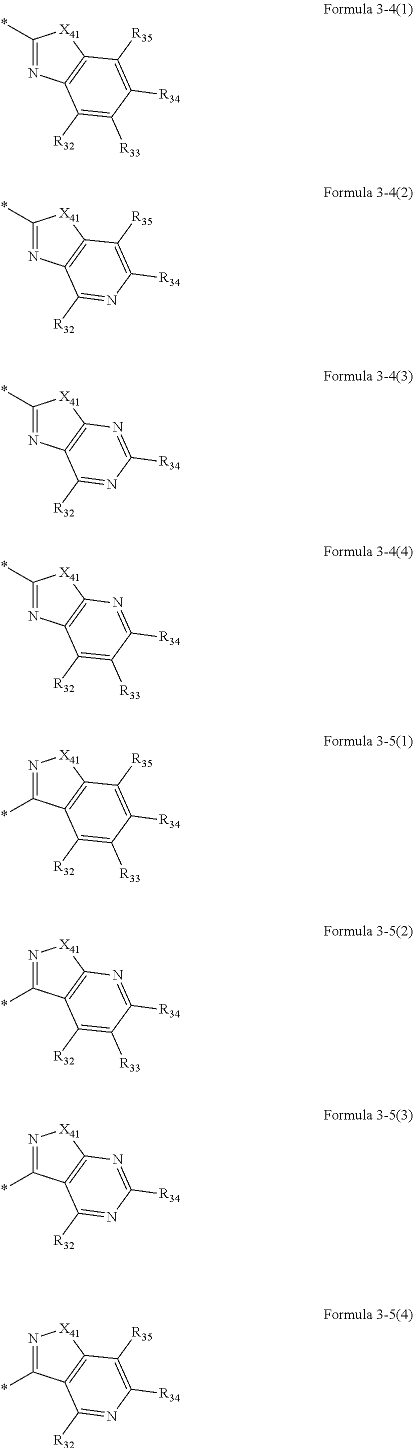

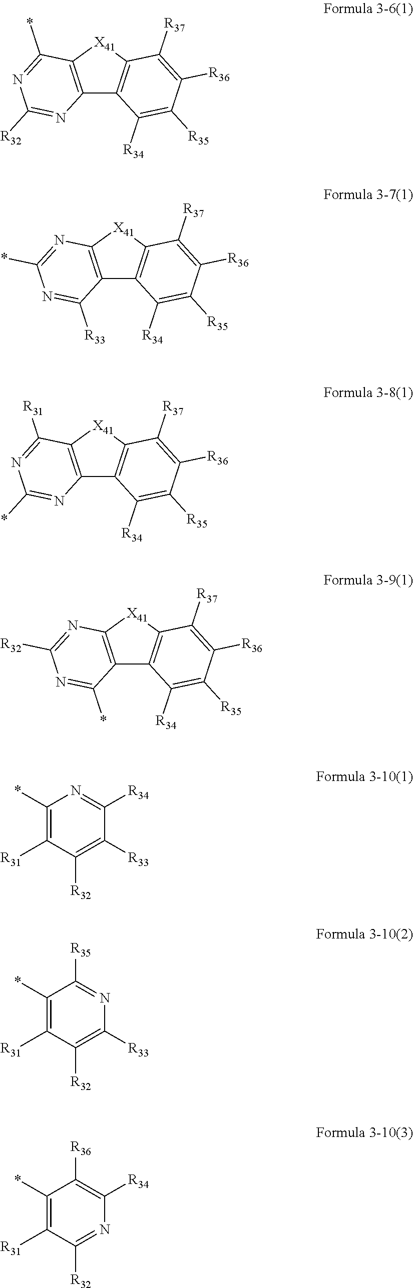

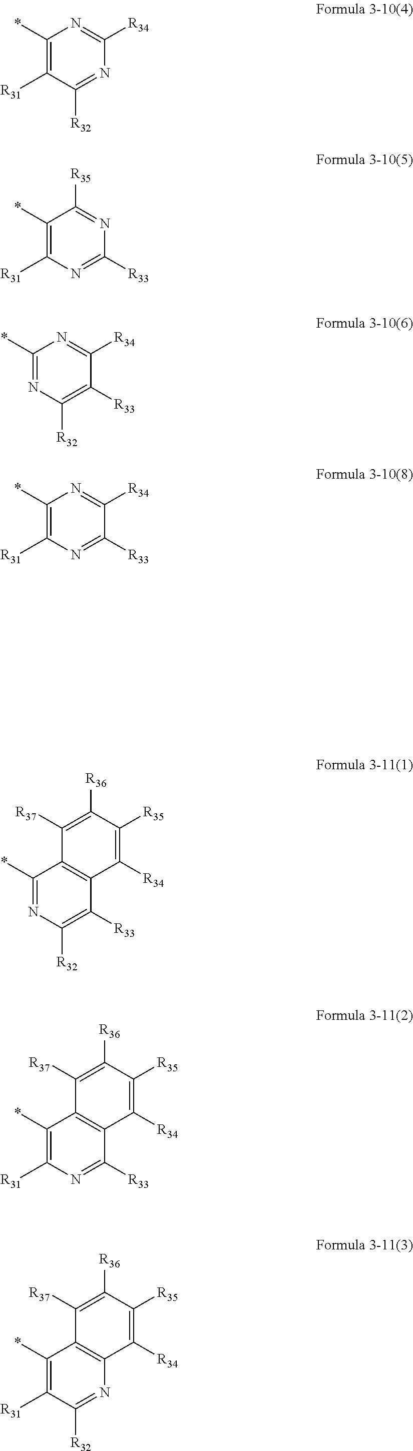

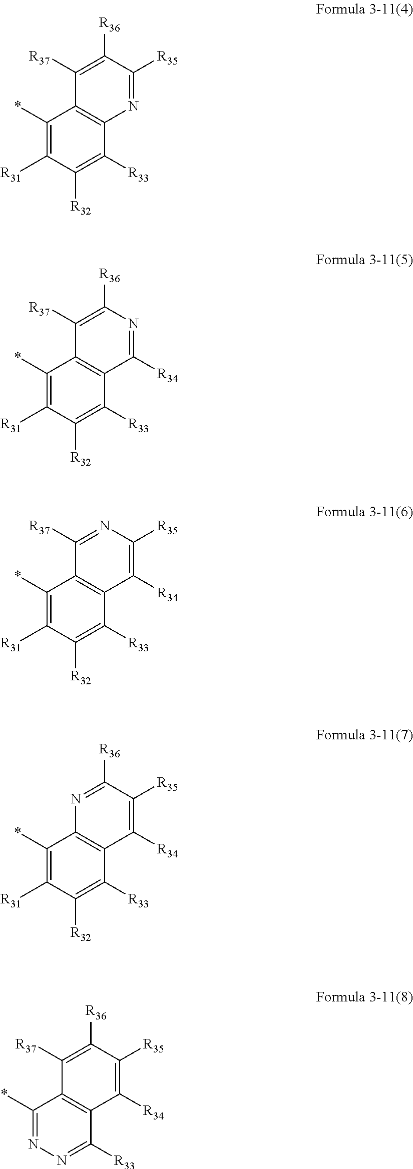

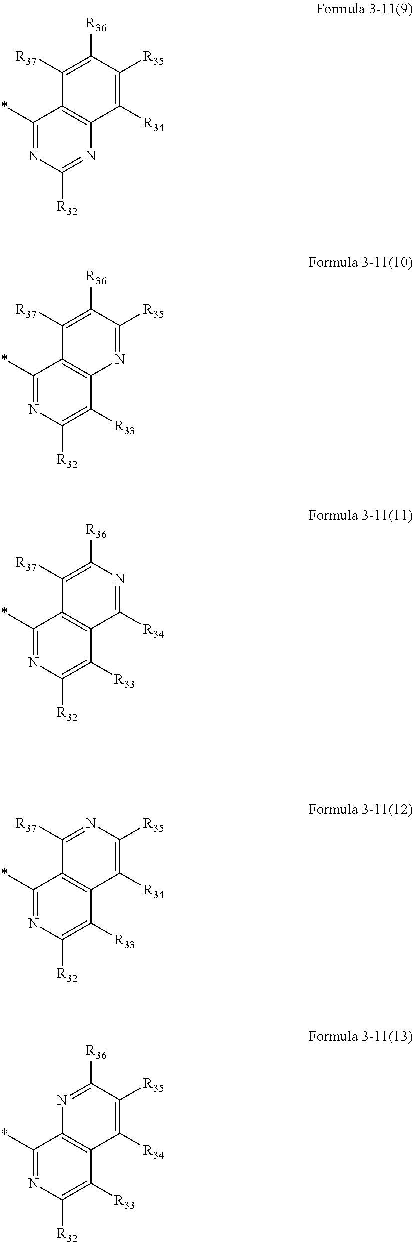

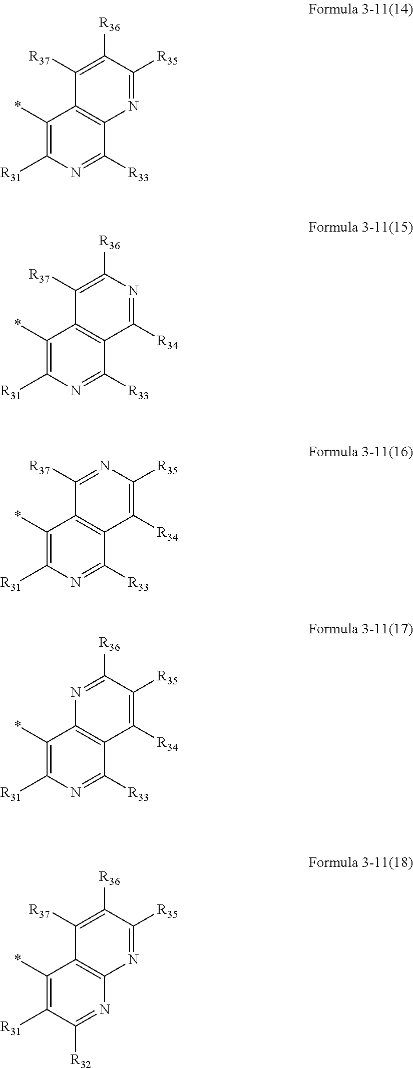

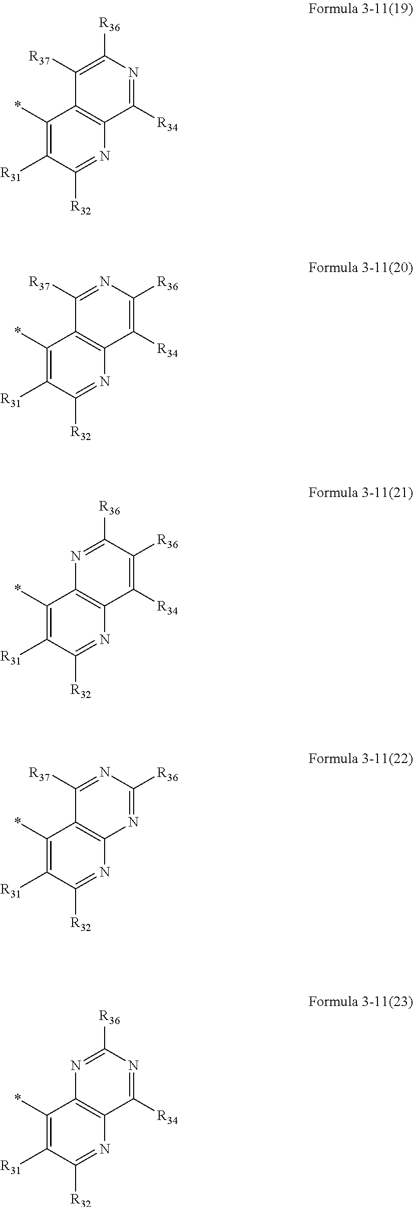

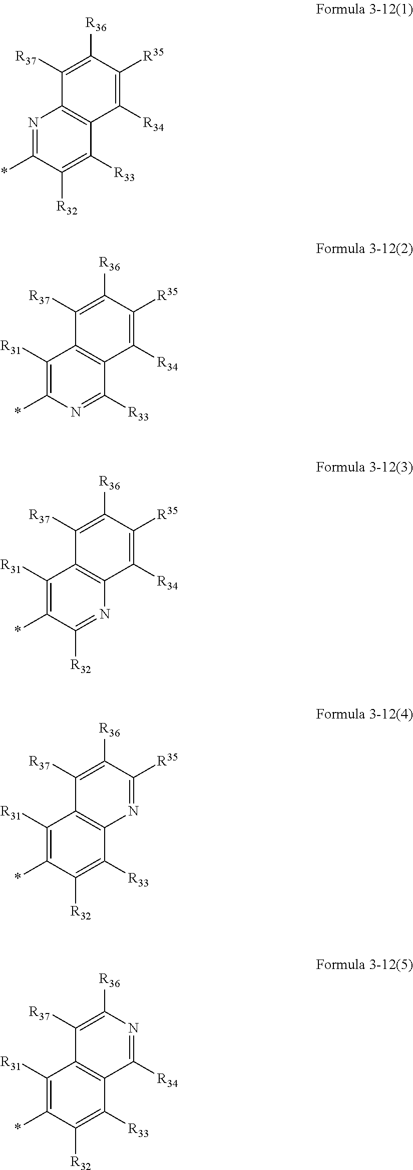

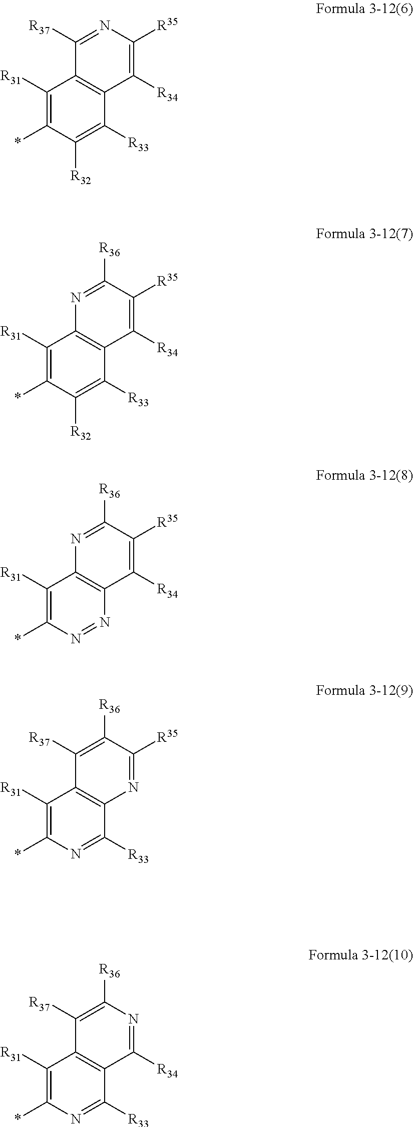

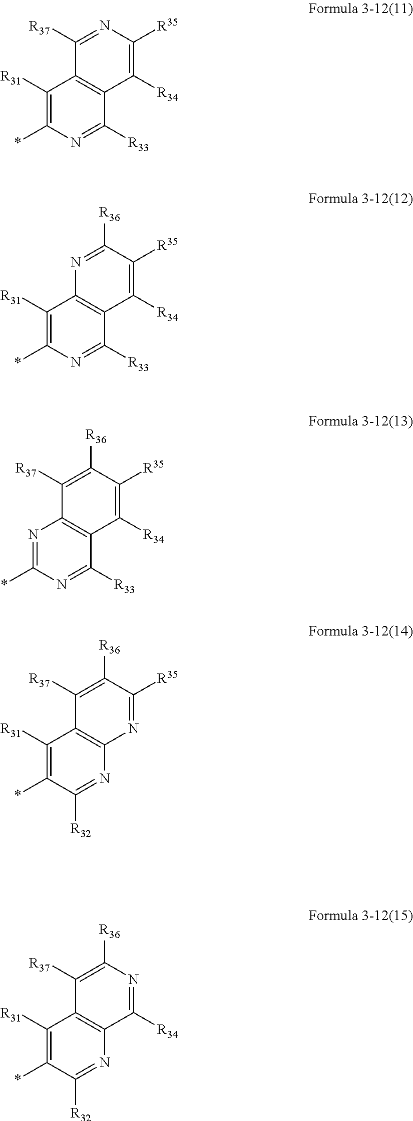

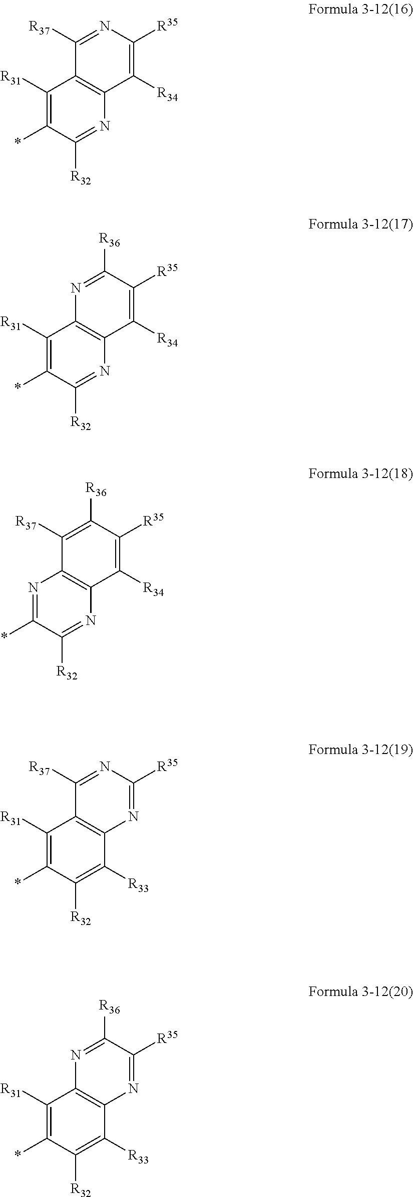

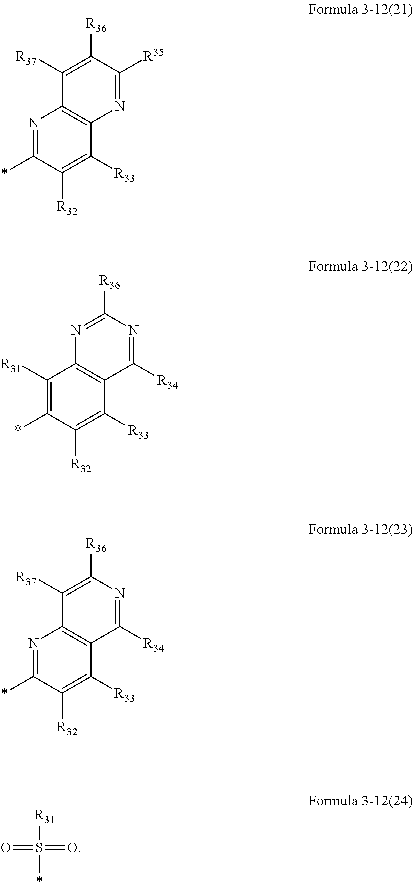

In Formulae 3-4(1) to 3-4(4), 3-5(1) to 3-5(4), 3-6(1), 3-7(1), 3-8(1), 3-9(1), 3-10(1) to 3-10(8), 3-11(1) to 3-11(23), and 3-12(1) to 3-12(24), X₄₁ may be N(R₄₁), C(R₄₂)(R₄₃), O, or S,
R₃₁ to R₃₇ and R₄₁ to R₄₃ are each independently the same as described herein, and
* indicates a binding site to a neighboring atom.

In one or more embodiments, A₁ in Formula 1 may be selected from groups represented by Formulae 3-6(1), 3-10(4), 3-10(8), and 3-12(24).

In one or more embodiments, A₁ in Formula 1 may be a triazine-containing group or a sulphonyl-containing group.

R₁ in Formula 1 may be selected from hydrogen, deuterium, a cyano group, a C₁-C₂₀ alkyl group, a C₁-C₂₀ alkoxy group, a phenyl group, a biphenyl group, a terphenyl group, a naphthyl group, a fluorenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group.

The TADF emitter may be selected from Compounds 1 to 11, but embodiments of the present disclosure are not limited thereto:

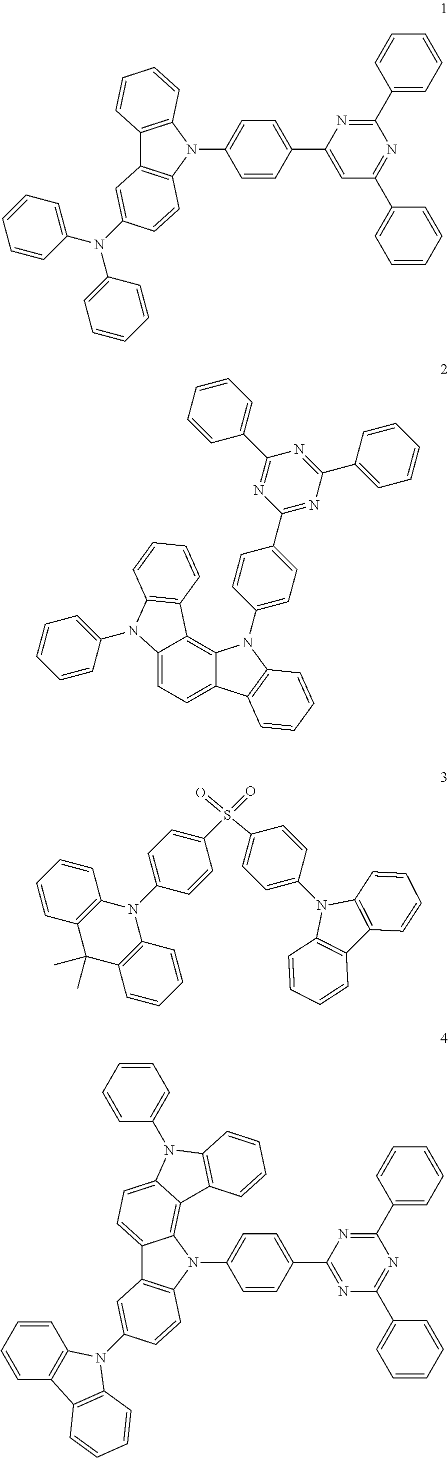 [SMILES: c1ccc(-c2cc(-c3ccc(-n4c5ccccc5c5cc(N(c6ccccc6)c6ccccc6)ccc54)cc3)nc(-c3ccccc3)n2)cc1 ; c1ccc(-c2nc(-c3ccccc3)nc(-c3ccc(-n4c5ccccc5c5ccc6c(c7ccccc7n6-c6ccccc6)c54)cc3)n2)cc1 ; CC1(C)c2ccccc2N(c2ccc(S(=O)(=O)c3ccc(-n4c5ccccc5c5ccccc54)cc3)cc2)c2ccccc21 ; c1ccc(-c2nc(-c3ccccc3)nc(-c3ccc(-n4c5ccc(-n6c7ccccc7c7ccccc76)cc5c5ccc6c(c7ccccc7n6-c6ccccc6)c54)cc3)n2)cc1]

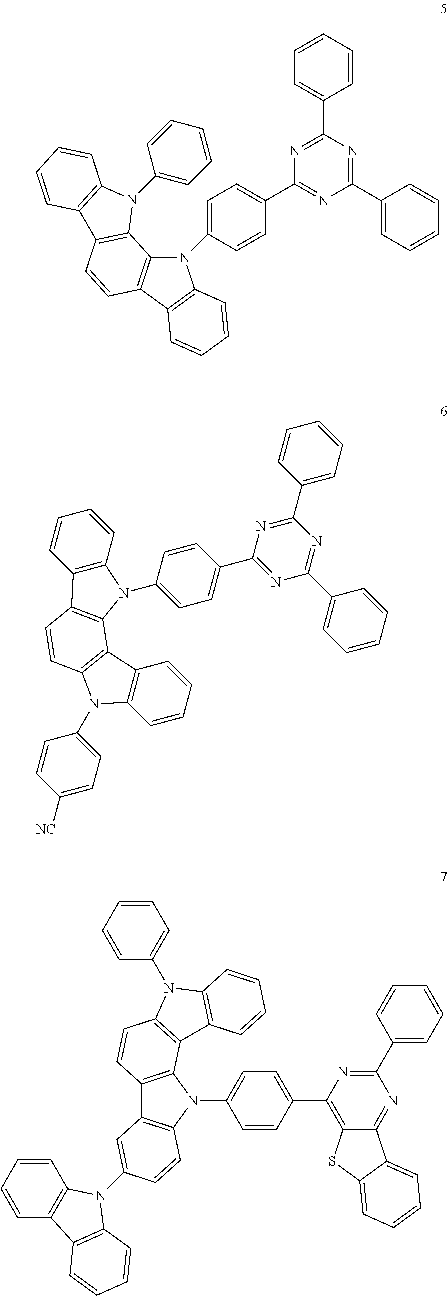 [SMILES: c1ccc(-c2nc(-c3ccccc3)nc(-c3ccc(-n4c5ccccc5c5ccc6c7ccccc7n(-c7ccccc7)c6c54)cc3)n2)cc1 ; N#Cc1ccc(-n2c3ccccc3c3c2ccc2c4ccccc4n(-c4ccc(-c5nc(-c6ccccc6)nc(-c6ccccc6)n5)cc4)c23)cc1 ; c1ccc(-c2nc(-c3ccc(-n4c5ccc(-n6c7ccccc7c7ccccc76)cc5c5ccc6c(c7ccccc7n6-c6ccccc6)c54)cc3)c3sc4ccccc4c3n2)cc1]

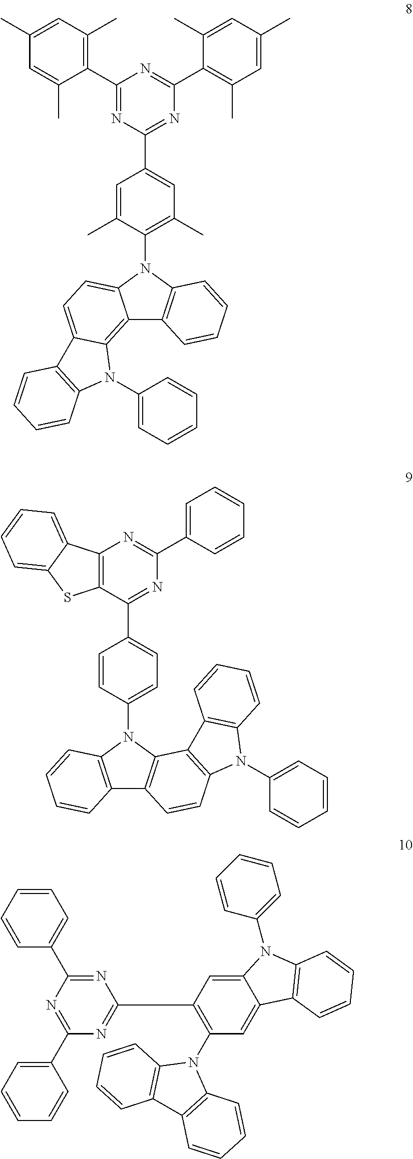

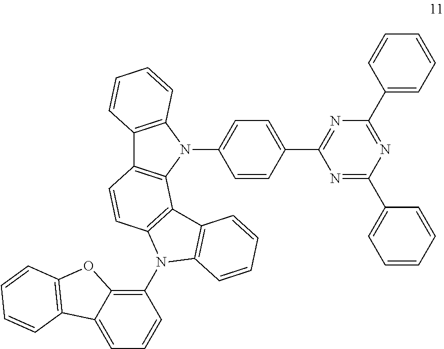 [SMILES: c1ccc(-c2nc(-c3ccccc3)nc(-c3ccc(-n4c5ccccc5c5ccc6c(c7ccccc7n6-c6cccc7c6oc6ccccc67)c54)cc3)n2)cc1]

The host, which is usable in the emission layer together with the TADF emitter, may be selected from any hosts.

For example, the host may include at least one compound selected from a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, and a sulphonyl-containing compound.

For example, the host may be a compound including at least one carbazole ring and at least one cyano group or a phosphine oxide-containing compound, but embodiments of the present disclosure are not limited thereto.

In an embodiment, the host may include at least one compound selected from Compounds H1 to H24, but embodiments of the present disclosure are not limited thereto:

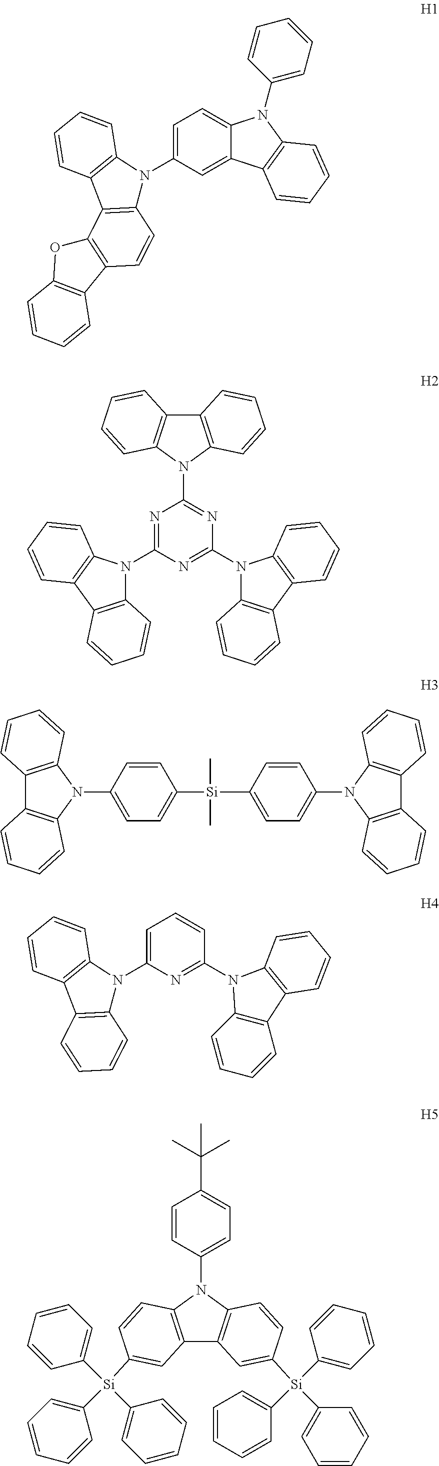

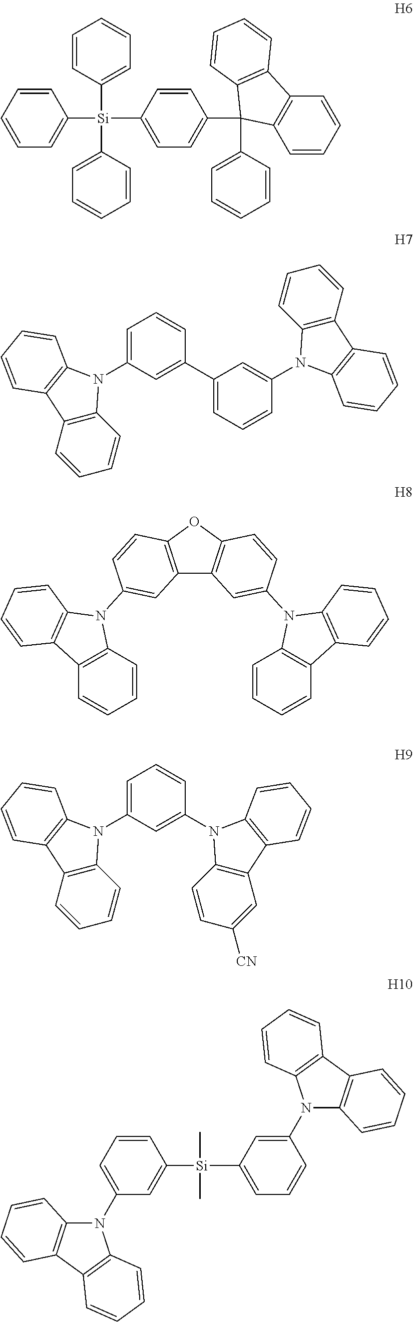 [SMILES: c1ccc(C2(c3ccc([Si](c4ccccc4)(c4ccccc4)c4ccccc4)cc3)c3ccccc3-c3ccccc32)cc1 ; c1cc(-c2cccc(-n3c4ccccc4c4ccccc43)c2)cc(-n2c3ccccc3c3ccccc32)c1 ; c1ccc2c(c1)c1ccccc1n2-c1ccc2oc3ccc(-n4c5ccccc5c5ccccc54)cc3c2c1 ; N#Cc1ccc2c(c1)c1ccccc1n2-c1cccc(-n2c3ccccc3c3ccccc32)c1 ; C[Si](C)(c1cccc(-n2c3ccccc3c3ccccc32)c1)c1cccc(-n2c3ccccc3c3ccccc32)c1]

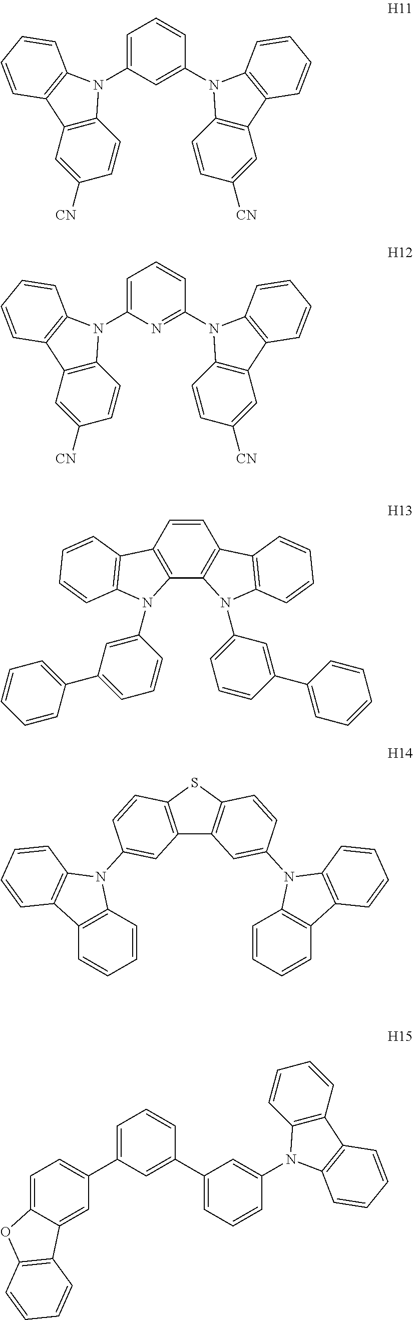

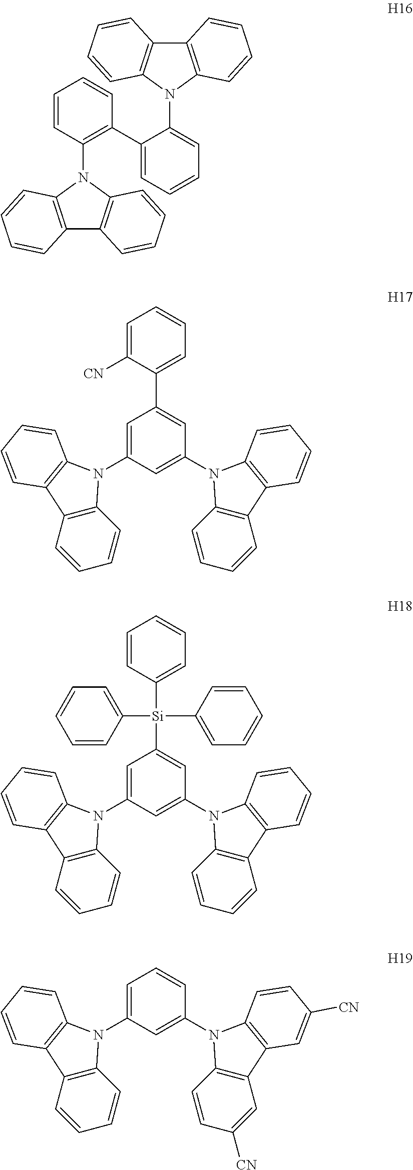

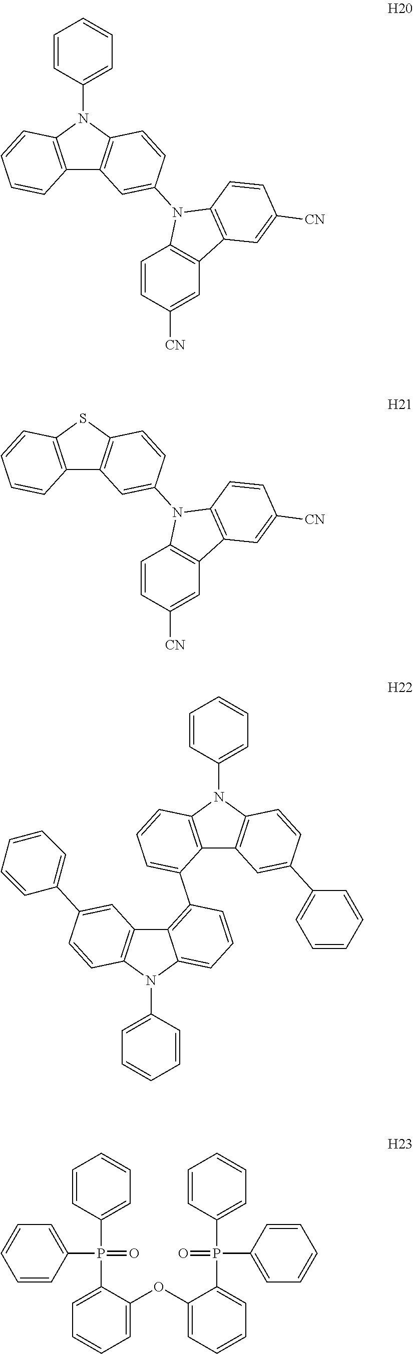 [SMILES: N#Cc1ccc2c(c1)c1cc(C#N)ccc1n2-c1ccc2c(c1)c1ccccc1n2-c1ccccc1 ; N#Cc1ccc2c(c1)c1cc(C#N)ccc1n2-c1ccc2sc3ccccc3c2c1 ; c1ccc(-c2ccc3c(c2)c2c(-c4cccc5c4c4cc(-c6ccccc6)ccc4n5-c4ccccc4)cccc2n3-c2ccccc2)cc1 ; O=P(c1ccccc1)(c1ccccc1)c1ccccc1Oc1ccccc1P(=O)(c1ccccc1)c1ccccc1]

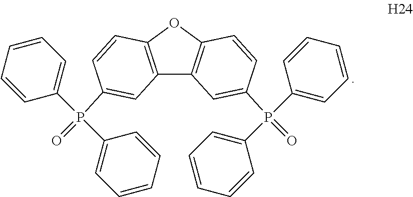 [SMILES: O=P(c1ccccc1)(c1ccccc1)c1ccc2oc3ccc(P(=O)(c4ccccc4)c4ccccc4)cc3c2c1]

A ratio of a delayed fluorescence component emitted from the TADF emitter with respect to a total emission component of the emission layer may be about 30% or more (about 33% or more in one example, about 48% or more in another example, about 74% or more in another embodiment).

An amount of the TADF emitter may be smaller than an amount of the host. For example, an amount of the TADF emitter in the emission layer may be generally selected within a range of about 0.01 parts by weight to about 20 parts by weight based on 100 parts by weight of the emission layer, but embodiments of the present disclosure are not limited thereto. While not wishing to be bound by theory, it is understood that when the amount of the TADF emitter is within this range, light emission may be provided without a quenching phenomenon.

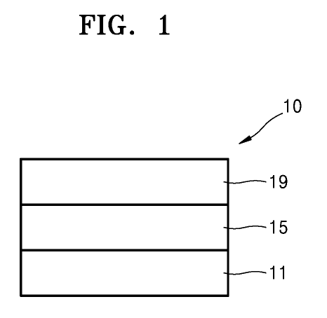

FIG. 1 is a schematic view of an organic light-emitting device 10 according to an embodiment. Hereinafter, the structure of an organic light-emitting device according to an embodiment and a method of manufacturing an organic light-emitting device according to an embodiment will be described in connection with FIG. 1. The organic light-emitting device 10 includes a first electrode 11, an organic layer 15, and a second electrode 19, which are sequentially stacked.

A substrate may be additionally disposed under the first electrode 11 or above the second electrode 19. For use as the substrate, any substrate that is used in general organic light-emitting devices may be used, and the substrate may be a glass substrate or a transparent plastic substrate, each having excellent mechanical strength, thermal stability, transparency, surface smoothness, ease of handling, and water resistance.

The first electrode 11 may be formed by depositing or sputtering a material for forming the first electrode 11 on the substrate. The first electrode 11 may be an anode. The material for forming the first electrode 11 may be selected from materials with a high work function to facilitate hole injection. The first electrode 11 may be a reflective electrode, a semi-transmissive electrode, or a transmissive electrode. The material for forming the first electrode may be, for example, indium tin oxide (ITO), indium zinc oxide (IZO), tin oxide (SnO₂), and zinc oxide (ZnO). In one or more embodiments, magnesium (Mg), aluminum (Al), aluminum-lithium (Al—Li), calcium (Ca), magnesium-indium (Mg—In), or magnesium-silver (Mg—Ag) may be used as the material for forming the first electrode.

The first electrode 11 may have a single-layered structure or a multi-layered structure including two or more layers. For example, the first electrode 11 may have a three-layered structure of ITO/Ag/ITO, but the structure of the first electrode 110 is not limited thereto.

The organic layer 15 is disposed on the first electrode 11.

The organic layer 15 may include a hole transport region, an emission layer, and an electron transport region.

The hole transport region may be disposed between the first electrode 11 and the emission layer.

The hole transport region may include at least one selected from a hole injection layer, a hole transport layer, an electron blocking layer, and a buffer layer.

The hole transport region may include only either a hole injection layer or a hole transport layer. In one or more embodiments, the hole transport region may have a hole injection layer/hole transport layer structure or a hole injection layer/hole transport layer/electron blocking layer structure, which are sequentially stacked in this stated order from the first electrode 11.

A hole injection layer may be formed on the first electrode 11 by using one or more suitable methods selected from vacuum deposition, spin coating, casting, or Langmuir-Blodgett (LB) deposition.

When a hole injection layer is formed by vacuum deposition, the deposition conditions may vary according to a compound that is used to form the hole injection layer, and the structure and thermal characteristics of the hole injection layer. For example, the deposition conditions may include a deposition temperature of about 100° C. to about 500° C., a vacuum pressure of about 10⁻⁸ torr to about 10⁻³ torr, and a deposition rate of about 0.01 Å/sec to about 100 Å/sec. However, the deposition conditions are not limited thereto.

When the hole injection layer is formed using spin coating, coating conditions may vary according to the material used to form the hole injection layer, and the structure and thermal properties of the hole injection layer. For example, a coating speed may be from about 2,000 revolutions per minute (rpm) to about 5,000 rpm, and a temperature at which a heat treatment is performed to remove a solvent after coating may be from about 80° C. to about 200° C. However, the coating conditions are not limited thereto.

Conditions for forming a hole transport layer and an electron blocking layer may be understood by referring to conditions for forming the hole injection layer.

The hole transport region may include at least one selected from m-MTDATA, TDATA, 2-TNATA, NPB, β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrene sulfonate) (PANI/PSS), a compound represented by Formula 201 below, and a compound represented by Formula 202 below:

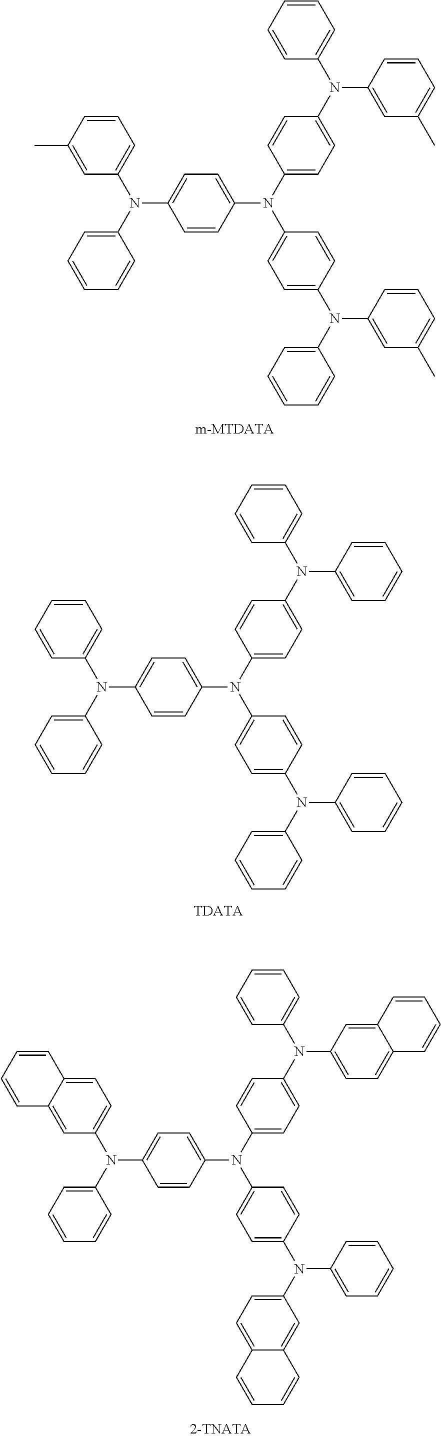

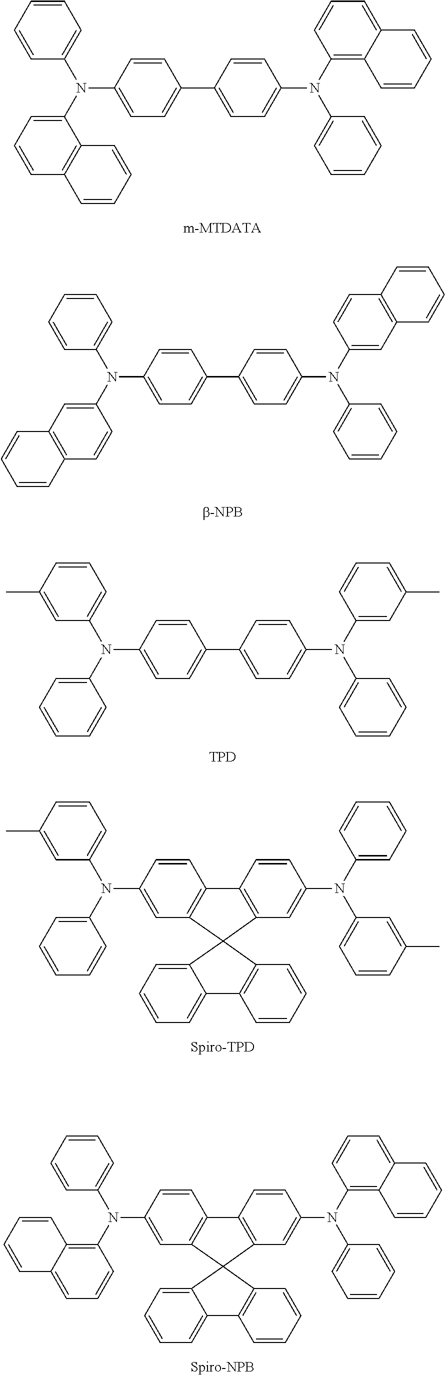

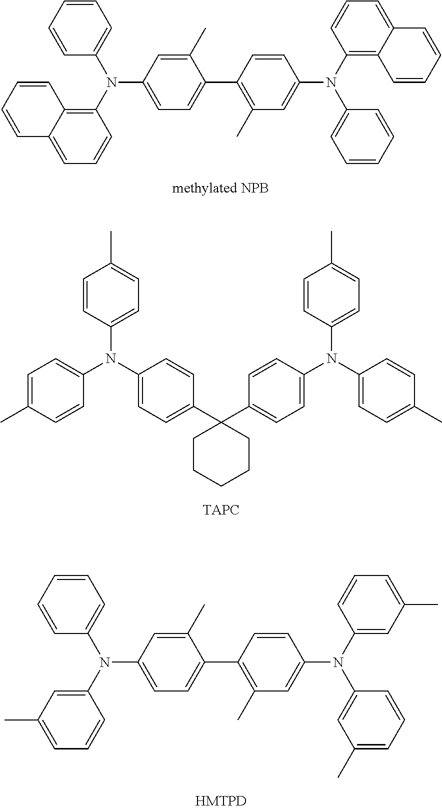

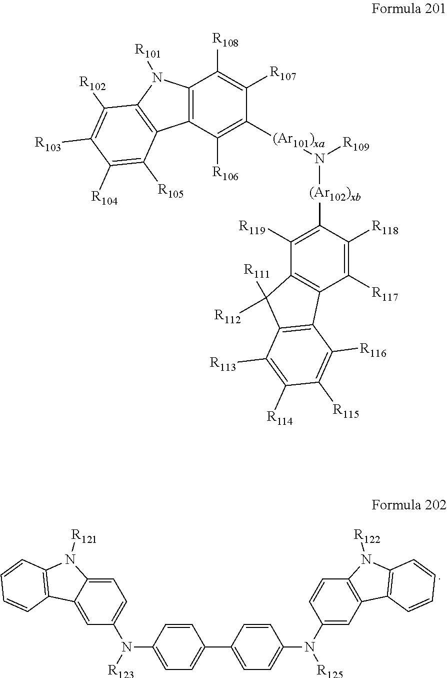

Ar₁₀₁ and Ar₁₀₂ in Formula 201 may each independently be selected from:
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group; and
a phenylene group, a pentalenylene group, an indenylene group, a naphthylene group, an azulenylene group, a heptalenylene group, an acenaphthylene group, a fluorenylene group, a phenalenylene group, a phenanthrenylene group, an anthracenylene group, a fluoranthenylene group, a triphenylenylene group, a pyrenylene group, a chrysenylenylene group, a naphthacenylene group, a picenylene group, a perylenylene group, and a pentacenylene group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ cycloalkenyl group, a C₁-C₁₀ heterocycloalkyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, and a monovalent non-aromatic condensed heteropolycyclic group.

xa and xb in Formula 201 may each independently be an integer from 0 to 5, or may be 0, 1, or 2. For example, xa is 1 and xb is 0, but xa and xb are not limited thereto.

R₁₀₁ to R₁₀₈, R₁₁₁ to R₁₁₉, and R₁₂₁ to R₁₂₄ in Formulae 201 and 202 may each independently be selected from:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, and a C₁-C₁₀ alkyl group (for example, a methyl group, an ethyl group, a propyl group, a butyl group, a pentyl group, a hexyl group, and so on), or a C₁-C₁₀ alkoxy group (for example, a methoxy group, an ethoxy group, a propoxy group, a butoxy group, a pentoxy group, and so on);
a C₁-C₁₀ alkyl group and a C₁-C₁₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, and a phosphoric acid group or a salt thereof;
a phenyl group, a naphthyl group, an anthracenyl group, a fluorenyl group, and a pyrenyl group; and
a phenyl group, a naphthyl group, an anthracenyl group, a fluorenyl group, and a pyrenyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group,
but embodiments of the present disclosure are not limited thereto.

R₁₀₉ in Formula 201 may be selected from:
a phenyl group, a naphthyl group, an anthracenyl group, and a pyridinyl group; and
a phenyl group, a naphthyl group, an anthracenyl group, and a pyridinyl group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a naphthyl group, an anthracenyl group, and a pyridinyl group.

According to an embodiment, the compound represented by Formula 201 may be represented by Formula 201 Å, but embodiments of the present disclosure are not limited thereto:

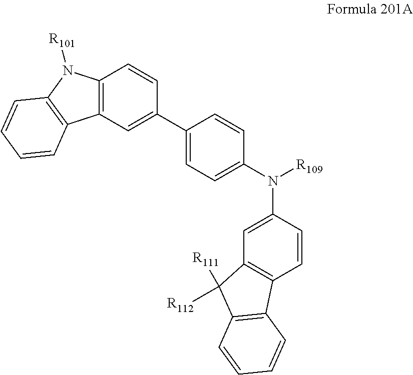

R₁₀₁, R₁₁₁, R₁₁₂, and R₁₀₉ in Formula 201 Å may be understood by referring to the description provided herein.

For example, the compound represented by Formula 201, and the compound represented by Formula 202 may include compounds HT1 to HT20 illustrated below, but are not limited thereto.

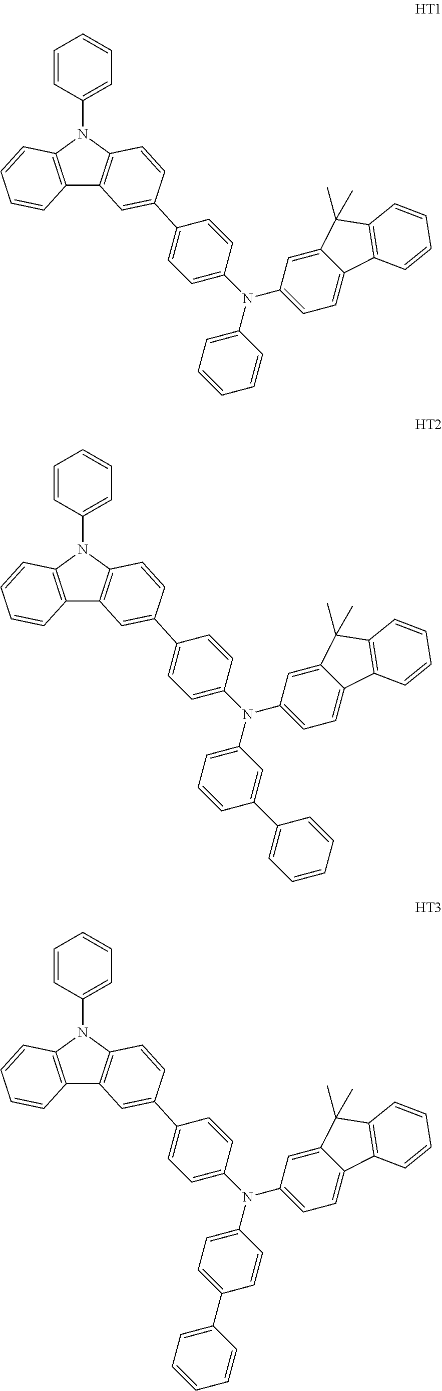 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

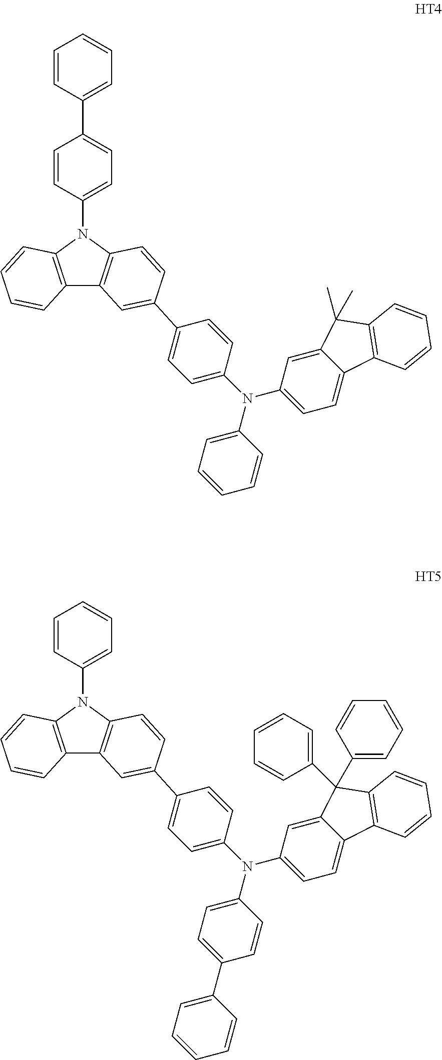 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

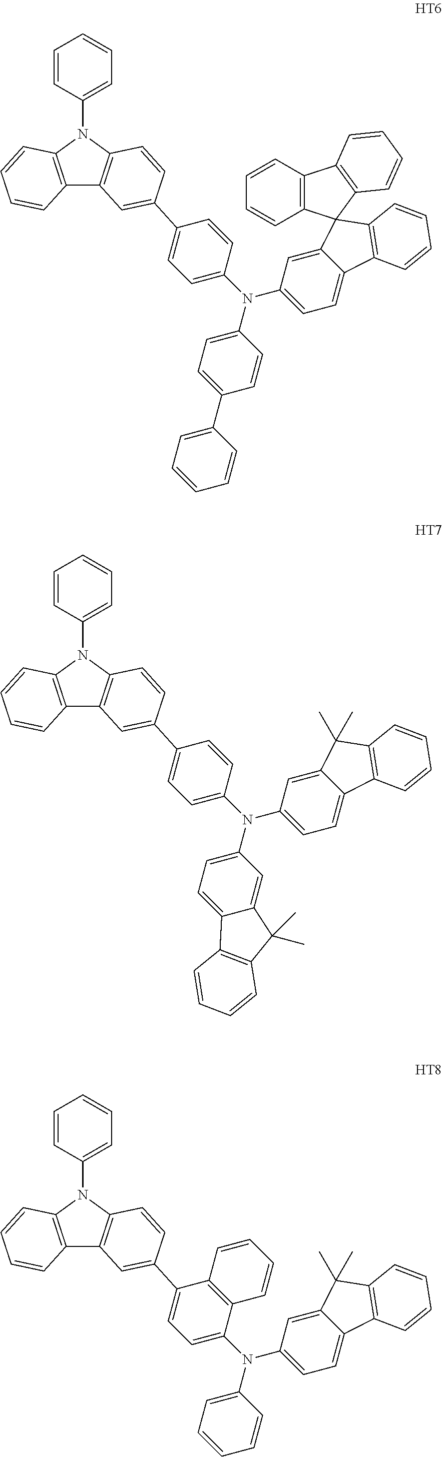 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

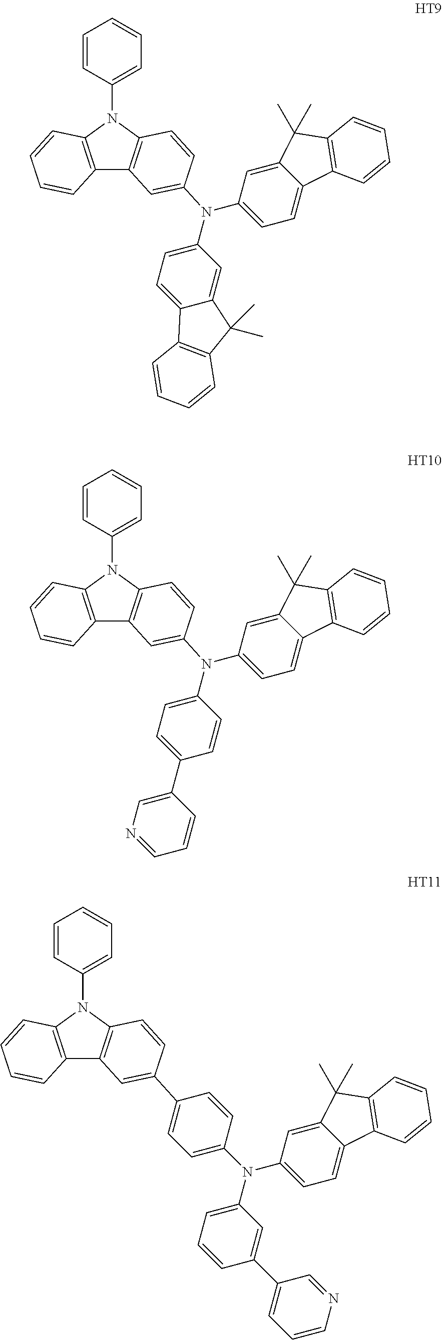 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc4c(c3)c3ccccc3n4-c3ccccc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

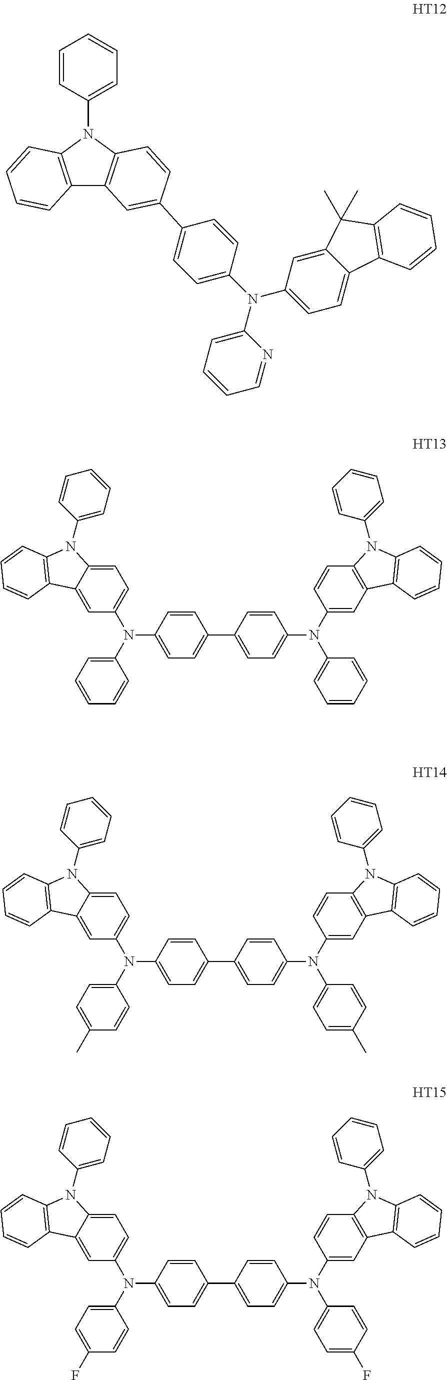 [SMILES: CC1(C)c2ccccc2-c2ccc(N(c3ccc(-c4ccc5c(c4)c4ccccc4n5-c4ccccc4)cc3)c3ccccn3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

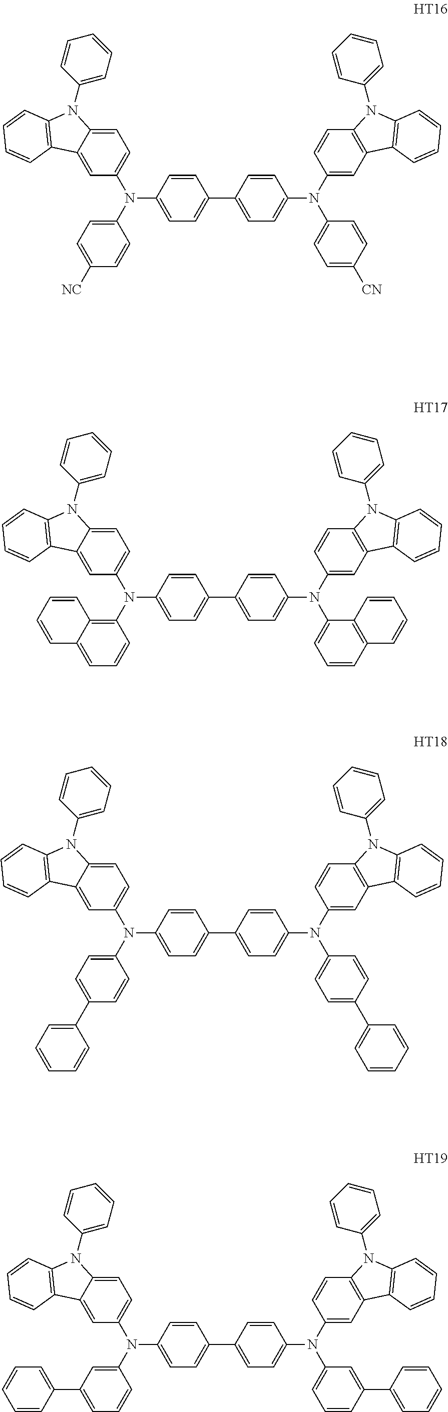 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1]

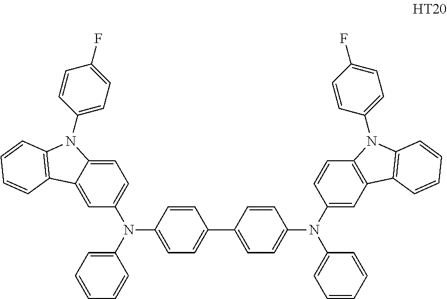 [SMILES: Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be in a range of about 100 Å to about 10,000 Å, for example, about 100 Å to about 3,000 Å. When the hole transport region includes at least one of a hole injection layer and a hole transport layer, the thickness of the hole injection layer may be in a range of about 100 Å to about 10,000 Å, for example, about 100 Å to about 2,000 Å, and the thickness of the hole transport layer may be in a range of about 50 Å to about 2,000 Å, for example, about 100 Å to about 1,500 Å. While not wishing to be bound by theory, it is understood that when the thicknesses of the hole transport region, the hole injection layer and the hole transport layer are within these ranges, satisfactory hole transporting characteristics may be obtained without a substantial increase in driving voltage.

The hole transport region may further include, in addition to these materials, a charge-generation material for the improvement of conductive properties. The charge-generation material may be homogeneously or non-homogeneously dispersed in the hole transport region.

The charge-generation material may be, for example, a p-dopant. The p-dopant may be one selected from a quinone derivative, a metal oxide, and a cyano group-containing compound, but embodiments of the present disclosure are not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as a tungsten oxide or a molybdenium oxide; and a cyano group-containing compound, such as Compound HT-D1 or Compound HT-D2 below, but are not limited thereto.

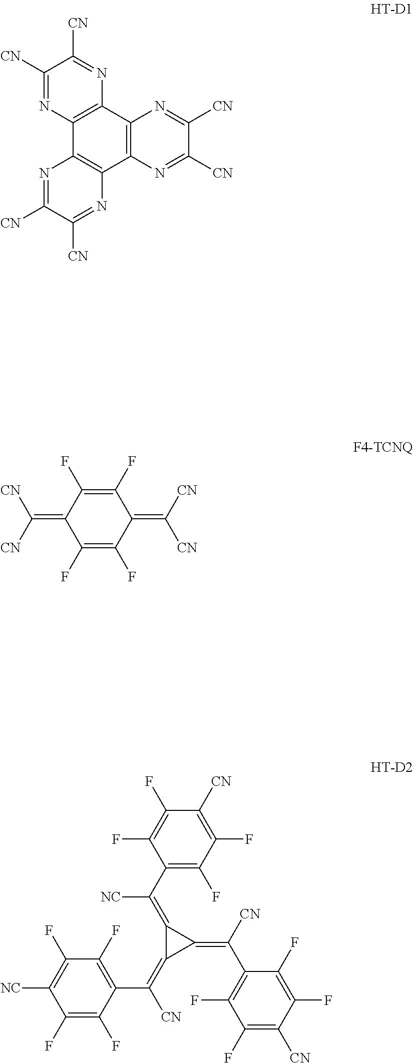

The hole transport region may include a buffer layer.

Also, the buffer layer may compensate for an optical resonance distance according to a wavelength of light emitted from the emission layer, and thus, efficiency of a formed organic light-emitting device may be improved.

The hole transport region may further include an electron blocking layer. The electron blocking layer may include, for example, mCP, but a material therefor is not limited thereto.

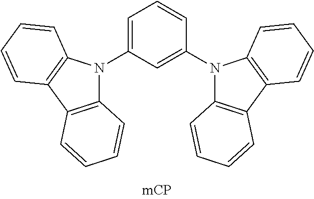 [SMILES: c1cc(-n2c3ccccc3c3ccccc32)cc(-n2c3ccccc3c3ccccc32)c1]

In one or more embodiments, as an electron blocking material, the host included in the emission layer may be used, but the embodiments are not limited thereto.

Then, an emission layer may be formed on the hole transport region by vacuum deposition, spin coating, casting, LB deposition, or the like. When the emission layer is formed by vacuum deposition or spin coating, the deposition or coating conditions may be similar to those applied in forming the hole injection layer although the deposition or coating conditions may vary according to a compound that is used to form the emission layer.

When the organic light-emitting device is a full-color organic light-emitting device, the emission layer may be patterned into a red emission layer, a green emission layer, and a blue emission layer. In one or more embodiments, due to a stacked structure including a red emission layer, a green emission layer, and/or a blue emission layer, the emission layer may emit white light.

The emission layer may include the TADF emitter and the host described above.

In one or more embodiments, the emission layer may consist of the TADF emitter and the host described above.

A thickness of the emission layer may be in a range of about 100 Å to about 1,000 Å, for example, about 200 Å to about 600 Å. While not wishing to be bound by theory, it is understood that when the thickness of the emission layer is within this range, excellent light-emission characteristics may be obtained without a substantial increase in driving voltage.

Then, an electron transport region may be disposed on the emission layer.

The electron transport region may include at least one selected from a hole blocking layer, an electron transport layer, and an electron injection layer.

For example, the electron transport region may have a hole blocking layer/electron transport layer/electron injection layer structure or an electron transport layer/electron injection layer structure, but the structure of the electron transport region is not limited thereto. The electron transport layer may have a single-layered structure or a multi-layered structure including two or more different materials.

Conditions for forming the hole blocking layer, the electron transport layer, and the electron injection layer which constitute the electron transport region may be understood by referring to the conditions for forming the hole injection layer.

When the electron transport region includes a hole blocking layer, the hole blocking layer may include, for example, at least one of BCP and Bphen, but may also include other materials.

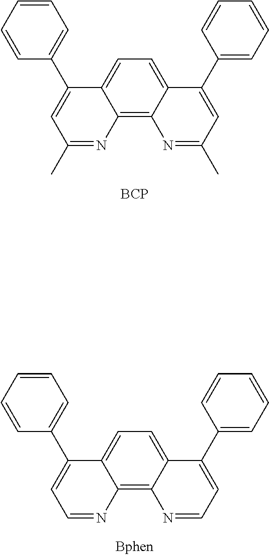

In one or more embodiments, as the hole blocking material, a compound that is identical to the host included in the emission layer may be used, but the embodiments are not limited thereto.

A thickness of the hole blocking layer may be in a range of about 20 Å to about 1,000 Å, for example, about 30 Å to about 300 Å. While not wishing to be bound by theory, it is understood that when the thickness of the hole blocking layer is within these ranges, the hole blocking layer may have improved hole blocking ability without a substantial increase in driving voltage.

The electron transport layer may include at least one selected from BCP, Bphen, Alq₃, BAlq, TAZ, and NTAZ.

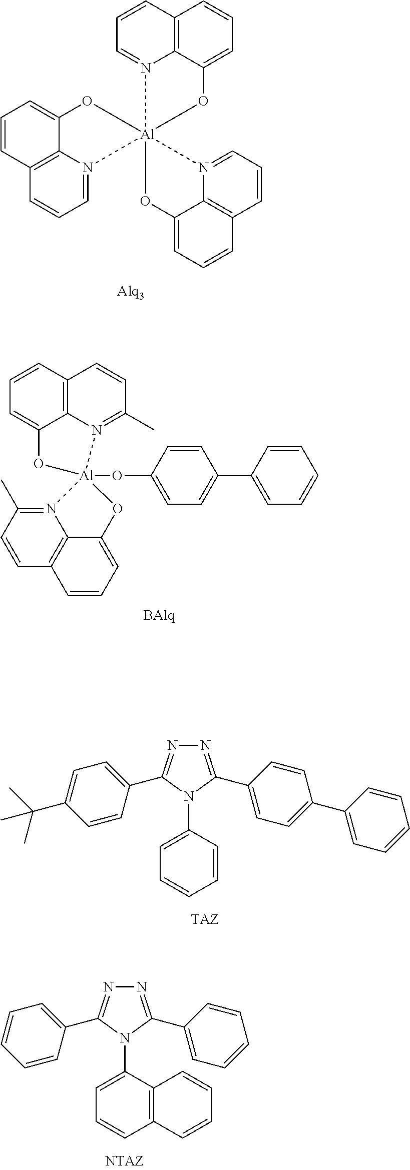

In one or more embodiments, the electron transport layer may include at least one of ET1 to ET25, but are not limited thereto:

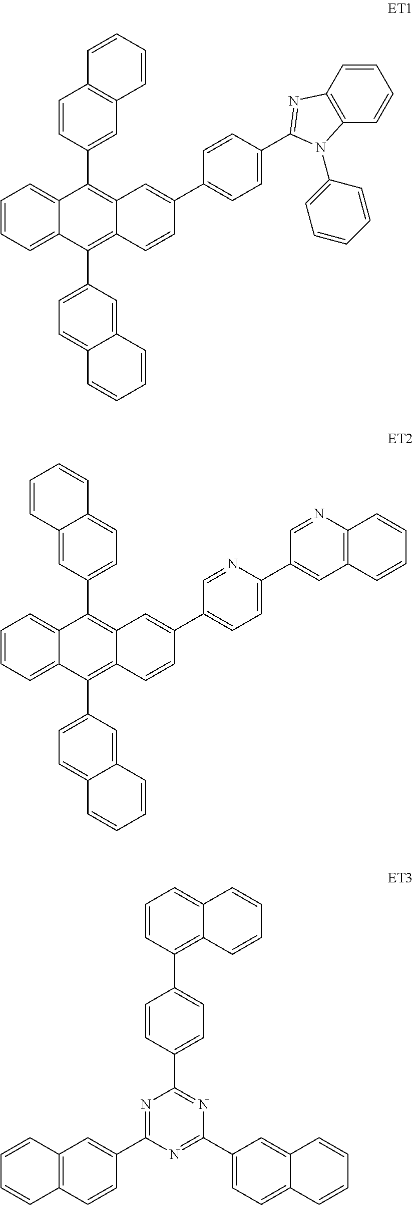 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc2cc(-c3nc(-c4ccc(-c5cccc6ccccc56)cc4)nc(-c4ccc5ccccc5c4)n3)ccc2c1]

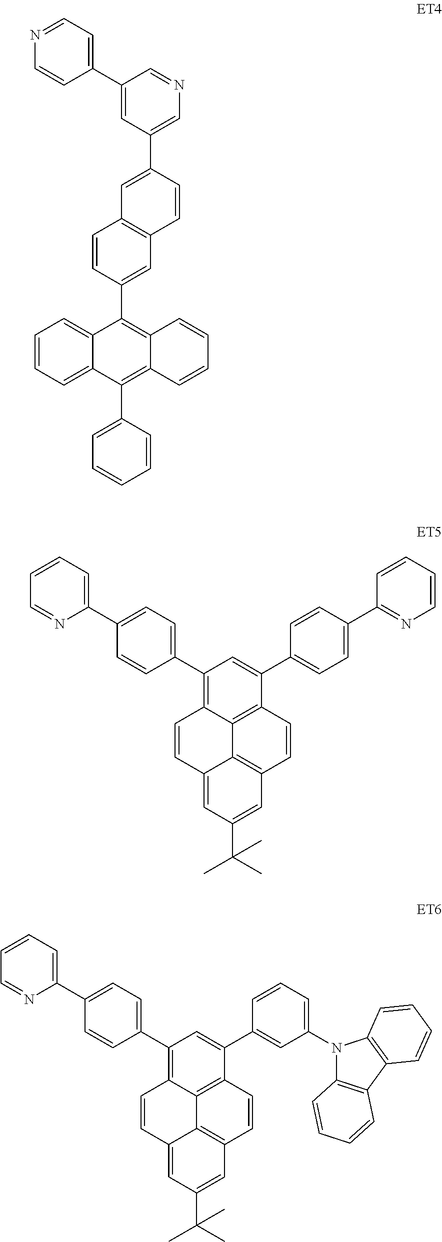 [SMILES: c1ccc(-c2c3ccccc3c(-c3ccc4cc(-c5cncc(-c6ccncc6)c5)ccc4c3)c3ccccc23)cc1 ; CC(C)(C)c1cc2ccc3c(-c4ccc(-c5ccccn5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4cccc(-n5c6ccccc6c6ccccc65)c4)c4ccc(c1)c2c34]

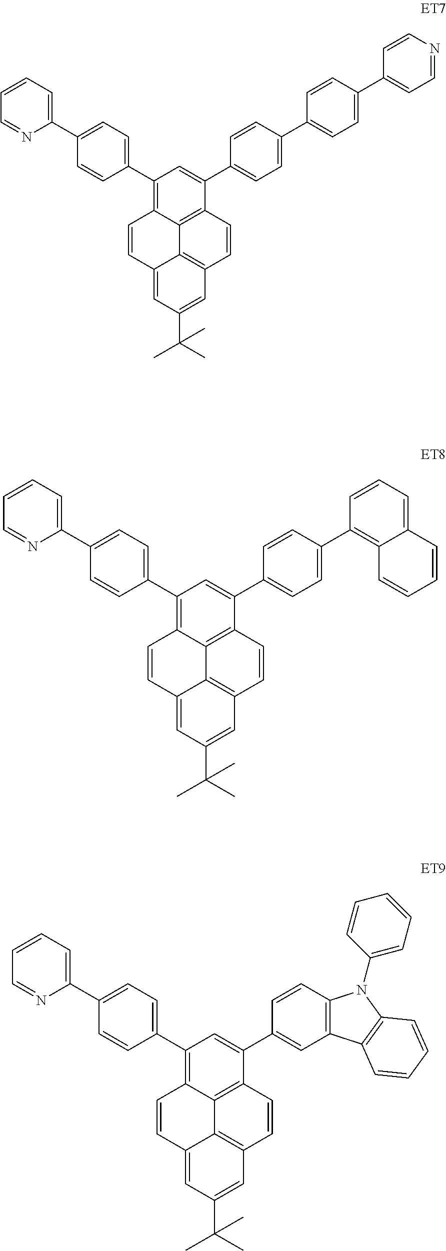 [SMILES: CC(C)(C)c1cc2ccc3c(-c4ccc(-c5ccc(-c6ccncc6)cc5)cc4)cc(-c4ccc(-c5ccccn5)cc4)c4ccc(c1)c2c34 ; CC(C)(C)c1cc2ccc3c(-c4ccc(-c5ccccn5)cc4)cc(-c4ccc(-c5cccc6ccccc56)cc4)c4ccc(c1)c2c34 ; CC(C)(C)c1cc2ccc3c(-c4ccc(-c5ccccn5)cc4)cc(-c4ccc5c(c4)c4ccccc4n5-c4ccccc4)c4ccc(c1)c2c34]

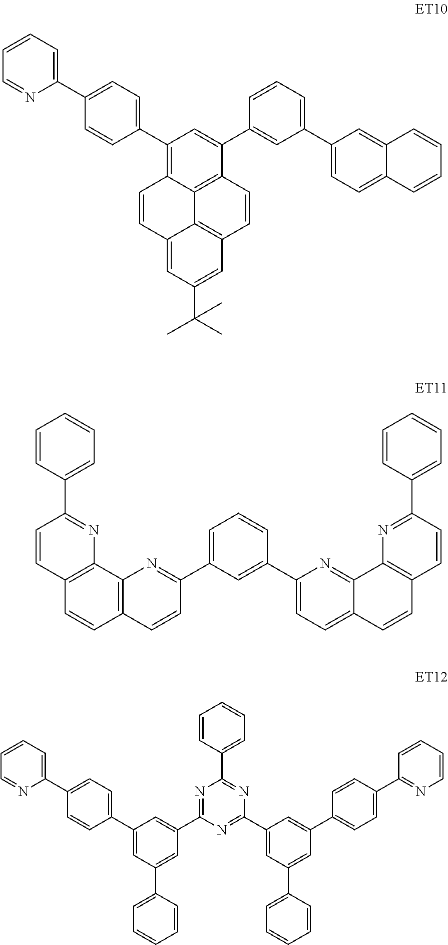 [SMILES: CC(C)(C)c1cc2ccc3c(-c4ccc(-c5ccccn5)cc4)cc(-c4cccc(-c5ccc6ccccc6c5)c4)c4ccc(c1)c2c34 ; c1ccc(-c2ccc3ccc4ccc(-c5cccc(-c6ccc7ccc8ccc(-c9ccccc9)nc8c7n6)c5)nc4c3n2)cc1 ; c1ccc(-c2cc(-c3ccc(-c4ccccn4)cc3)cc(-c3nc(-c4ccccc4)nc(-c4cc(-c5ccccc5)cc(-c5ccc(-c6ccccn6)cc5)c4)n3)c2)cc1]

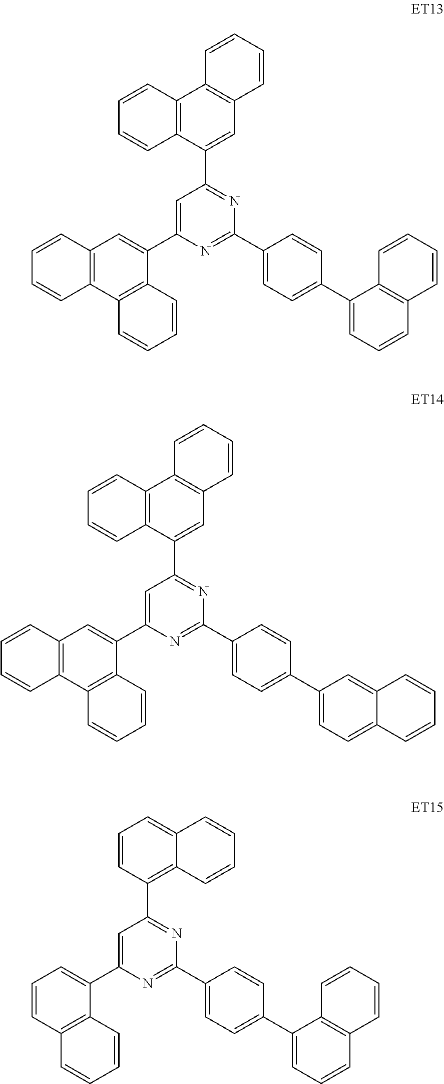 [SMILES: c1ccc2c(-c3ccc(-c4nc(-c5cc6ccccc6c6ccccc56)cc(-c5cc6ccccc6c6ccccc56)n4)cc3)cccc2c1 ; c1ccc2cc(-c3ccc(-c4nc(-c5cc6ccccc6c6ccccc56)cc(-c5cc6ccccc6c6ccccc56)n4)cc3)ccc2c1 ; c1ccc2c(-c3ccc(-c4nc(-c5cccc6ccccc56)cc(-c5cccc6ccccc56)n4)cc3)cccc2c1]

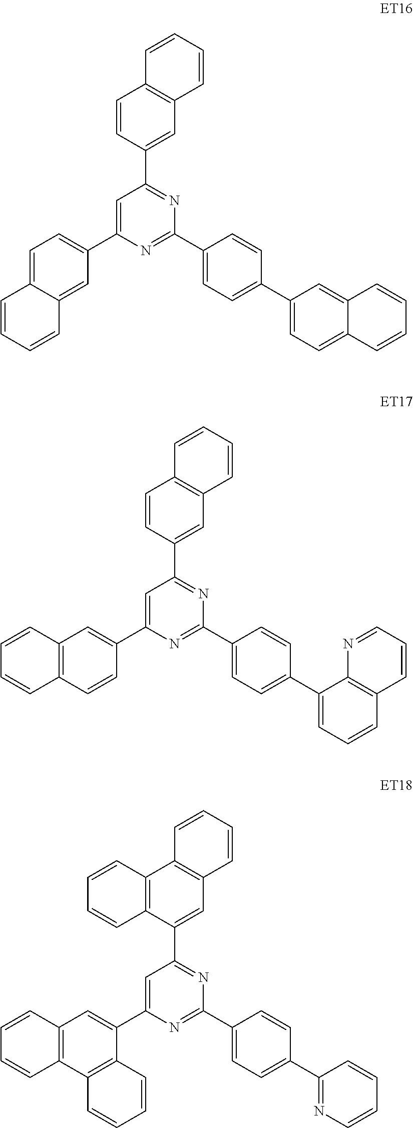 [SMILES: c1ccc2cc(-c3ccc(-c4nc(-c5ccc6ccccc6c5)cc(-c5ccc6ccccc6c5)n4)cc3)ccc2c1 ; c1ccc2cc(-c3cc(-c4ccc5ccccc5c4)nc(-c4ccc(-c5cccc6cccnc56)cc4)n3)ccc2c1 ; c1ccc(-c2ccc(-c3nc(-c4cc5ccccc5c5ccccc45)cc(-c4cc5ccccc5c5ccccc45)n3)cc2)nc1]

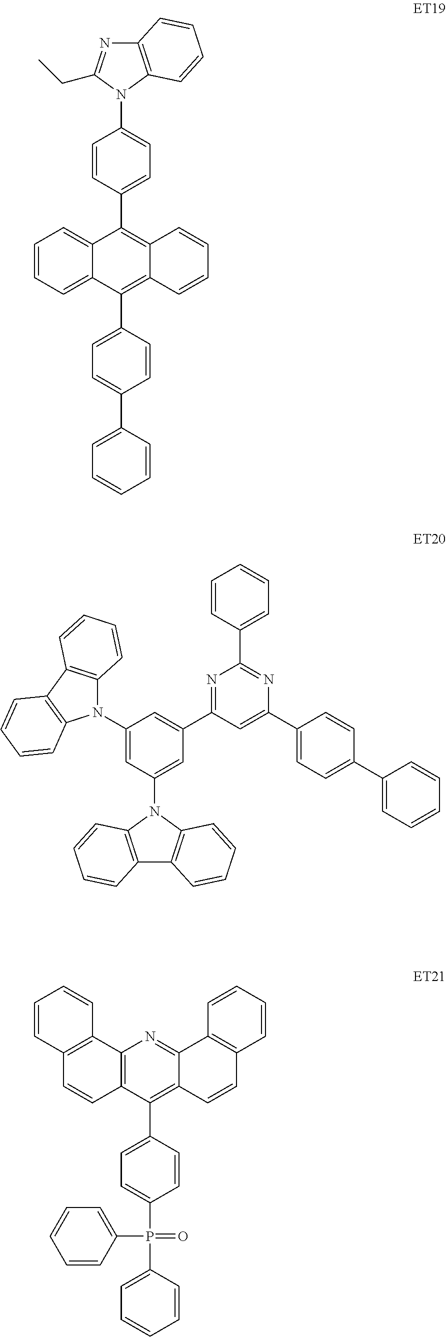 [SMILES: CCc1nc2ccccc2n1-c1ccc(-c2c3ccccc3c(-c3ccc(-c4ccccc4)cc3)c3ccccc23)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; O=P(c1ccccc1)(c1ccccc1)c1ccc(-c2c3ccc4ccccc4c3nc3c2ccc2ccccc23)cc1]

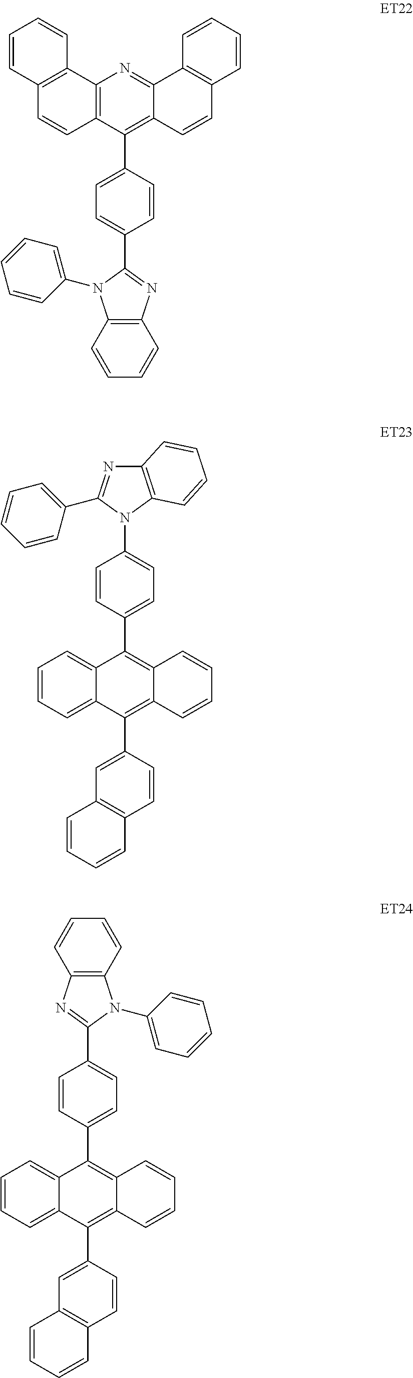 [SMILES: c1ccc(-n2c(-c3ccc(-c4c5ccc6ccccc6c5nc5c4ccc4ccccc45)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

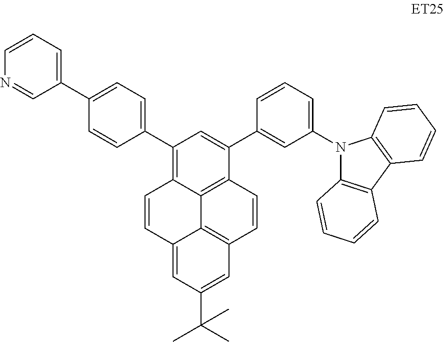 [SMILES: CC(C)(C)c1cc2ccc3c(-c4ccc(-c5cccnc5)cc4)cc(-c4cccc(-n5c6ccccc6c6ccccc65)c4)c4ccc(c1)c2c34]

A thickness of the electron transport layer may be in a range of about 100 Å to about 1,000 Å, for example, about 150 Å to about 500 Å. While not wishing to be bound by theory, it is understood that when the thickness of the electron transport layer is within the range described above, the electron transport layer may have satisfactory electron transport characteristics without a substantial increase in driving voltage.

Also, the electron transport layer may further include, in addition to the materials described above, a metal-containing material.

The metal-containing material may include a Li complex. The Li complex may include, for example, Compound ET-D1 (lithium 8-hydroxyquinolate, LiQ) or ET-D2.

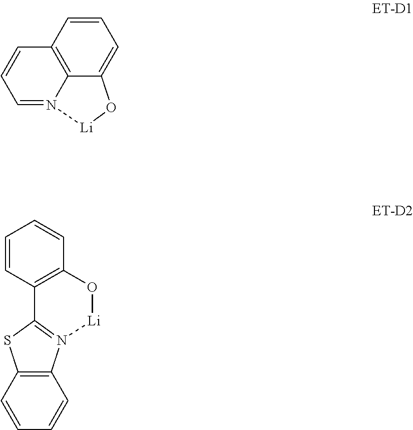

The electron transport region may include an electron injection layer that promotes flow of electrons from the second electrode 19 thereinto.

The electron injection layer may include at least one selected from LiF, NaCl, CsF, Li₂O, and BaO.

A thickness of the electron injection layer may be in a range of about 1 Å to about 100 Å, for example, about 3 Å to about 90 Å. While not wishing to be bound by theory, it is understood that when the thickness of the electron injection layer is within the range described above, the electron injection layer may have satisfactory electron injection characteristics without a substantial increase in driving voltage.

The second electrode 19 is disposed on the organic layer 15. The second electrode 19 may be a cathode. A material for forming the second electrode 19 may be selected from metal, an alloy, an electrically conductive compound, and a combination thereof, which have a relatively low work function. For example, lithium (Li), magnesium (Mg), aluminum (Al), aluminum-lithium (Al—Li), calcium (Ca), magnesium-indium (Mg—In), or magnesium-silver (Mg—Ag) may be used as a material for forming the second electrode 19. In one or more embodiments, to manufacture a top-emission type light-emitting device, a transmissive electrode formed using ITO or IZO may be used as the second electrode 19.

Hereinbefore, the organic light-emitting device has been described with reference to FIG. 1, but embodiments of the present disclosure are not limited thereto.

The term “C₁-C₂₀ alkyl group” as used herein refers to a linear or branched saturated aliphatic hydrocarbon monovalent group having 1 to 60 carbon atoms, and non-limiting examples thereof include a methyl group, an ethyl group, a propyl group, an iso-butyl group, a sec-butyl group, a tert-butyl group, a pentyl group, an iso-amyl group, and a hexyl group. The term “C₁-C₂₀ alkylene group” as used herein refers to a divalent group having the same structure as the C₁-C₂₀ alkyl group.

The term “C₁-C₂₀ alkoxy group” as used herein refers to a monovalent group represented by —OA₁₀₁ (wherein A₁₀₁ is the C₁-C₂₀ alkyl group), and non-limiting examples thereof include a methoxy group, an ethoxy group, and an iso-propyloxy group.

The term “C₂-C₆₀ alkenyl group” as used herein refers to a hydrocarbon group formed by including at least one carbon-carbon double bond in the middle or at the terminus of the C₂-C₆₀ alkyl group, and examples thereof include an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a hydrocarbon group formed by including at least one carbon-carbon triple bond in the middle or at the terminus of the C₂-C₆₀ alkyl group, and examples thereof include an ethynyl group, and a propynyl group. The term “C₂-C₆₀ alkynylene group” as used herein refers to a divalent group having the same structure as the C₂-C₆₀ alkynyl group.

The term “C₃-C₁₀ cycloalkyl group” as used herein refers to a monovalent saturated hydrocarbon monocyclic group having 3 to 10 carbon atoms, and non-limiting examples thereof include a cyclopropyl group, a cyclobutyl group, a cyclopentyl group, a cyclohexyl group, and a cycloheptyl group. The term “C₃-C₁₀ cycloalkylene group” as used herein refers to a divalent group having the same structure as the C₃-C₁₀ cycloalkyl group.

The term “C₁-C₁₀ heterocycloalkyl group” as used herein refers to a monovalent saturated monocyclic group having at least one heteroatom selected from N, O, P, Si and S as a ring-forming atom and 1 to 10 carbon atoms, and non-limiting examples thereof include a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” as used herein refers to a monovalent monocyclic group that has 3 to 10 carbon atoms, at least one carbon-carbon double bond in the ring thereof, and no aromaticity, and non-limiting examples thereof include a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent monocyclic group that has at least one heteroatom selected from N, O, P, Si, and S as a ring-forming atom, 1 to 10 carbon atoms, and at least one carbon-carbon double bond in its ring. Examples of the C₁-C₁₀ heterocycloalkenyl group are a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group each include two or more rings, the rings may be fused to each other.

The term “C₁-C₆₀ heteroaryl group” as used herein refers to a monovalent group having a heterocyclic aromatic system that has at least one heteroatom selected from N, O, P, and S as a ring-forming atom, and 1 to 60 carbon atoms. The term “C₁-C₆₀ heteroarylene group” as used herein refers to a divalent group having a heterocyclic aromatic system that has at least one heteroatom selected from N, O, P, and S as a ring-forming atom, and 1 to 60 carbon atoms. Non-limiting examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₁-C₆₀ heteroaryl group and the C₁-C₆₀ heteroarylene group each include two or more rings, the rings may be fused to each other.

The term “C₆-C₆₀ aryloxy group” as used herein indicates —OA₁₀₂ (wherein A₁₀₂ is the C₆-C₆₀ aryl group), a C₆-C₆₀ arylthio group as used herein indicates —SA₁₀₃ (wherein A₁₀₃ is the C₆-C₆₀ aryl group), and the term “C₇-C₆₀ arylalkyl group” as used herein indicates -A₁₀₄A₁₀₅ (wherein A₁₀₄ is the C₆-C₅₉ aryl group and A₁₀₅ is the C₁-C₅₃ alkyl group).

The term “C₁-C₆₀ heteroaryloxy group” as used herein refers to —OA₁₀₆ (wherein A₁₀₆ is the C₂-C₆₀ heteroaryl group), and the term “C₁-C₆₀ heteroarylthio group” as used herein indicates —SA₁₀₇ (wherein A₁₀₇ is the C₂-C₆₀ heteroaryl group).

The term “C₂-C₆₀ heteroarylalkyl group” as used herein refers to -A₁₀₈A₁₀₉ (A₁₀₉ is a C₂-C₅₉ heteroaryl group, and A₁₀₈ is a C₁-C₅₈ alkylene group).

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group include a fluorenyl group. The term “divalent non-aromatic condensed polycyclic group,” as used herein, refers to a divalent group having the same structure as the monovalent non-aromatic condensed polycyclic group.

The term “monovalent non-aromatic condensed heteropolycyclic group” as used herein refers to a monovalent group (for example, having 2 to 60 carbon atoms) having two or more rings condensed to each other, a heteroatom selected from N, O, P, Si, and S, other than carbon atoms, as a ring-forming atom, and no aromaticity in its entire molecular structure. Non-limiting examples of the monovalent non-aromatic condensed heteropolycyclic group include a carbazolyl group. The term “divalent non-aromatic condensed heteropolycyclic group” as used herein refers to a divalent group having the same structure as the monovalent non-aromatic condensed heteropolycyclic group.

The term “C₅-C₃₀ carbocyclic group” as used herein refers to a saturated or unsaturated cyclic group having, as a ring-forming atom, 5 to 30 carbon atoms only. The C₅-C₃₀ carbocyclic group may be a monocyclic group or a polycyclic group.

The term “C₁-C₃₀ heterocyclic group” as used herein refers to a saturated or unsaturated cyclic group having, as a ring-forming atom, at least one heteroatom selected from N, O, Si, P, and S other than 1 to 30 carbon atoms. The C₁-C₃₀ heterocyclic group may be a monocyclic group or a polycyclic group.

At least one substituent of the substituted π electron-depleted nitrogen-containing C₂-C₆₀ heterocyclic group, the substituted C₃-C₁₀ cycloalkylene group, the substituted C₁-C₁₀ heterocycloalkylene group, the substituted C₃-C₁₀ cycloalkenylene group, the substituted C₁-C₁₀ heterocycloalkenylene group, the substituted C₆-C₆₀ arylene group, the substituted C₁-C₆₀ heteroarylene group, the substituted divalent non-aromatic condensed polycyclic group, the substituted divalent non-aromatic condensed heteropolycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀ heterocycloalkenyl group, the substituted C₆-C₆₀ aryl group, the substituted C₆-C₆₀ aryloxy group, the substituted C₆-C₆₀ arylthio group, the substituted C₇-C₆₀ arylalkyl group, the substituted C₁-C₆₀ heteroaryl group, the substituted C₁-C₆₀ heteroaryloxy group, the substituted C₁-C₆₀ heteroarylthio group, the substituted C₂-C₆₀ heteroarylalkyl group, the substituted monovalent non-aromatic condensed polycyclic group, and the substituted monovalent non-aromatic condensed heteropolycyclic group may be:
deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, or a C₁-C₆₀ alkoxy group;
a C₁-C₆₀ alkyl group, a C₂-C₆₀ alkenyl group, a C₂-C₆₀ alkynyl group, or a C₁-C₆₀ alkoxy group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), and —B(Q₁₆)(Q₁₇);
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, or a monovalent non-aromatic condensed heteropolycyclic group, each substituted with at least one selected from deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₆₀ heteroaryl group, a C₁-C₆₀ heteroaryloxy group, a C₁-C₆₀ heteroarylthio group, a C₂-C₆₀ heteroarylalkyl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), and —B(Q₂₆)(Q₂₇); or
—N(Q₃₁)(Q₃₂), —Si(Q₃₃)(Q₃₄)(Q₃₅), or —B(Q₃₆)(Q₃₇), and
Q₁₁ to Q₁₇, Q₂₁ to Q₂₇, and Q₃₁ to Q₃₇ may each independently be hydrogen, a C₁-C₂₀ alkyl group, a C₂-C₆₀ alkenyl group, a C₂-C₆₀ alkynyl group, a C₁-C₂₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₇-C₆₀ arylalkyl group, a C₁-C₂₀ heteroaryl group, a C₁-C₆₀ heteroaryloxy group, a C₁-C₂₀ heteroarylthio group, a C₂-C₆₀ heteroarylalkyl group, a monovalent non-aromatic condensed polycyclic group, or a monovalent non-aromatic condensed heteropolycyclic group.

The term “room temperature” as used herein refers to about 25° C.

Hereinafter, an organic light-emitting device according to embodiments are described in detail with reference to Examples. However, the organic light-emitting device is not limited thereto.

### EXAMPLE

### Evaluation Example 1

After a quartz substrate cleaned by using chloroform and pure water was prepared, materials shown in Table 1 were vacuum-deposited (co-deposited) at a vacuum degree of 10⁻⁷ torr to prepare films 1, 2, 3, 3 (DPEPO), 4, A, A (DPEPO), B, and B (DPEPO) each having a thickness of 50 nanometers (nm).

TABLE 1

| Film No. | Compound used to form film |
|---|---|
| Film 1 | Compound 1 and Compound H19 (volume ratio = 15:85) |
| Film 2 | Compound 2 and Compound H19 (volume ratio = 15:85) |
| Film 3 | Compound 3 and Compound H19 (volume ratio = 15:85) |
| Film 3 | Compound 3 and DPEPO (volume ratio = 15:85) |
| (DPEPO) | |
| Film 4 | Compound 4 and Compound H19 (volume ratio = 15:85) |
| Film A | Compound A and Compound H19 (volume ratio = 15:85) |
| Film A | Compound A and DPEPO (volume ratio = 15:85) |
| (DPEPO) | |
| Film B | Compound B and Compound H19 (volume ratio = 15:85) |
| Film B | Compound B and DPEPO (volume ratio = 15:85) |
| (DPEPO) | |

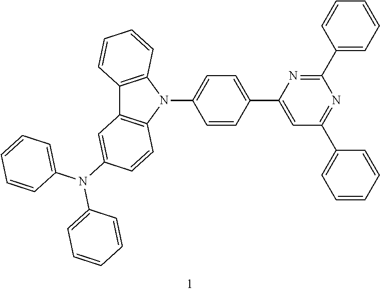 [SMILES: c1ccc(-c2cc(-c3ccc(-n4c5ccccc5c5cc(N(c6ccccc6)c6ccccc6)ccc54)cc3)nc(-c3ccccc3)n2)cc1]

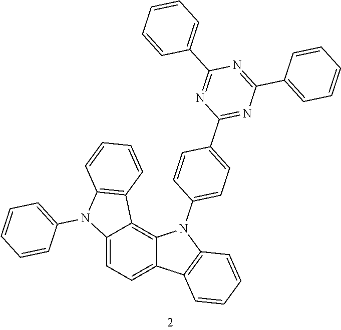 [SMILES: c1ccc(-c2nc(-c3ccccc3)nc(-c3ccc(-n4c5ccccc5c5ccc6c(c7ccccc7n6-c6ccccc6)c54)cc3)n2)cc1]

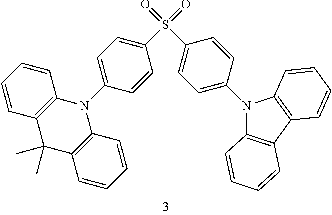 [SMILES: CC1(C)c2ccccc2N(c2ccc(S(=O)(=O)c3ccc(-n4c5ccccc5c5ccccc54)cc3)cc2)c2ccccc21]

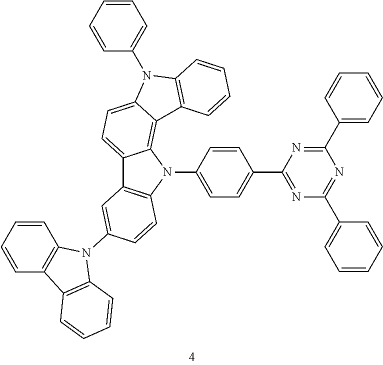 [SMILES: c1ccc(-c2nc(-c3ccccc3)nc(-c3ccc(-n4c5ccc(-n6c7ccccc7c7ccccc76)cc5c5ccc6c(c7ccccc7n6-c6ccccc6)c54)cc3)n2)cc1]

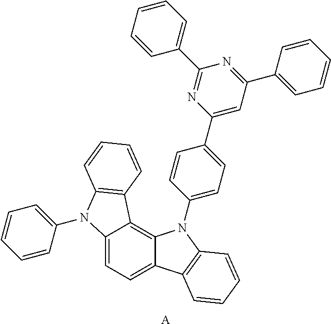

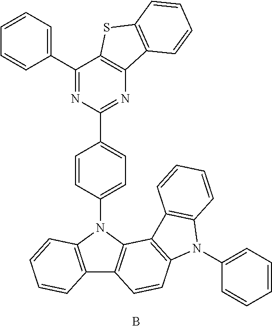

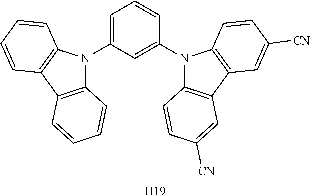 [SMILES: N#Cc1ccc2c(c1)c1cc(C#N)ccc1n2-c1cccc(-n2c3ccccc3c3ccccc32)c1 ; "H19"]

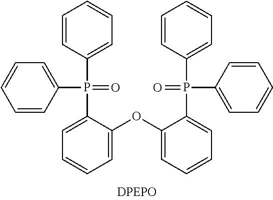 [SMILES: O=P(c1ccccc1)(c1ccccc1)c1ccccc1Oc1ccccc1P(=O)(c1ccccc1)c1ccccc1]

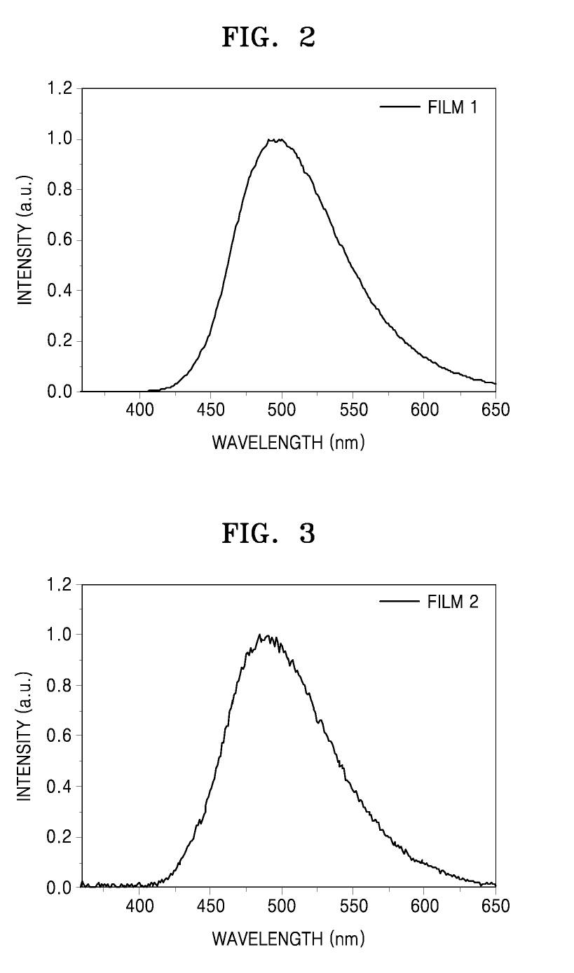

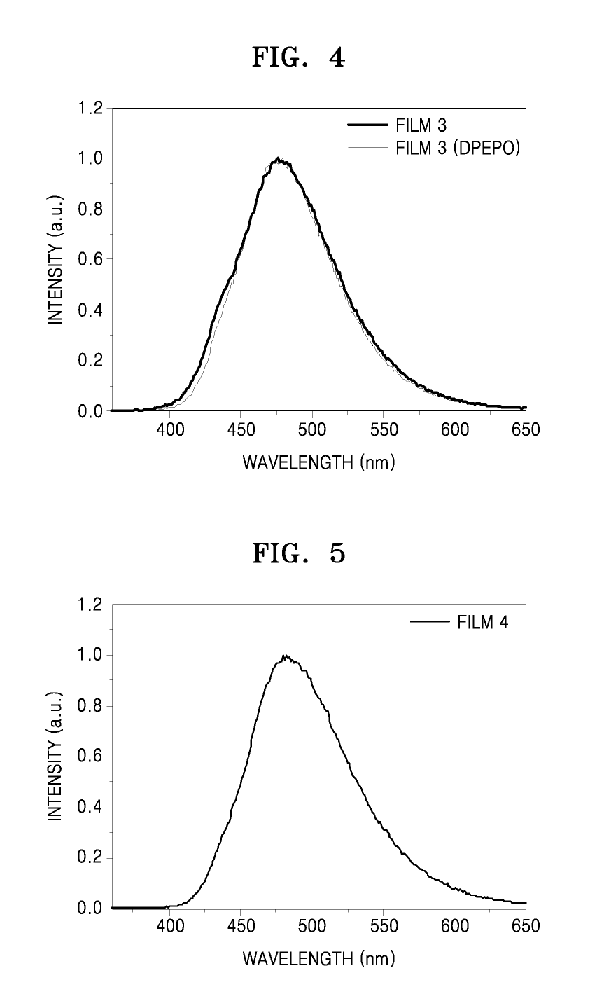

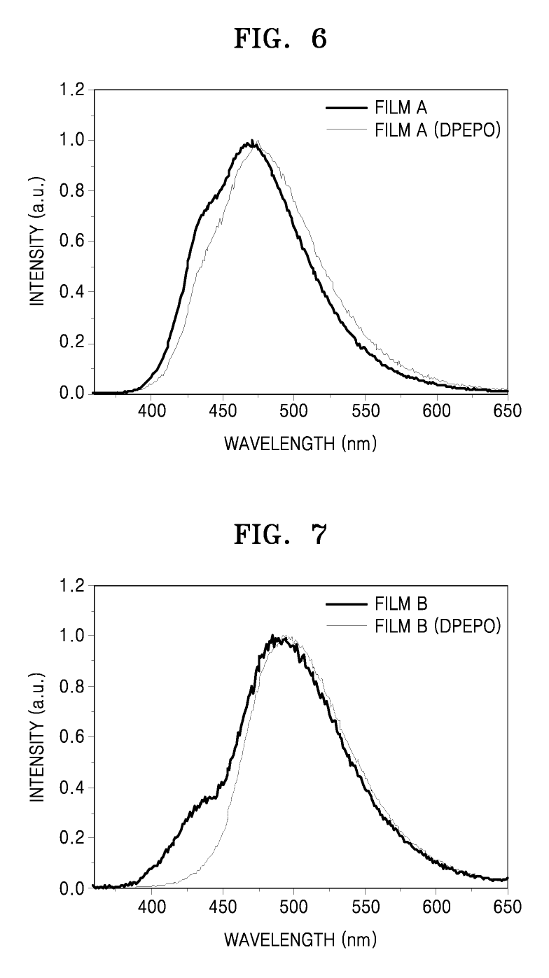

Then, photoluminescence (PL) spectra of the films 1, 2, 3, 3 (DPEPO), 4, A, A (DPEPO), B, and B (DPEPO) were evaluated by using an ISC PC1 spectrofluorometer equipped with a xenon lamp. Evaluation results are shown in FIG. 2 (PL spectrum of the film 1), FIG. 3 (PL spectrum of the film 2), FIG. 4 (PL spectra of the film 3 and the film 3 (DPEPO)), FIG. 5 (PL spectrum of the film 4), FIG. 6 (PL spectra of the film A and the film A (DPEPO)), and FIG. 7 (PL spectra of the film B and the film B (DPEPO)), and whether each film satisfies Condition 1-1 or Condition 1-2 are shown in Table 2.

TABLE 2

| | Whether a film | Whether a film |
|---|---|---|
| Film | satisfies | satisfies |
| No. | Condition 1-1 | Condition 1-2 |
| Film 1 | ◯ | — |
| Film 2 | ◯ | — |
| Film 3 | X | ◯ |
| | | (I₁/I₂) × 100 = 105% |
| | | I₁ = emission intensity at the shortest peak |
| | | emission wavelength (440 nm) in the PL |
| | | spectrum of the film 3 |
| | | I₂ = emission intensity at the shortest peak |
| | | emission wavelength (440 nm) in the PL |
| | | spectrum of the film 3 (DPEPO) |
| Film 4 | ◯ | — |
| Film A | X | X |
| | | (I₁/I₂) × 100 = 127% |
| | | I₁ = emission intensity at the shortest peak |
| | | emission wavelength (435 nm) in the PL |
| | | spectrum of the film A |
| | | I₂ = emission intensity at the shortest peak |
| | | emission wavelength (435 nm) in the PL |
| | | spectrum of the film A (DPEPO) |
| Film B | X | X |
| | | (I₁/I₂) × 100 = 292% |
| | | I₁ = emission intensity at the shortest peak |
| | | emission wavelength (437 nm) in the PL |
| | | spectrum of the film B |
| | | I₂ = emission intensity at the same emission |
| | | wavelength (437 nm) as the shortest peak |
| | | emission wavelength of the PL spectrum |
| | | of the film B in the PL spectrum of |
| | | film B (DPEPO) |

Referring to Table 2, it is confirmed that, since the films 1 to 4 satisfies one of Condition 1-1 and Condition 1-2 but the films A and B do not satisfy both Condition 1-1 and Condition 1-2, Compounds 1 to 4 used in the films 1 to 4 are excellent TADF emitters, in which dual fluorescence is prevented, and Compounds A and B used in the films A and B have poor TADF characteristics.

### Evaluation Example 2

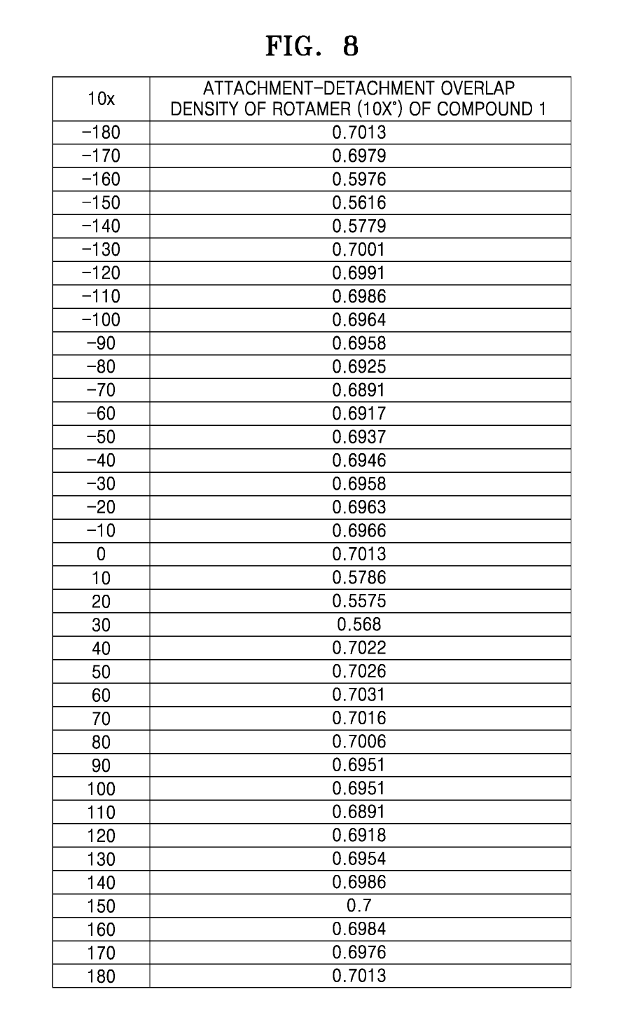

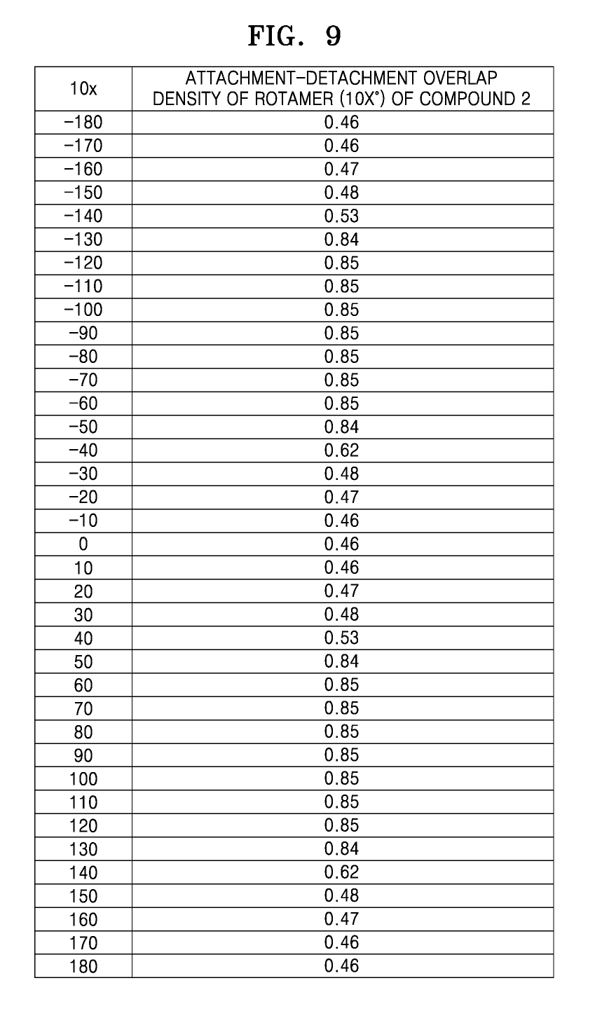

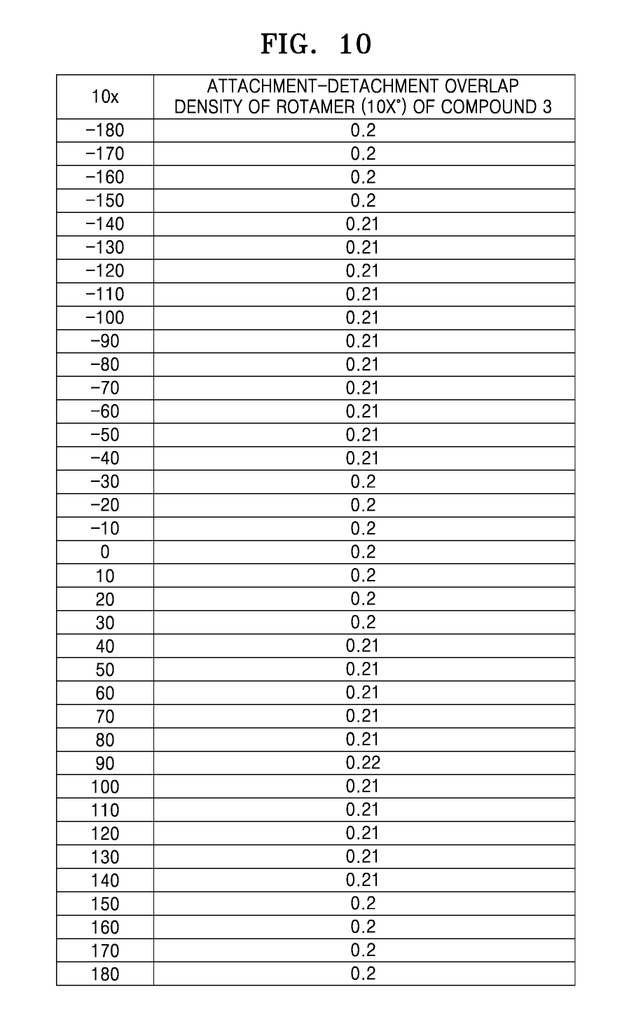

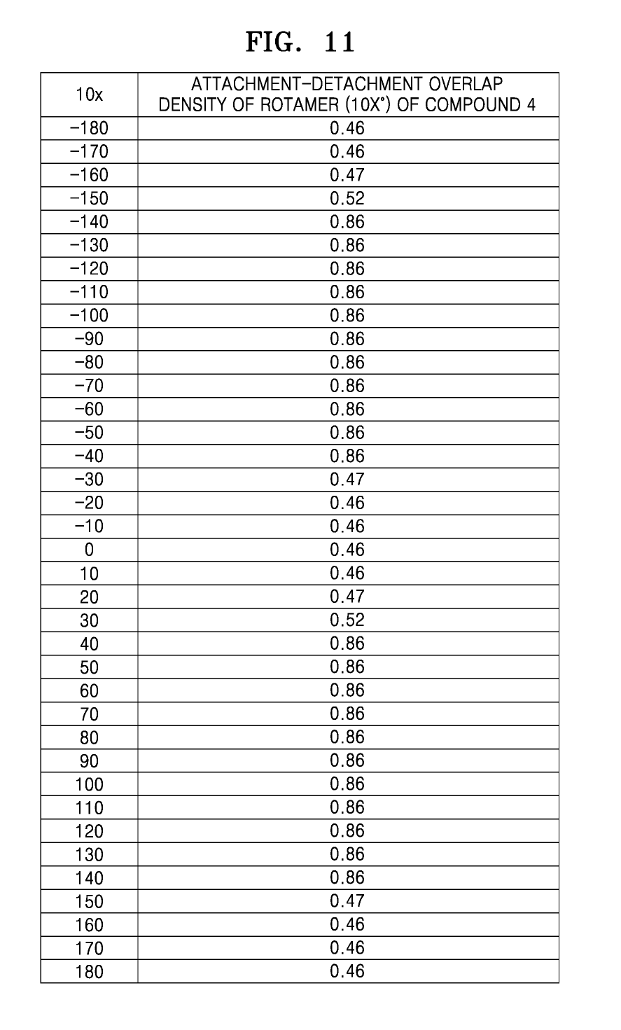

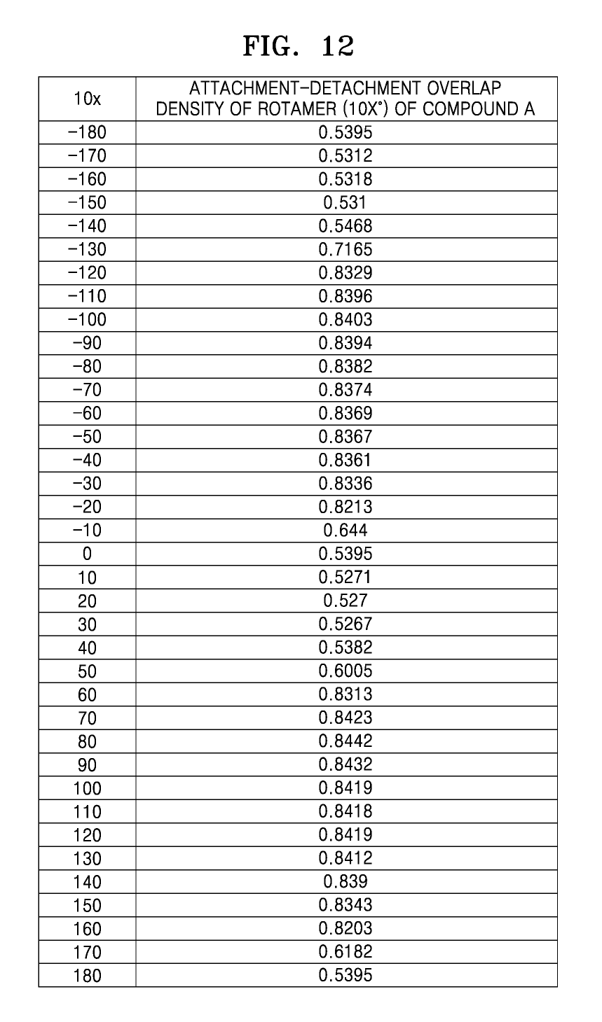

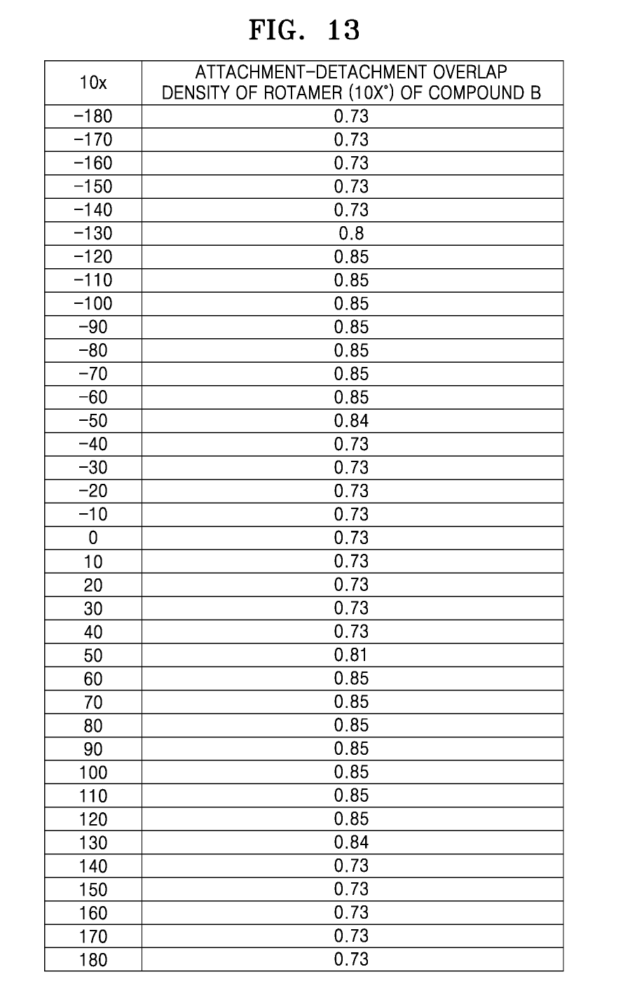

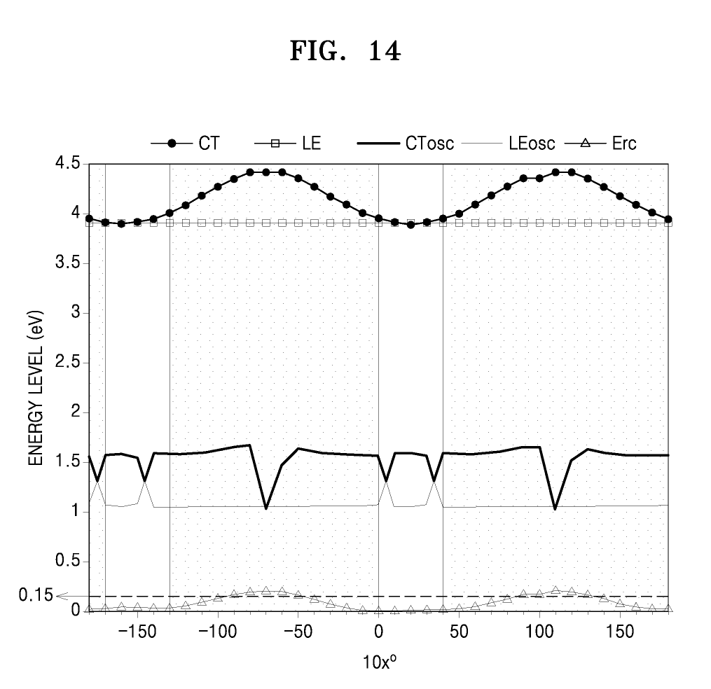

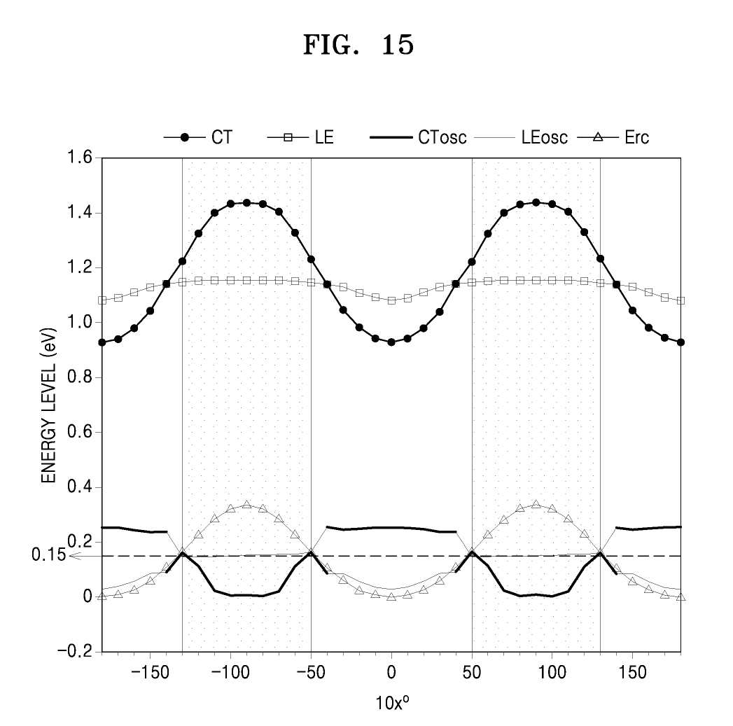

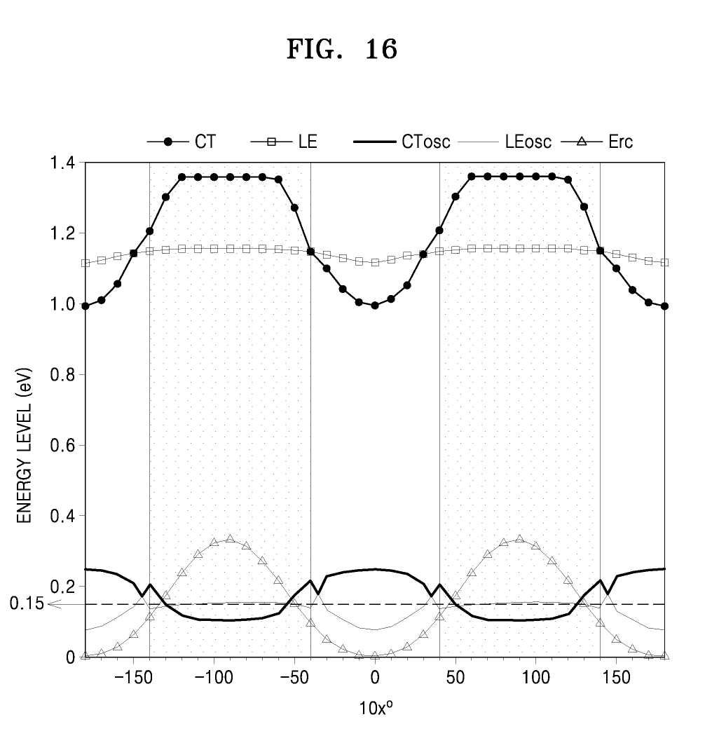

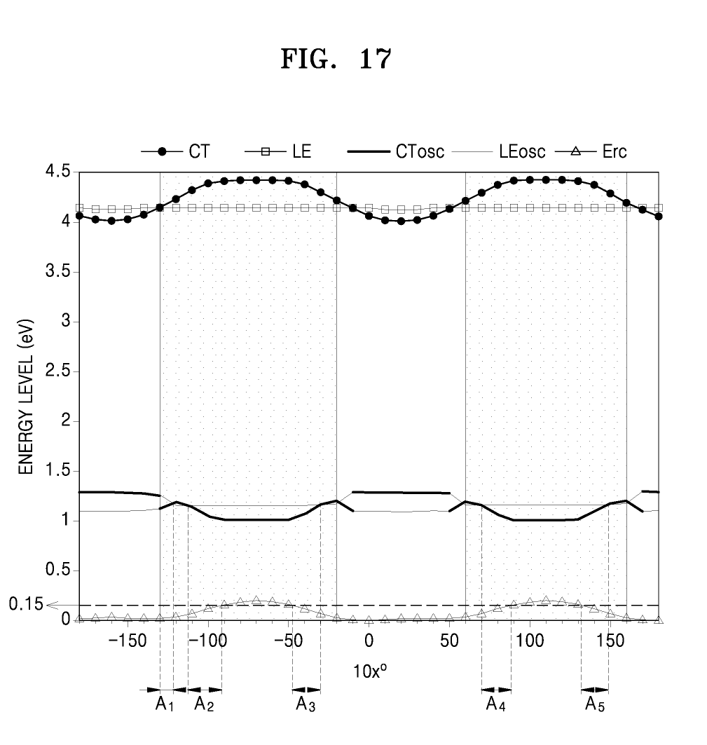

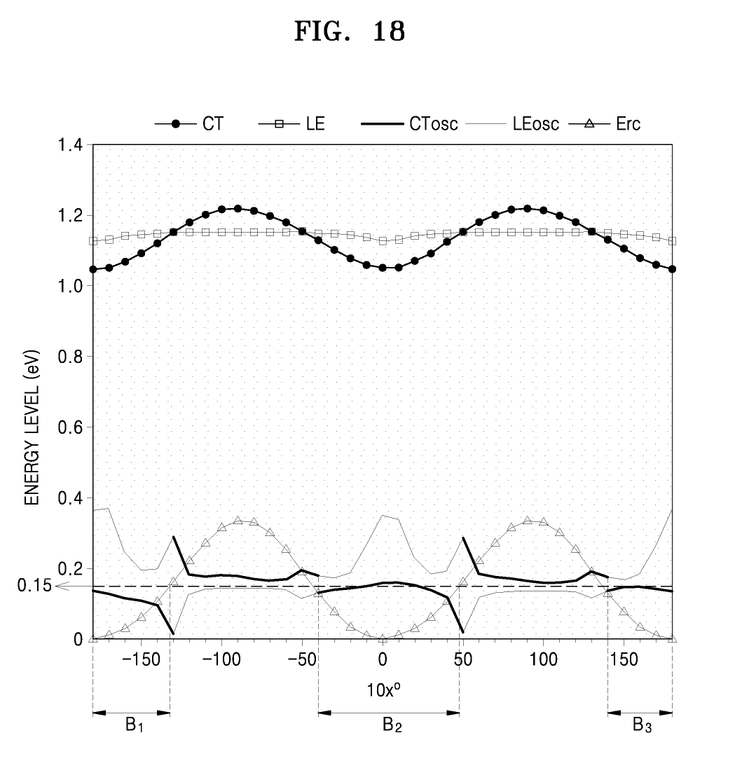

Regarding each of Compounds 1 to 4 and Compounds A and B, with respect to rotamer (10x°) for an integer x satisfying −18≤x≤18,
1) attachment-detachment overlap density (see FIGS. 8 to 13)
2) rotational conformational energy (see graphs indicated by “Erc” in FIGS. 14 to 18)
3) LEosc (oscillator strength in a locally excited state of the rotamer (10x°)) (see graphs indicated by “LEosc” in FIGS. 14 to 18), and
4) CTosc (oscillator strength in a charge transfer state of the rotamer (10x°)) (see graphs indicated by “CTosc” in FIGS. 14 to 18)
were evaluated by using DFT and TD-DFT methods of a Gaussian program in which a structure was optimized at a CAM-B3LYP/6-31G(d,p) level. Evaluation results are shown in FIGS. 8 to 18. In FIGS. 14 to 18, graphs indicated by “LE” show a locally excited state energy level of the corresponding rotamer (10x°) of each Compound, and graphs indicated by “CT” show a charge transfer state energy level of the corresponding rotamer (10x°) of each compound.

First, the attachment-detachment overlap densities of the each rotamers (10x°) of Compounds 1 to 4 and Compounds A and B are shown in Table 3 with reference to FIGS. 8 to 13.

TABLE 3

| | Range including 10x at which | |
|---|---|---|
| | the attachment-detachment overlap | Whether Compound |
| Compound | density of the corresponding rotamer | satisfies |
| No. | (10x°) is 0.65 or more | Condition 2-1¹ |
| 1 | −180~−170 | X |
| | −130~0 | |
| | 40~180 | |
| 2 | −130~−50 | X |
| | 50~130 | |
| 3 | None | ◯ |
| 4 | −140~−40 | X |
| | 40~140 | |
| A | −130~−20 | X |
| | 60~160 | |
| B | −180~180 | X |

¹a condition that attachment-detachment overlap densities of all rotamer(10x°) are less than 0.65

Referring to Table 3, it is confirmed that Compound 3 satisfies Condition 2-1.

Then, whether Compounds 1, 2, 4, A, and B satisfy Condition 2-2 is shown in Table 4 with reference to FIGS. 14 to 18 showing rotational conformational energy, LEosc (oscillator strength in a locally excited state of the rotamer (10x°)), and CTosc (oscillator strength in a charge transfer state of the rotamer (10x°)) for the corresponding rotamer (10x°) of each of Compounds 1, 2, 4, A, and B. Shaded regions in FIGS. 14 to 18 indicate a range including 10x at which the attachment-detachment overlap density of the corresponding rotamer (10x°) is 0.65 or more.

TABLE 4

| | Range including 10x at which | |
|---|---|---|
| Com- | the attachment-detachment overlap | Whether Compound |
| pound | density of the rotamer | satisfies |
| No. | (10x°) is 0.65 or more | Condition 2-2 |
| 1 | −180~−170 | ◯ |
| | −130~0 | |
| | 40~180 | |
| 2 | −130~−50 | ◯ |
| | 50~130 | |
| 4 | −140~−40 | ◯ |
| | 40~140 | |
| A | −130~−20 | X |
| | 60~160 | (Sections A₁ to A₅ |
| | | not satisfying Condition |
| | | 2-2 are present) |
| B | −180~180 | X |
| | | (Sections B₁ to B₃ |
| | | not satisfying Condition |
| | | 2-2 are present) |

Referring to Table 4, it is confirmed that Compounds 1, 2, and 4 satisfy Condition 2-2, but Compounds A and B do not satisfy Condition 2-2.

Referring to FIGS. 3 and 4, it is confirmed that Compound 3 satisfies Condition 2-1 and Compounds 1, 2, and 4 satisfy Condition 2-2, but Compounds A and B satisfy neither Condition 2-1 nor Condition 2-2.

### Evaluation Example 3

PL spectra of the films 1, 2, 3, 4, A and B manufactured according to Evaluation Example 1 were evaluated at room temperature by using FluoTime 300, which is a time resolved photoluminescence (TRPL) measurement system of PicoQuant, and PLS340 (excitation wavelength=340 nanometers, spectral width=20 nanometers), which is a pumping source of PicoQuant, wavelengths of main peaks of the spectra were determined, and the number of photons emitted from each film at the main peak by a photon pulse (pulse width=500 picoseconds) applied to each film by PLS340 was measured over time based on Time-Correlated Single Photon Counting (TCSPC). By repeating the above processes, a sufficiently fittable TRPL curve was obtained.

T_{decay}(Ex) of the films 1, 2, 3, 4, A, and B was obtained by fitting two or more exponential decay functions to a result obtained from the TRPL curve. The function used in fitting was equal to Equation 1, and the greatest value of T_{decay} obtained from the exponential decay functions used in fitting was taken as T_{decay}(Ex). The other T_{decay} values may be used to determine a lifetime of a general fluorescence decay lifetime. In this case, a baseline or background signal curve was obtained by repeating the same measurement once more in a dark state (a state in which a pumping signal incident on the film was blocked) for the same time as the measurement time for obtaining the TRPL curve, and the obtained a baseline or background signal curve was used as a baseline in fitting.

Then, a ratio of a delayed fluorescence component with respect to a total emission component was evaluated by calculating a ratio of a value obtained by integrating an exponential decay curve (=change in intensity based on time) determined by T_{decay}(Ex) to entire emission intensity integral value according to time. Evaluation results are shown in Table 5.

$$f ( t ) = {\sum }_{i = 1}^{n} {A}_{i} exp ( - t / {T}_{decay , i} ) \qquad Equation 1$$

TABLE 5

| | Ratio of delayed fluorescence |
|---|---|
| | component with respect to a total |
| Film No. | emission component (%) |
| Film 1 | 33.9 |
| Film 2 | 74.3 |
| Film 3 | 30.7 |
| Film 4 | 48.6 |
| Film A | 4.4 |
| Film B | 10.8 |

Referring to Table 5, it is determined that the films 1 to 4 respectively including Compounds 1 to 4 as an emitter have excellent delayed fluorescence characteristics, as compared with those of the films A and B respectively including Compounds A and B as an emitter.

### Evaluation Example 4

Photoluminescent quantum yields in the films 1, 2, 4, A, and B manufactured according to Evaluation Example 1 were evaluated by using a Hamamatsu Photonics absolute PL quantum yield measurement system equipped with a xenon light source, a monochromator, a photonic multichannel analyzer, and an integrating sphere and using PLQY measurement software (Hamamatsu Photonics, Ltd., Shizuoka, Japan). Evaluation results are shown in Table 6.

TABLE 6

| Film No. | PLQY in film |
|---|---|
| Film 1 | 0.735 |
| Film 2 | 0.782 |
| Film 4 | 0.531 |
| Film A | 0.425 |
| Film B | 0.147 |

Referring to Table 6, it is confirmed that the films 1, 2, and 4 respectively including Compounds 1, 2, and 4 as an emitter have excellent photoluminescent quantum yields, as compared with the films A and B respectively including Compounds A and B as an emitter.

### Example 1

As an anode, a glass substrate, on which an ITO electrode was formed, was cut to a size of 50 mm×50 mm×0.5 mm (mm=millimeter), sonicated with acetone, iso-propyl alcohol, and pure water each for 15 minutes, and then cleaned by exposure to ultraviolet (UV) rays and ozone for 30 minutes.

Then, Compound HT3 and HT-D2 (a concentration of HT-D2 was 3 percent by weight, wt %) were co-deposited on the anode to form a hole injection layer having a thickness of 100 Å, Compound HT3 was deposited on the hole injection layer to form a hole transport layer having a thickness of 1,500 Å, and mCP was deposited on the hole transport layer to form an electron blocking layer having a thickness of 100 Å, thereby forming a hole transport region having a thickness of 1,700 Å.

Compound H19 (host) and Compound 1 (dopant) were co-deposited on the hole transport region at a volume ratio of 9:1 to form an emission layer having a thickness of 400 Å.

Compound H19 was vacuum-deposited on the emission layer to form a hole blocking layer having a thickness of 100 Å, Compound ET17 and LiQ were co-deposited on the hole blocking layer at a weight ratio of 5:5 to form an electron transport layer having a thickness of 360 Å, LiQ was deposited on the electron transport layer to form an electron injection layer having a thickness of 5 Å, and Al was vacuum-deposited on the electron injection layer to form a cathode having a thickness of 120 Å, thereby completing the manufacture of an organic light-emitting device.

### Examples 2 and 3 and Comparative Examples A and B

Organic light-emitting devices were manufactured in the same manner as in Example 1, except that Compounds shown in Table 7 were each used as a dopant in forming an emission layer.

### Evaluation Example 5

The maximum emission wavelength and the maximum external quantum efficiency of the organic light-emitting devices manufactured according to Examples 1 to 3 and Comparative Examples A and B were measured by using a current-voltage meter (Keithley 2400) and a luminance meter (Minolta Cs-1000A). Results thereof are shown in Table 7.

TABLE 7

| | | | Maximum | Maximum |
|---|---|---|---|---|
| | | | emission | external quantum |
| | | | wavelength | efficiency |
| | Host | Dopant | (nm) | (EQE) (%) |
| Example 1 | H19 | 1 | 500 | 16.8 |
| Example 2 | H19 | 2 | 484 | 15.6 |
| Example 3 | H19 | 4 | 472 | 14.8 |
| Comparative | H19 | A | 444 | 4.2 |
| Example A | | | | |
| Comparative | H19 | B | 444 | 2.8 |
| Example B | | | | |

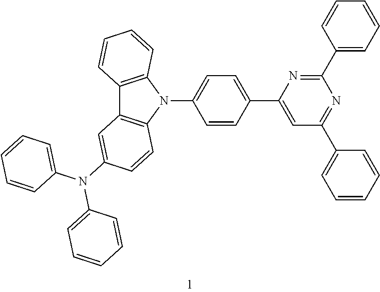 [SMILES: c1ccc(-c2cc(-c3ccc(-n4c5ccccc5c5cc(N(c6ccccc6)c6ccccc6)ccc54)cc3)nc(-c3ccccc3)n2)cc1]

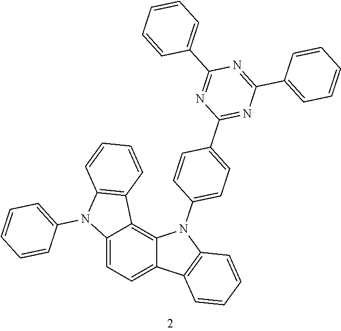 [SMILES: c1ccc(-c2nc(-c3ccccc3)nc(-c3ccc(-n4c5ccccc5c5ccc6c(c7ccccc7n6-c6ccccc6)c54)cc3)n2)cc1]

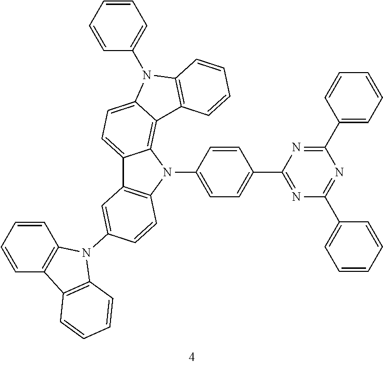 [SMILES: c1ccc(-c2nc(-c3ccccc3)nc(-c3ccc(-n4c5ccc(-n6c7ccccc7c7ccccc76)cc5c5ccc6c(c7ccccc7n6-c6ccccc6)c54)cc3)n2)cc1]

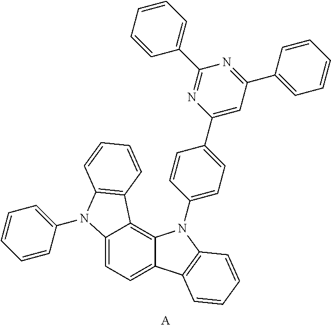

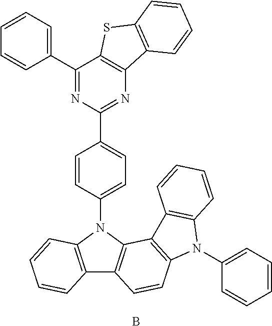

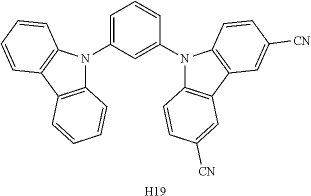 [SMILES: N#Cc1ccc2c(c1)c1cc(C#N)ccc1n2-c1cccc(-n2c3ccccc3c3ccccc32)c1 ; "H19"]

Referring to Table 7, it is determined that the organic light-emitting devices of Examples 1 to 3 have improved maximum external quantum efficiency, as compared with those of the organic light-emitting devices of Comparative Examples A and B.

According to one or more embodiments, since an organic light-emitting device including a TADF emitter satisfying Condition 1-1 or Condition 1-2 may have excellent delayed fluorescence characteristics, regardless of a type of a host used together in an emission layer, the organic light-emitting device including the TADF emitter may have excellent characteristics in terms of quantum efficiency and roll-off ratio.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the present disclosure as defined by the following claims.

What is claimed is:

1. An organic light-emitting device comprising:
a first electrode;
a second electrode facing the first electrode; and
an organic layer that is disposed between the first electrode and the second electrode, wherein the organic layer comprises an emission layer,
wherein the emission layer comprises a thermally activated delayed fluorescence (TADF) emitter and a host and the TADF emitter is different from the host,
the TADF emitter satisfies Condition 1-1 or Condition 1-2:
Condition 1-1
a condition that n1 is one, and
Condition 1-2
a condition that, when n1 is two or more, (I₁/I₂)×100(%) is less than 110%,
wherein, in Condition 1-1 and Condition 1-2,
I₁ (arbitrary units) is emission intensity at the shortest peak emission wavelength in a photoluminescence spectrum 1,
1) when n2 is one, I₂ (arbitrary units) is emission intensity at the same emission wavelength as the shortest peak emission wavelength of the photoluminescence spectrum 1 in the photoluminescence spectrum 2, and 2) when n2 is two or more, I₂ (arbitrary units) is emission intensity at the shortest peak emission wavelength in a photoluminescence spectrum 2,
the photoluminescence spectrum 1 is a photoluminescence spectrum of a film 1 that is doped with 15 percent by volume of the TADF emitter in a matrix with the host comprised in the emission layer and has a thickness of 50 nanometers, and
the photoluminescence spectrum 2 is a photoluminescence spectrum of a film 2 that is doped with 15 percent by volume of the TADF emitter in a matrix with DPEPO and has a thickness of 50 nanometers: 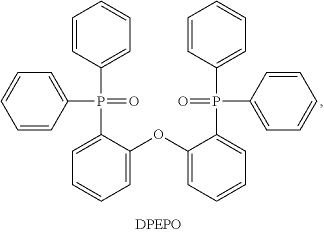
wherein n1 is the number of distinguishable emission peaks in the photoluminescence spectrum 1, and n2 is the number of distinguishable emission peaks in the photoluminescence spectrum 2.

2. The organic light-emitting device of claim 1, wherein
the TADF emitter is a compound represented by Formula 1:
R₁-(D₂)_{d1}-D₁-(L₁)ₐ₁-A₁, Formula 1
wherein, in Formula 1,
L₁ is selected from:
a single bond, a cyclopentane group, a cyclohexane group, a cycloheptane group, a cyclooctane group, a cyclopentene group, a cyclohexene group, a cycloheptene group, a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an isoindole group, an indole group, an indazole group, a purine group, a quinoline group, an isoquinoline group, a benzoquinoline group, a quinoxaline group, a quinazoline group, a cinnoline group, a phenanthroline group, a benzimidazole group, a benzofuran group, a benzothiophene group, a benzoxazole group, an isobenzoxazole group, a triazole group, a tetrazole group, an oxadiazole group, a triazine group, a dibenzofuran group, a dibenzothiophene group, a benzocarbazole group, a dibenzocarbazole group, an imidazopyridine group, an imidazopyrimidine group, an azaindole group, an azaindene group, an azabenzofuran group, an azabenzothiophene group, an azacarbazole group, an azafluorene group, an azadibenzofuran group, and an azadibenzothiophene group; and
a cyclopentane group, a cyclohexane group, a cycloheptane group, a cyclooctane group, a cyclopentene group, a cyclohexene group, a cycloheptene group, a benzene group, a naphthalene group, a fluorene group, a phenanthrene group, an anthracene group, a fluoranthene group, a triphenylene group, a pyrene group, a chrysene group, a pyrrole group, a thiophene group, a furan group, an imidazole group, a pyrazole group, a thiazole group, an isothiazole group, an oxazole group, an isoxazole group, a pyridine group, a pyrazine group, a pyrimidine group, a pyridazine group, an iso-indole group, an indole group, an indazole group, a purine group, a quinoline group, an isoquinoline group, a benzoquinoline group, a quinoxaline group, a quinazoline group, a cinnoline group, a phenanthroline group, a benzimidazole group, a benzofuran group, a benzothiophene group, a benzoxazole group, an isobenzoxazole group, a triazole group, a tetrazole group, an oxadiazole group, a triazine group, a dibenzofuran group, a dibenzothiophene group, a benzocarbazole group, a dibenzocarbazole group, an imidazopyridine group, an imidazopyrimidine group, an azaindole group, an azaindene group, an azabenzofuran group, an azabenzothiophene group, an azacarbazole group, an azafluorene group, an azadibenzofuran group, and an azadibenzothiophene group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a tri(C₁-C₂₀ alkyl)phenyl group, a (C₆-C₂₀ aryl)phenyl group, a di(C₆-C₂₀ aryl)phenyl group, a tri(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group,
a1 is an integer from 1 to 5,
D₁ and D₂ are each an electron donor group,
d1 is an integer from 0 to 5,
A₁ is an electron acceptor group, and
R₁ is selected from:
hydrogen, deuterium, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, and a π electron-depleted nitrogen-free C₂-C₆₀ heterocyclic group; and
a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, and a π electron-depleted nitrogen-free C₂-C₆₀ heterocyclic group, each substituted with at least one selected from deuterium, a C₁-C₆₀ alkyl group, a C₂-C₆₀ alkenyl group, a C₂-C₆₀ alkynyl group, a C₁-C₆₀ alkoxy group, a C₅-C₆₀ carbocyclic group, a (C₁-C₁₀ alkyl)C₅-C₆₀ carbocyclic group, a di(C₁-C₁₀ alkyl)C₅-C₆₀ carbocyclic group, a (phenyl)C₅-C₆₀ carbocyclic group, a di(phenyl)C₅-C₆₀ carbocyclic group, a (biphenyl)C₅-C₆₀ carbocyclic group, a di(biphenyl)C₅-C₆₀ carbocyclic group, a π electron-depleted nitrogen-free C₂-C₆₀ heterocyclic group, a (C₁-C₁₀ alkyl) π electron-depleted nitrogen-free C₂-C₆₀ heterocyclic group, a di(C₁-C₁₀ alkyl) π electron-depleted nitrogen-free C₂-C₆₀ heterocyclic group, a (phenyl) π electron-depleted nitrogen-free C₂-C₆₀ heterocyclic group, a di(phenyl) π electron-depleted nitrogen-free C₂-C₆₀ heterocyclic group, a (biphenyl) π electron-depleted nitrogen-free C₂-C₆₀ heterocyclic group, and a di(biphenyl) π electron-depleted nitrogen-free C₂-C₆₀ heterocyclic group,
provided that,
i) d1 is an integer from 1 to 5; or
ii) when d1 is zero, A₁ is selected from groups represented by Formulae 3-6(1), 3-10(8), and 3-12(24): 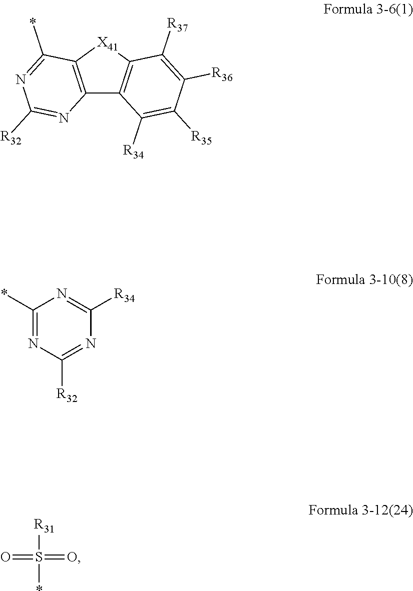
wherein, in Formulae 3-6(1), 3-10(8), and 3-12(24),
X₄₁ is N(R₄₁), C(R₄₂)(R₄₃), O, or S,
R₃₁, R₃₂, R₃₄, to R₃₇ and R₄₁ to R₄₃ are each independently selected from hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a tri(C₁-C₂₀ alkyl)phenyl group, a (C₆-C₂₀ aryl)phenyl group, a di(C₆-C₂₀ aryl)phenyl group, a tri(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
* indicates a binding site to a neighboring atom.

3. The organic light-emitting device of claim 2, wherein
the TADF emitter satisfies Condition 2-1, when assuming that rotamer (0°) is a molecular structure that the TADF emitter has in a gas-phase isolated molecular state, a constant α is an angle between a first plane including D₁ and a second plane including A₁ in the rotamer (0°), rotamer (10x°) is a molecular structure that the TADF emitter has in a state in which the angle between the first plane and the second plane is changed to α+10x°, and x is an integer satisfying −18≤x≤18:
Condition 2-1
a condition that attachment-detachment overlap densities of the rotamer (10x°) are all less than 0.65.

4. The organic light-emitting device of claim 2, wherein
the TADF emitter satisfies Condition 2-2, when assuming that rotamer (0°) is a molecular structure that the TADF emitter has in a gas-phase isolated molecular state, a constant α is an angle between a first plane including D₁ and a second plane including A₁ in the rotamer (0°), rotamer (10x°) is a molecular structure that the TADF emitter has in a state in which the angle between the first plane and the second plane is changed to α+10x°, and x is an integer satisfying −18≤x≤18:
Condition 2-2
a condition that at least one 10x, of which an attachment-detachment overlap density of the rotamer (10x°) is 0.65 or more, is present, and rotamer (10x°) for all values 10x, of which an attachment-detachment overlap density of rotamer (10x°) is 0.65 or more, have i) rotational conformational energy of 0.15 electron volts or more, ii) CTosc greater than LEosc, or iii) rotational conformational energy of 0.15 electron volts or more and CTosc greater than LEosc,
wherein, in Condition 2-2, LEosc is oscillator strength in a locally excited state of the corresponding rotamer (10x°), and CTosc is oscillator strength in a charge transfer state of the corresponding rotamer (10x°).

5. The organic light-emitting device of claim 2, wherein
L₁ is selected from:
a single bond, a benzene group, a naphthalene group, a fluorene group, a pyridine group, a pyrazine group, a pyrimidine group, a pyridazine group, a quinoline group, an isoquinoline group, a benzoquinoline group, a quinoxaline group, a quinazoline group, and a triazine group; and
a benzene group, a naphthalene group, a fluorene group, a pyridine group, a pyrazine group, a pyrimidine group, a pyridazine group, a quinoline group, an isoquinoline group, a benzoquinoline group, a quinoxaline group, a quinazoline group, and a triazine group, each substituted with at least one selected from deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a (C₆-C₂₀ aryl)phenyl group, a di(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
a1 is 1 or 2.

6. The organic light-emitting device of claim 2, wherein
D₁ and D₂ are each independently selected from groups represented by Formulae 11-1 to 11-4: 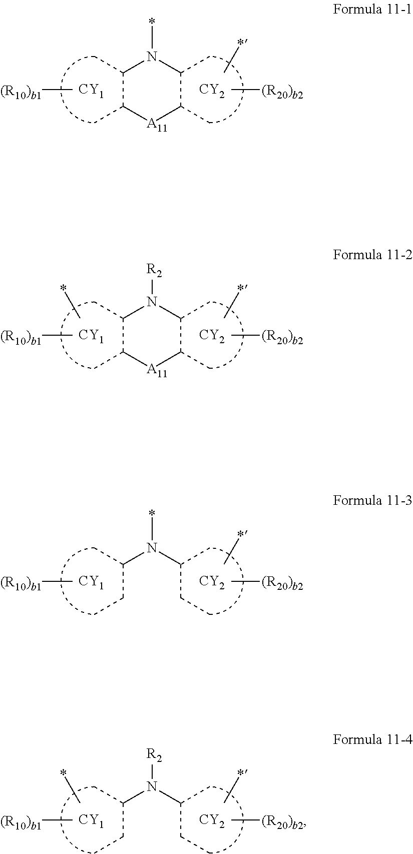
wherein, in Formulae 11-1 to 11-4,
CY₁ and CY₂ are each independently a C₅-C₆₀ carbocyclic group or a C₂-C₆₀ heterocyclic group,
A₁₁ is selected from:
a single bond, a C₁-C₄ alkylene group, and a C₂-C₄ alkenylene group; and
a C₁-C₄ alkylene group and a C₂-C₄ alkenylene group, each substituted with at least one selected from deuterium, a cyano group, a C₁-C₆₀ alkyl group, a C₁-C₆₀ alkoxy group, a phenyl group, a fluorenyl group, a carbazolyl group, a dibenzofuranyl group, and a dibenzothiophenyl group,
R₂, R₁₀, and R₂₀ are each independently selected from:
hydrogen, deuterium, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a furanyl group, a thiophenyl group, an indolyl group, a benzofuranyl group, a benzothiophenyl group, a carbazolyl group, a dibenzofuranyl group, a dibenzothiophenyl group, a benzocarbazolyl group, a naphthobenzofuranyl group, a naphthobenzothiophenyl group, a dibenzocarbazolyl group, a dinaphthofuranyl group, a dinaphthothiophenyl group, an indolocarbazolyl group, an indolodibenzofuranyl group, and an indolodibenzothiophenyl group; and
a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, a heptalenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coronenyl group, an ovalenyl group, a pyrrolyl group, a furanyl group, a thiophenyl group, an indolyl group, a benzofuranyl group, a benzothiophenyl group, a carbazolyl group, a dibenzofuranyl group, a dibenzothiophenyl group, a benzocarbazolyl group, a naphthobenzofuranyl group, a naphthobenzothiophenyl group, a dibenzocarbazolyl group, a dinaphthofuranyl group, a dinaphthothiophenyl group, an indolocarbazolyl group, an indolodibenzofuranyl group, and an indolodibenzothiophenyl group, each substituted with at least one selected from deuterium, a C₁-C₂₀ alkyl group, a C₁-C₂₀ alkoxy group, a phenyl group, a biphenyl group, a terphenyl group, a naphthyl group, a fluorenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group,
b1 and b2 are each independently an integer from 0 to 3, and
* and *′ each indicate a binding site to a neighboring atom.

7. The organic light-emitting device of claim 6, wherein
D₁ and D₂ are each independently selected from groups represented by Formulae 11(1) to 11(19): 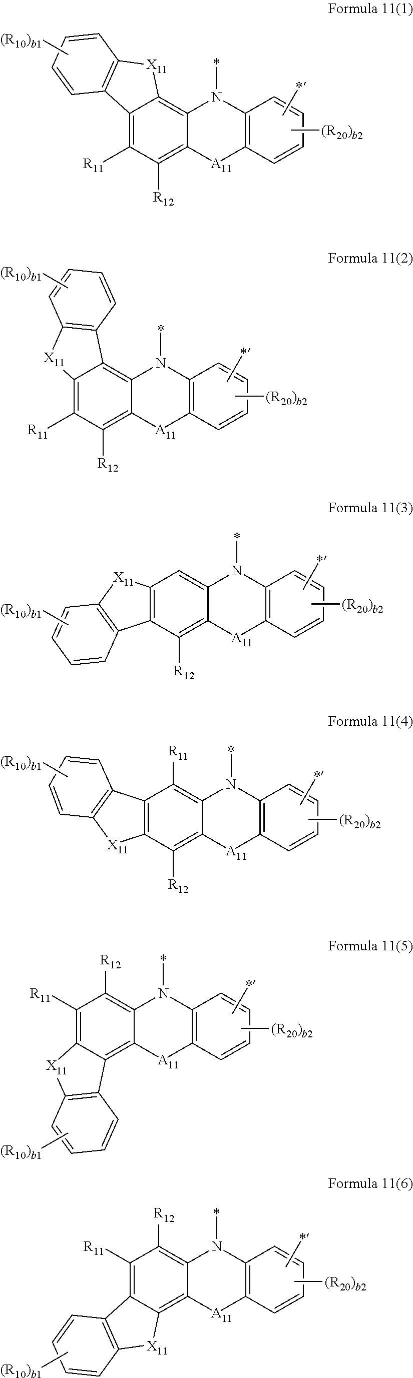 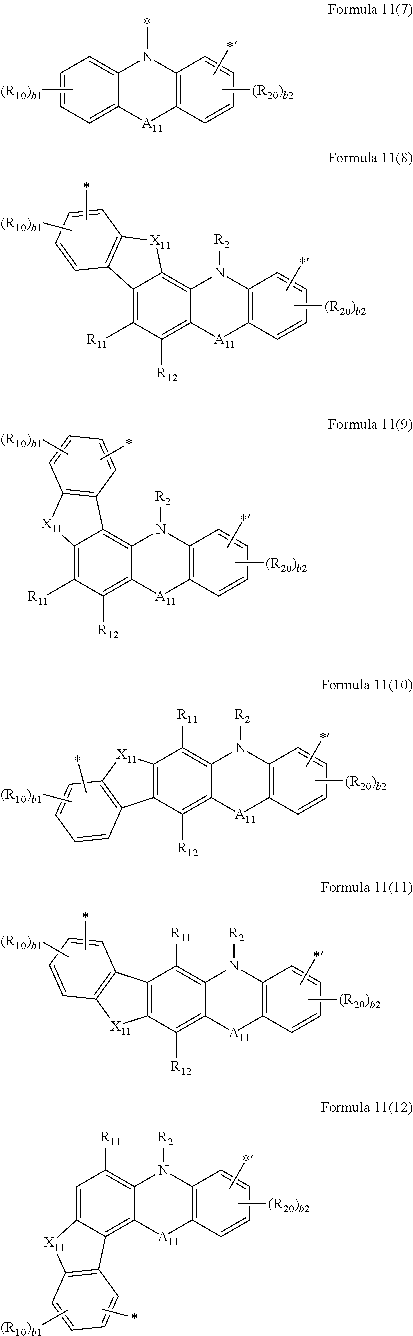 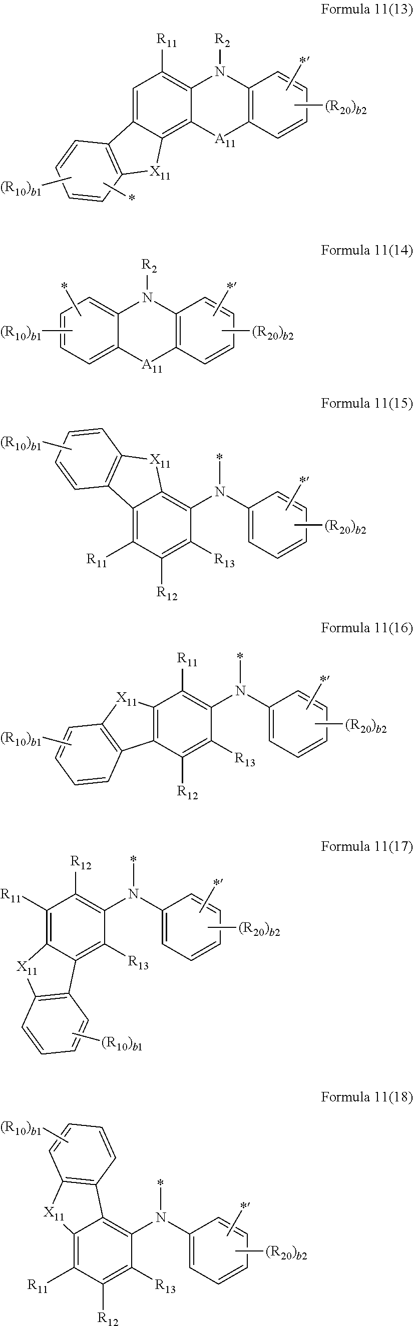 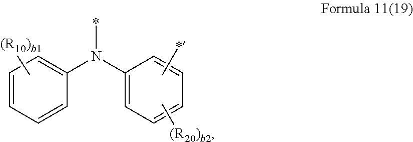
wherein, in Formulae 11(1) to 11(19),
X₁₁ is O, S, C(R₁₄), or N(R₁₅)(R₁₆),
A₁₁, R₂, R₁₀, R₂₀, b1, and b2 are each independently the same as described in claim 6,
R₁₁ to R₁₆ are each independently the same as described in connection with R₁₀, and
* and *′ each indicate a binding site to a neighboring atom.

8. The organic light-emitting device of claim 7, wherein
R₁₀ to R₁₆ and R₂₀ are each independently selected from hydrogen, deuterium, a cyano group, a C₁-C₂₀ alkyl group, a C₁-C₂₀ alkoxy group, a phenyl group, a biphenyl group, a terphenyl group, a naphthyl group, a fluorenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group.

9. The organic light-emitting device of claim 2, wherein
d1 is 1.

10. The organic light-emitting device of claim 2, wherein
A₁ is selected from a substituted or unsubstituted π electron-depleted nitrogen-containing C₂-C₆₀ heterocyclic group and a sulphonyl-containing group.

11. The organic light-emitting device of claim 2, wherein
A₁ is selected from groups represented by Formulae 3-1 to 3-14 and a sulphonyl-containing group: 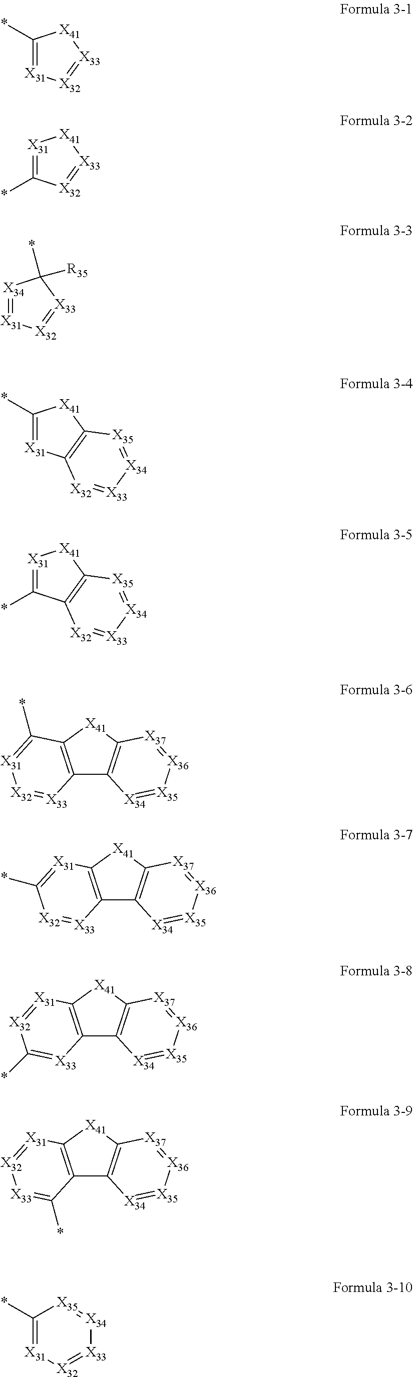 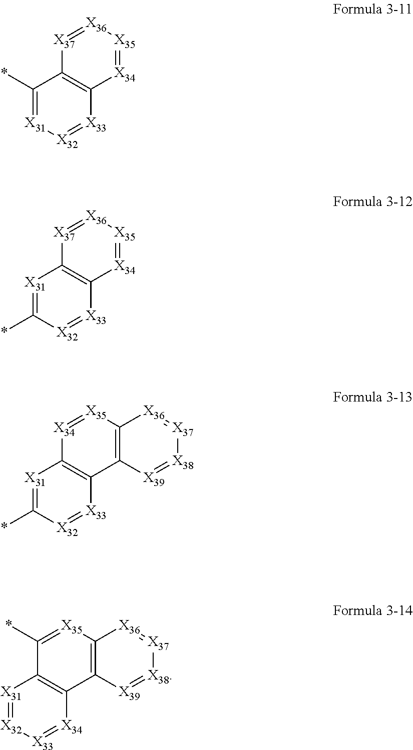
wherein, in Formula 3-1 to 3-14, X₃₁ is N or C(R₃₁), X₃₂ is N or C(R₃₂), X₃₃ is N or C(R₃₃), X₃₄ is N or C(R₃₄), X₃₅ is N or C(R₃₅), X₃₆ is N or C(R₃₆), X₃₇ is N or C(R₃₇), X₃₈ is N or C(R₃₈), and X₃₉ is N or C(R₃₉),
X₄₁ in Formulae 3-1, 3-2, and 3-4 to 3-9 is N(R₄₁), C(R₄₂)(R₄₃), O, or S,
at least one of X₃₁ to X₃₃ in Formulae 3-1 and 3-2 is N, at least one of X₃₁ to X₃₄ in Formula 3-3 is N, at least one of X₃₁ to X₃₅ in Formulae 3-4, 3-5, and 3-10 is N, at least one of X₃₁ to X₃₇ in Formulae 3-6 to 3-9, 3-11, and 3-12 is N, and at least one of X₃₁ to X₃₉ in Formulae 3-13 and 3-14 is N,
R₃₁ to R₃₉ and R₄₁ to R₄₃ are each independently selected from hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a C₁-C₂₀ alkoxy group, a phenyl group, a (C₁-C₂₀ alkyl)phenyl group, a di(C₁-C₂₀ alkyl)phenyl group, a tri(C₁-C₂₀ alkyl)phenyl group, a (C₆-C₂₀ aryl)phenyl group, a di(C₆-C₂₀ aryl)phenyl group, a tri(C₆-C₂₀ aryl)phenyl group, a (C₃-C₂₀ heteroaryl)phenyl group, a di(C₃-C₂₀ heteroaryl)phenyl group, a pyridinyl group, a (C₁-C₂₀ alkyl)pyridinyl group, a di(C₁-C₂₀ alkyl)pyridinyl group, a (C₆-C₂₀ aryl)pyridinyl group, a di(C₆-C₂₀ aryl)pyridinyl group, a (C₃-C₂₀ heteroaryl)pyridinyl group, a di(C₃-C₂₀ heteroaryl)pyridinyl group, a pyrimidinyl group, a (C₁-C₂₀ alkyl)pyrimidinyl group, a di(C₁-C₂₀ alkyl)pyrimidinyl group, a (C₆-C₂₀ aryl)pyrimidinyl group, a di(C₆-C₂₀ aryl)pyrimidinyl group, a (C₃-C₂₀ heteroaryl)pyrimidinyl group, a di(C₃-C₂₀ heteroaryl)pyrimidinyl group, a triazinyl group, a (C₁-C₂₀ alkyl)triazinyl group, a di(C₁-C₂₀ alkyl)triazinyl group, a (C₆-C₂₀ aryl)triazinyl group, a di(C₆-C₂₀ aryl)triazinyl group, a (C₃-C₂₀ heteroaryl)triazinyl group, and a di(C₃-C₂₀ heteroaryl)triazinyl group, and
* indicates a binding site to a neighboring atom.

12. The organic light-emitting device of claim 2, wherein
A₁ is selected from groups represented by Formulae 3-4(1) to 3-4(4), 3-5(1) to 3-5(4), 3-6(1), 3-7(1), 3-8(1), 3-9(1), 3-10(1) to 3-10(8), 3-11(1) to 3-11(23), and 3-12(1) to 3-12(24): 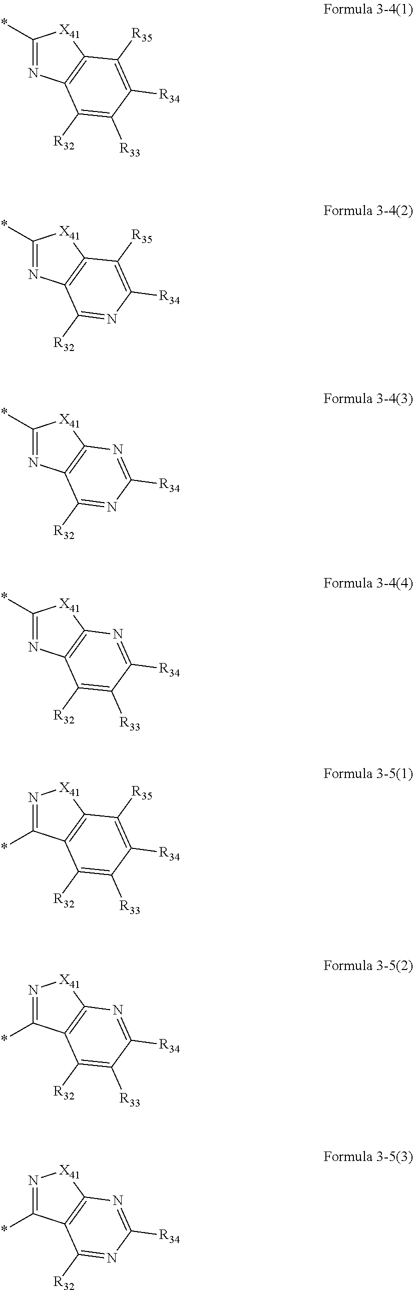 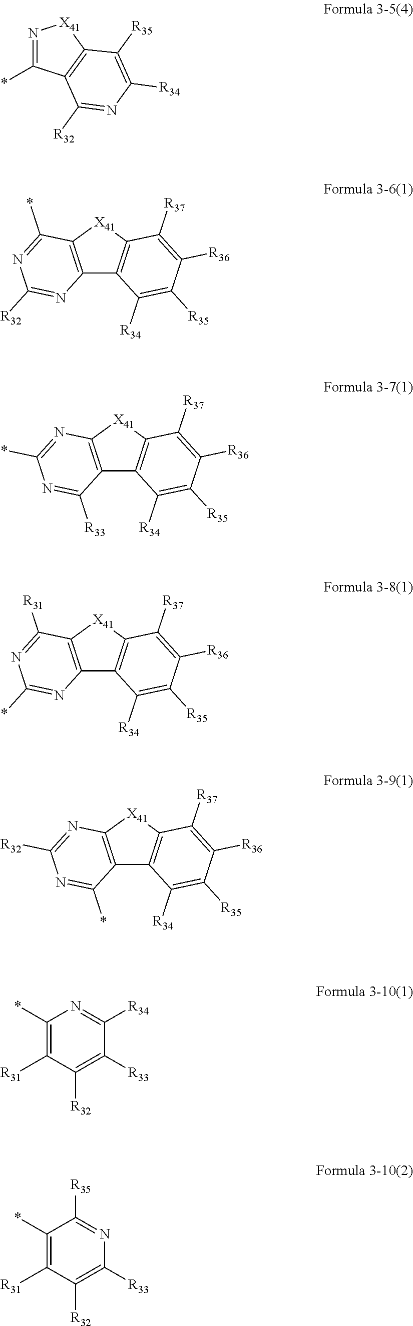 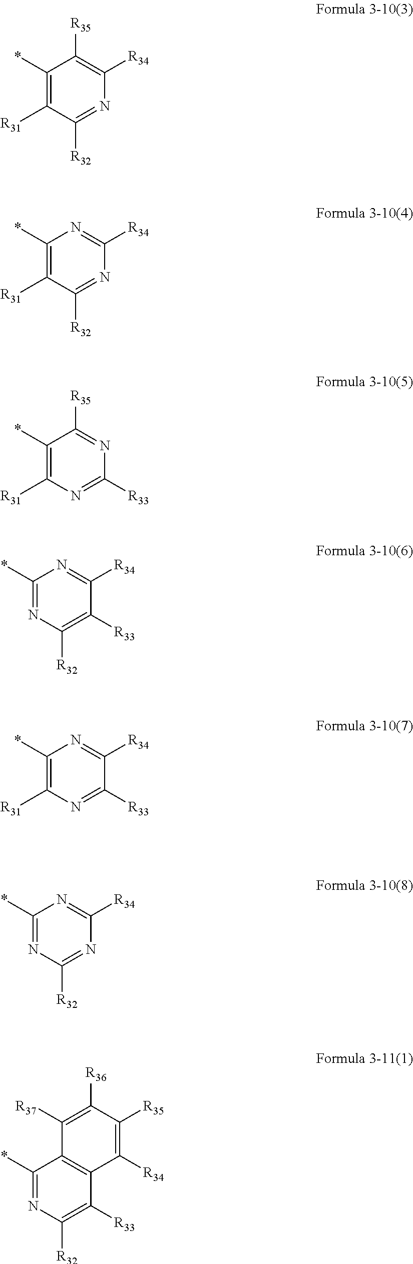 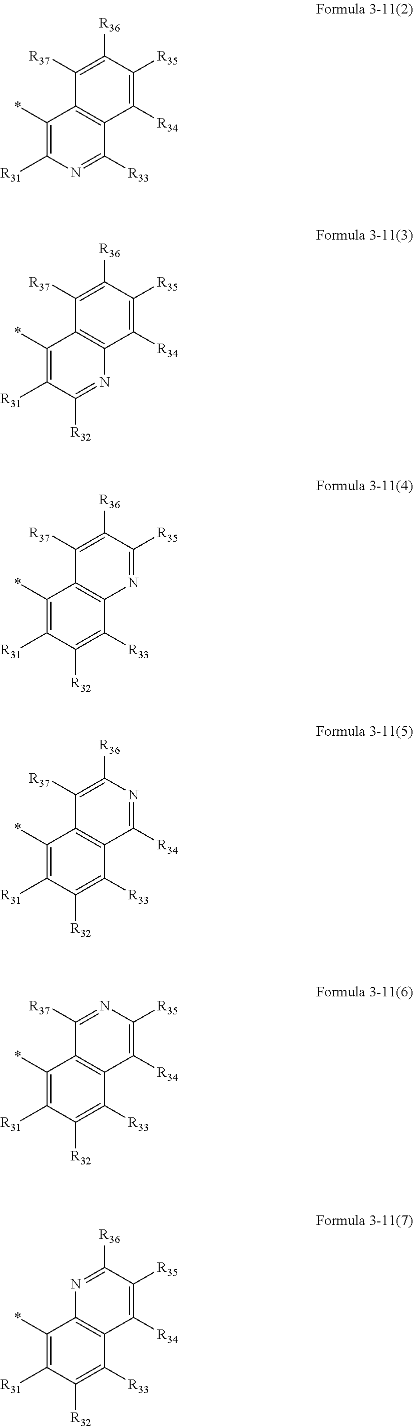 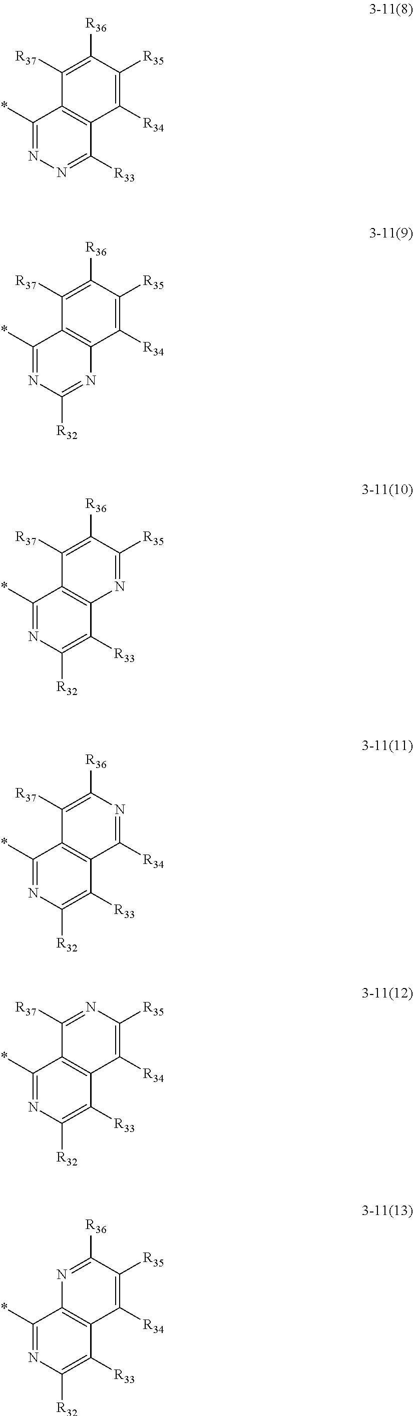 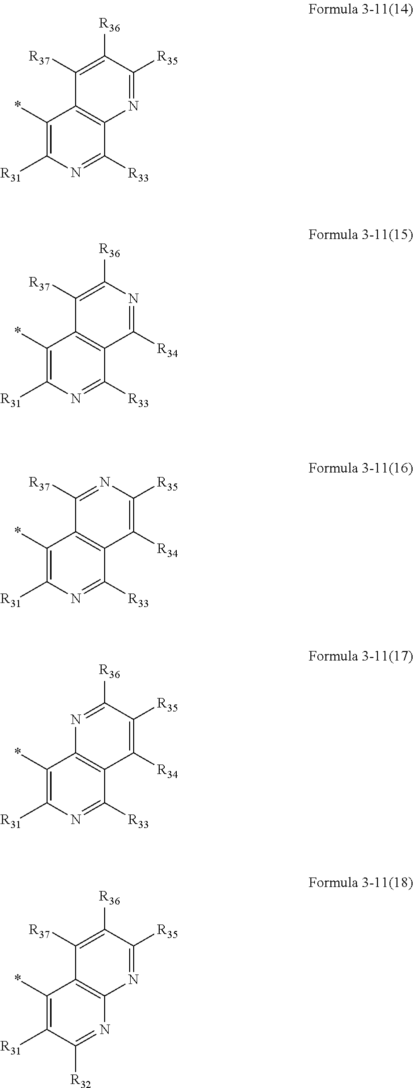 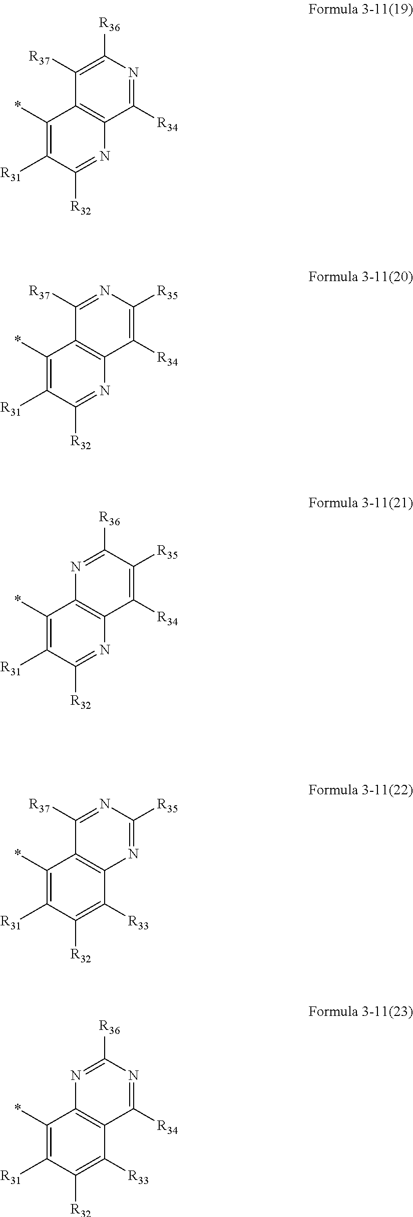 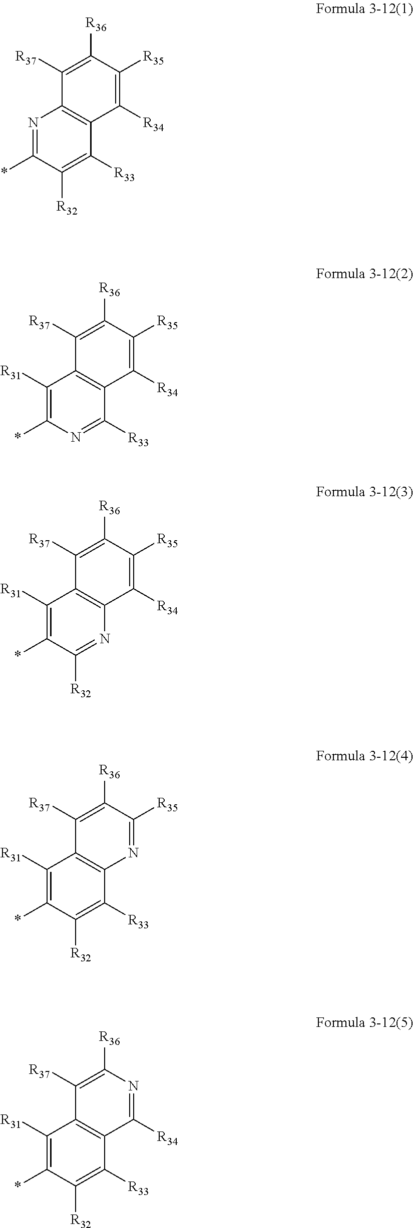 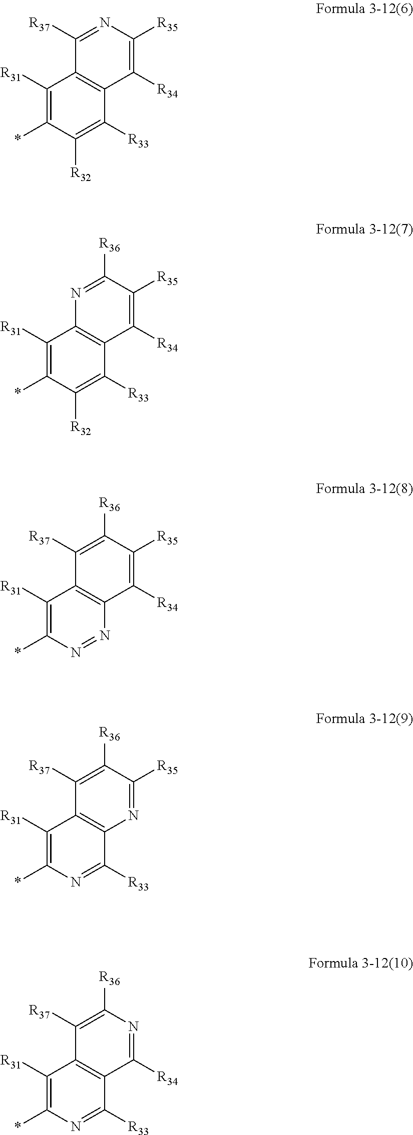 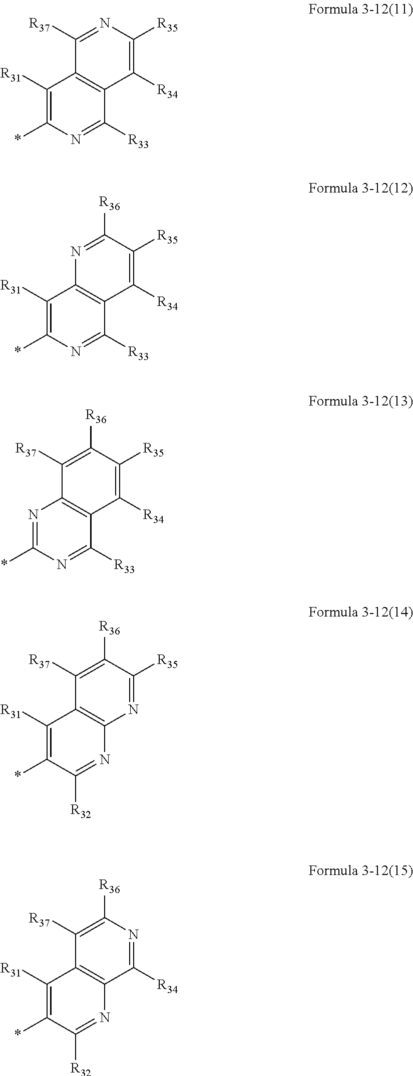 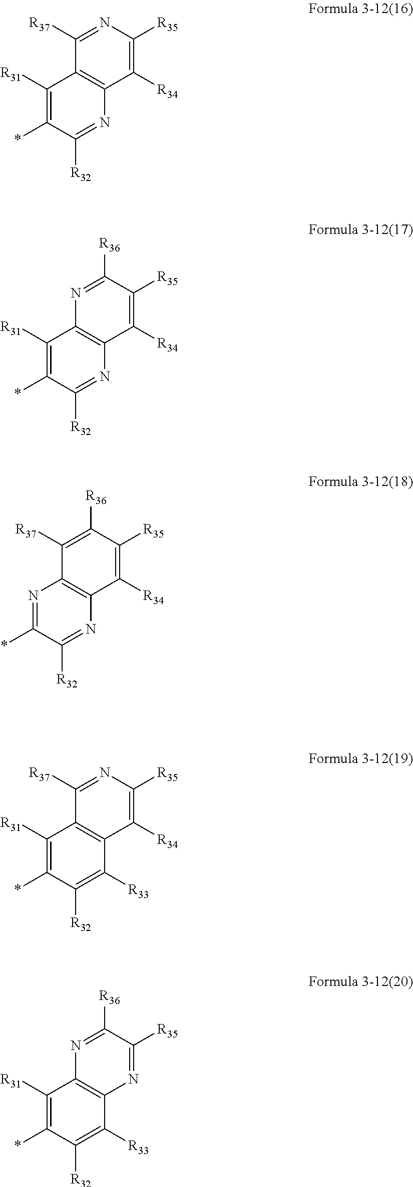 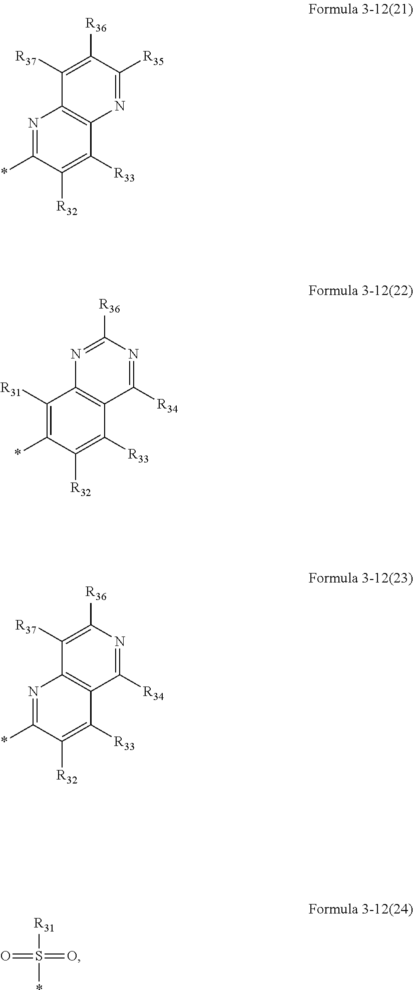
wherein, in Formulae 3-4(1) to 3-4(4), 3-5(1) to 3-5(4), 3-6(1), 3-7(1), 3-8(1), 3-9(1), 3-10(1) to 3-10(8), 3-11(1) to 3-11(23), and 3-12(1) to 3-12(24),
X₄₁ is N(R₄₁), C(R₄₂)(R₄₃), O, or S,
R₃₁ to R₃₇ and R₄₁ to R₄₃ are each independently selected from hydrogen, deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, a C₁-C₁₀ alkoxy group, a phenyl group, a (C₁-C₁₀ alkyl)phenyl group, a di(C₁-C₁₀ alkyl)phenyl group, a tri(C₁-C₁₀ alkyl)phenyl group, a biphenyl group, a di(phenyl)phenyl group, a tri(phenyl)phenyl group, a (pyridinyl)phenyl group, a di(pyridinyl)phenyl group, (pyrimidinyl)phenyl group, a di(pyrimidinyl)phenyl group, a (triazinyl)phenyl group, a di(triazinyl)phenyl group, a (carbazolyl)phenyl group, a pyridinyl group, a (C₁-C₁₀ alkyl)pyridinyl group, a di(C₁-C₁₀ alkyl)pyridinyl group, a (phenyl)pyridinyl group, a di(phenyl)pyridinyl group, a (pyridinyl)pyridinyl group, a di(pyridinyl)pyridinyl group, a (pyrimidinyl)pyridinyl group, a di(pyrimidinyl)pyridinyl group, a (triazinyl)pyridinyl group, a di(triazinyl)pyridinyl group, a triazinyl group, a (C₁-C₁₀ alkyl)triazinyl group, a di(C₁-C₁₀ alkyl)triazinyl group, a (phenyl)triazinyl group, a di(phenyl)triazinyl group, (pyridinyl)triazinyl group, a di(pyridinyl)triazinyl group, a (pyrimidinyl)triazinyl group, a di(pyrimidinyl)triazinyl group, a (triazinyl)triazinyl group, and a di(triazinyl)triazinyl group, and
* indicates a binding site to a neighboring atom.

13. The organic light-emitting device of claim 12, wherein
A₁ is selected from Formulae 3-6(1), 3-10(4), 3-10(8), and 3-12(24).

14. The organic light-emitting device of claim 2, wherein
A₁ is a triazine-containing group or a sulphonyl-containing group.

15. The organic light-emitting device of claim 2, wherein
R₁ is selected from hydrogen, deuterium, a cyano group, a C₁-C₂₀ alkyl group, a C₁-C₂₀ alkoxy group, a phenyl group, a biphenyl group, a terphenyl group, a naphthyl group, a fluorenyl group, a dimethylfluorenyl group, a diphenylfluorenyl group, a carbazolyl group, a phenylcarbazolyl group, a biphenylcarbazolyl group, a dibenzofuranyl group, and a dibenzothiophenyl group.

16. The organic light-emitting device of claim 1, wherein
the TADF emitter is selected from Compounds 1 to 11:

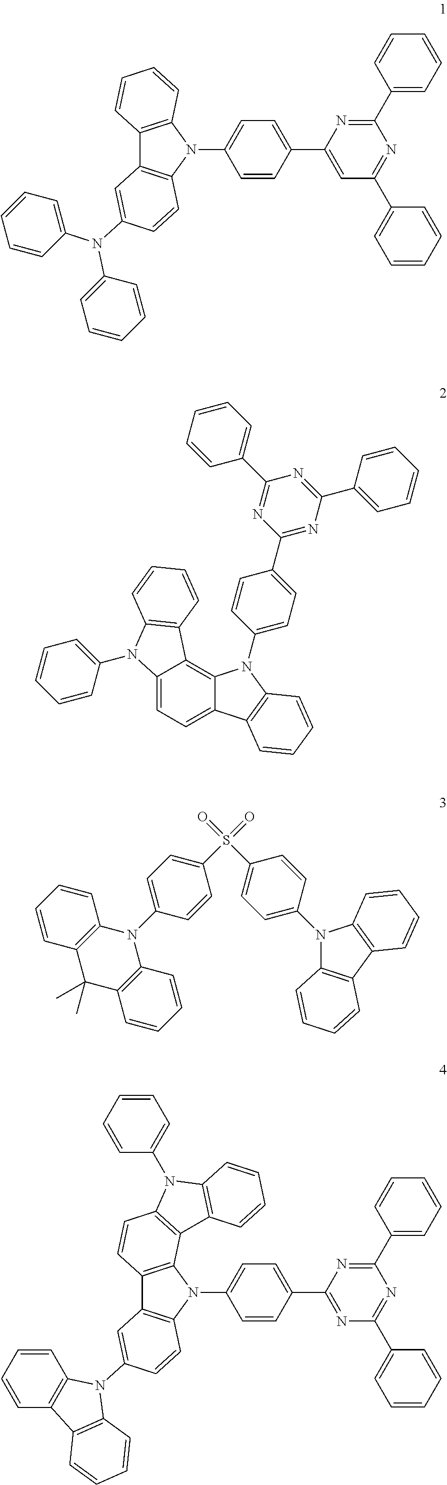 [SMILES: c1ccc(-c2cc(-c3ccc(-n4c5ccccc5c5cc(N(c6ccccc6)c6ccccc6)ccc54)cc3)nc(-c3ccccc3)n2)cc1 ; c1ccc(-c2nc(-c3ccccc3)nc(-c3ccc(-n4c5ccccc5c5ccc6c(c7ccccc7n6-c6ccccc6)c54)cc3)n2)cc1 ; CC1(C)c2ccccc2N(c2ccc(S(=O)(=O)c3ccc(-n4c5ccccc5c5ccccc54)cc3)cc2)c2ccccc21 ; c1ccc(-c2nc(-c3ccccc3)nc(-c3ccc(-n4c5ccc(-n6c7ccccc7c7ccccc76)cc5c5ccc6c(c7ccccc7n6-c6ccccc6)c54)cc3)n2)cc1]

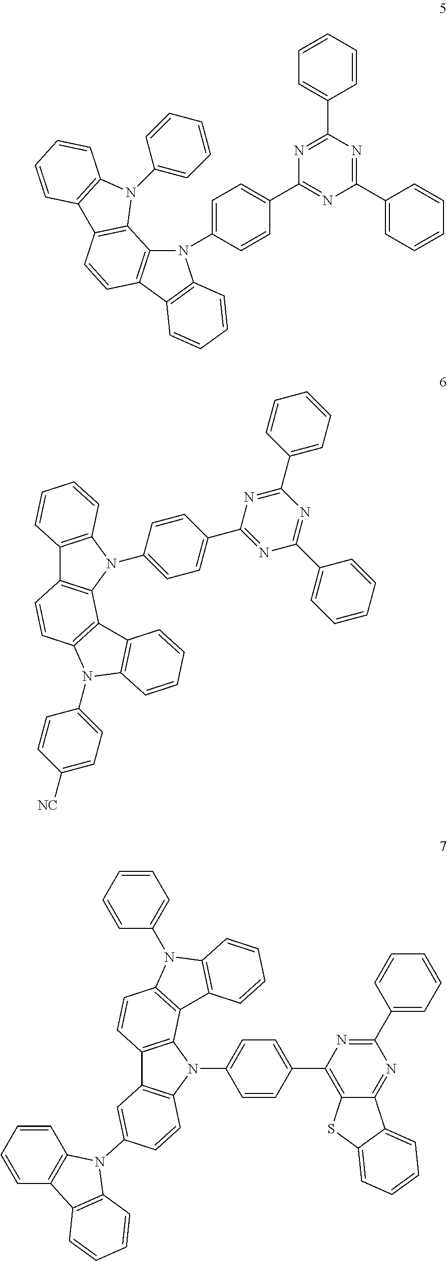 [SMILES: c1ccc(-c2nc(-c3ccccc3)nc(-c3ccc(-n4c5ccccc5c5ccc6c7ccccc7n(-c7ccccc7)c6c54)cc3)n2)cc1 ; N#Cc1ccc(-n2c3ccccc3c3c2ccc2c4ccccc4n(-c4ccc(-c5nc(-c6ccccc6)nc(-c6ccccc6)n5)cc4)c23)cc1 ; c1ccc(-c2nc(-c3ccc(-n4c5ccc(-n6c7ccccc7c7ccccc76)cc5c5ccc6c(c7ccccc7n6-c6ccccc6)c54)cc3)c3sc4ccccc4c3n2)cc1]

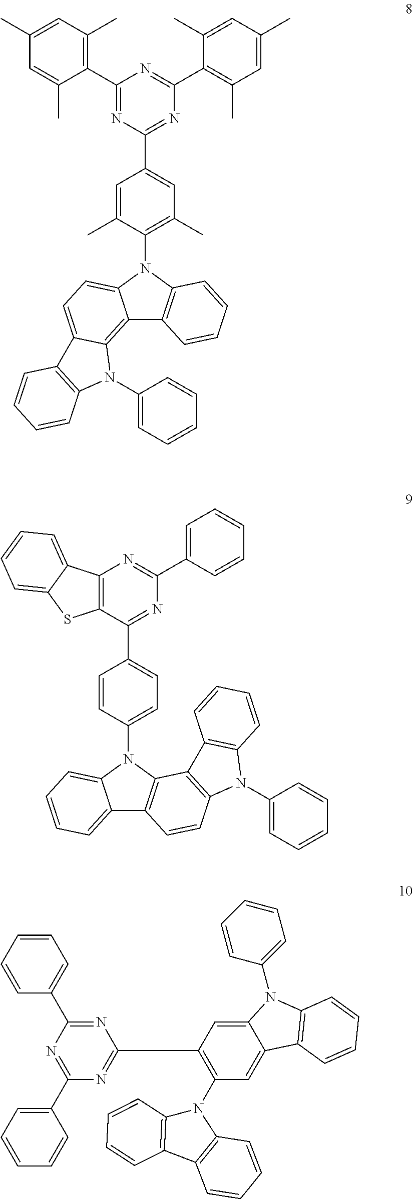

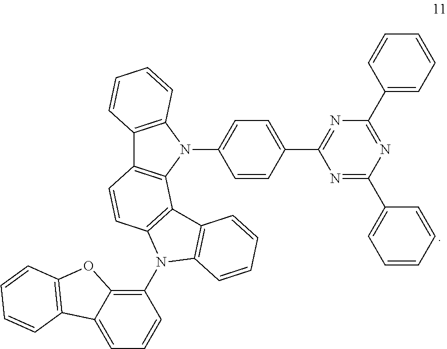 [SMILES: c1ccc(-c2nc(-c3ccccc3)nc(-c3ccc(-n4c5ccccc5c5ccc6c(c7ccccc7n6-c6cccc7c6oc6ccccc67)c54)cc3)n2)cc1]

17. The organic light-emitting device of claim 1, wherein
the host comprises at least one compound selected from a fluorene-containing compound, a carbazole-containing compound, a dibenzofuran-containing compound, a dibenzothiophene-containing compound, an indenocarbazole-containing compound, an indolocarbazole-containing compound, a benzofurocarbazole-containing compound, a benzothienocarbazole-containing compound, an acridine-containing compound, a dihydroacridine-containing compound, a triindolobenzene-containing compound, a pyridine-containing compound, a pyrimidine-containing compound, a triazine-containing compound, a silicon-containing compound, a cyano group-containing compound, a phosphine oxide-containing compound, a sulfoxide-containing compound, and a sulphonyl-containing compound.

18. The organic light-emitting device of claim 1, wherein
the host is a compound comprising at least one carbazole ring and at least one cyano group or a phosphine oxide-containing compound.

19. The organic light-emitting device of claim 1, wherein
the host comprises at least one compound selected from Compounds H1 to H24:

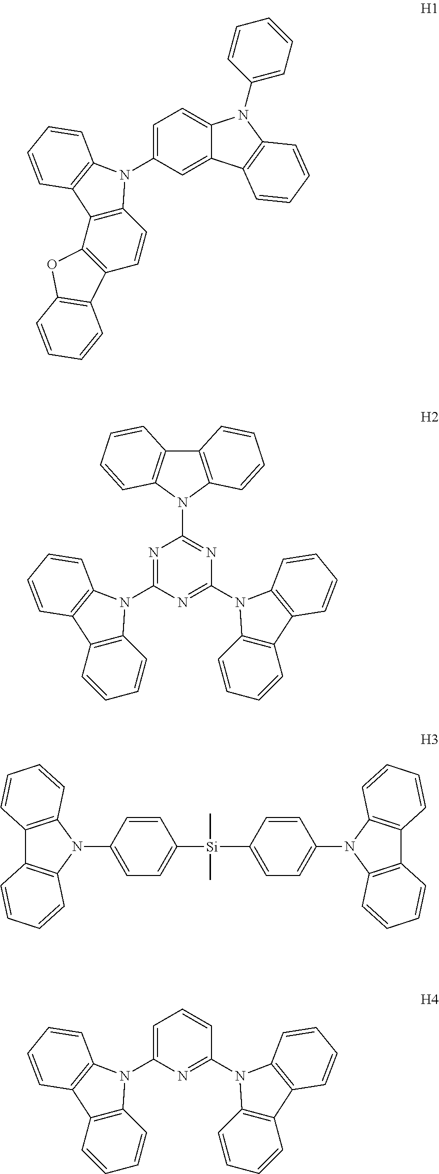 [SMILES: c1ccc(-n2c3ccccc3c3cc(-n4c5ccccc5c5c6oc7ccccc7c6ccc54)ccc32)cc1 ; c1ccc2c(c1)c1ccccc1n2-c1nc(-n2c3ccccc3c3ccccc32)nc(-n2c3ccccc3c3ccccc32)n1 ; C[Si](C)(c1ccc(-n2c3ccccc3c3ccccc32)cc1)c1ccc(-n2c3ccccc3c3ccccc32)cc1 ; c1cc(-n2c3ccccc3c3ccccc32)nc(-n2c3ccccc3c3ccccc32)c1]

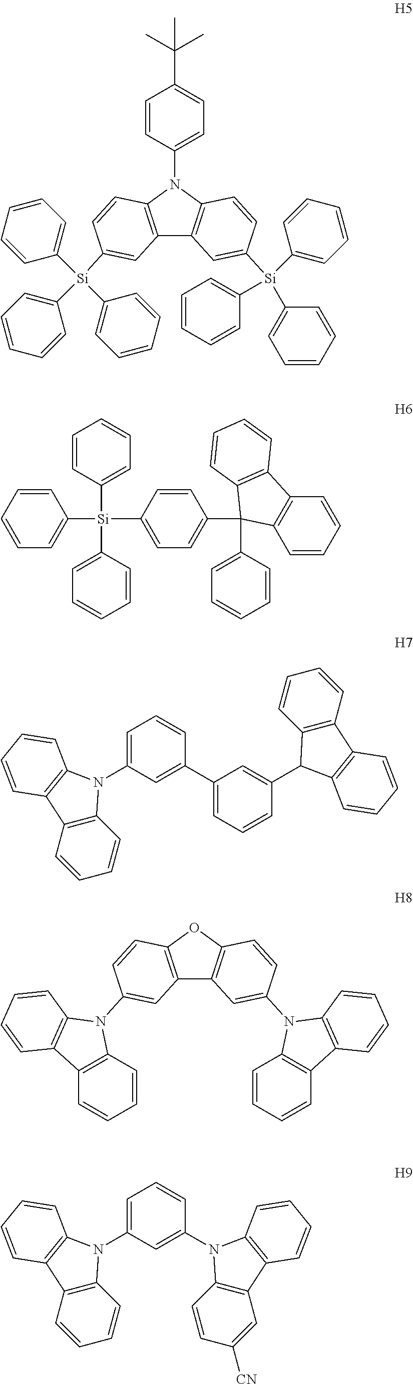 [SMILES: CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; c1ccc(C2(c3ccc([Si](c4ccccc4)(c4ccccc4)c4ccccc4)cc3)c3ccccc3-c3ccccc32)cc1 ; c1cc(-c2cccc(-n3c4ccccc4c4ccccc43)c2)cc(C2c3ccccc3-c3ccccc32)c1 ; c1ccc2c(c1)c1ccccc1n2-c1ccc2oc3ccc(-n4c5ccccc5c5ccccc54)cc3c2c1 ; N#Cc1ccc2c(c1)c1ccccc1n2-c1cccc(-n2c3ccccc3c3ccccc32)c1]

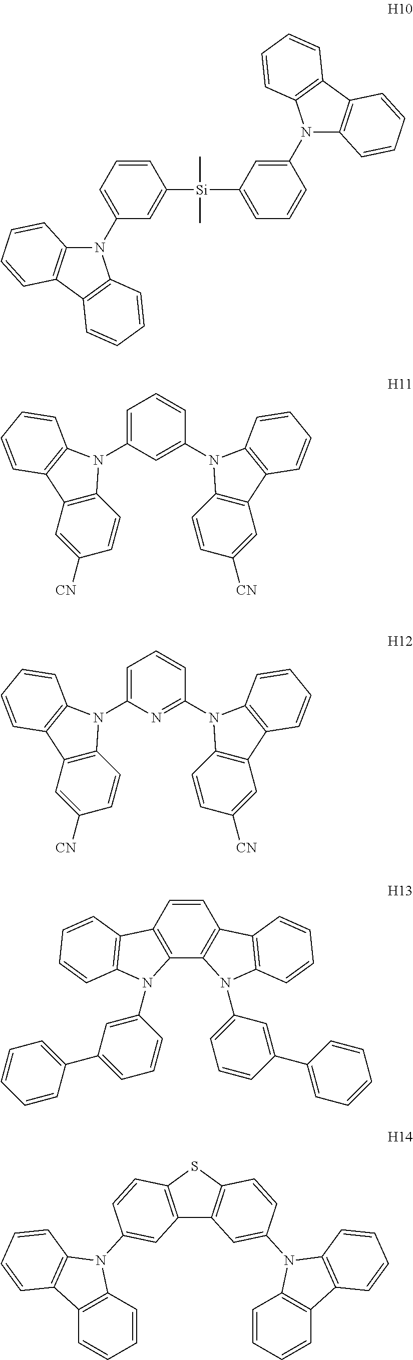

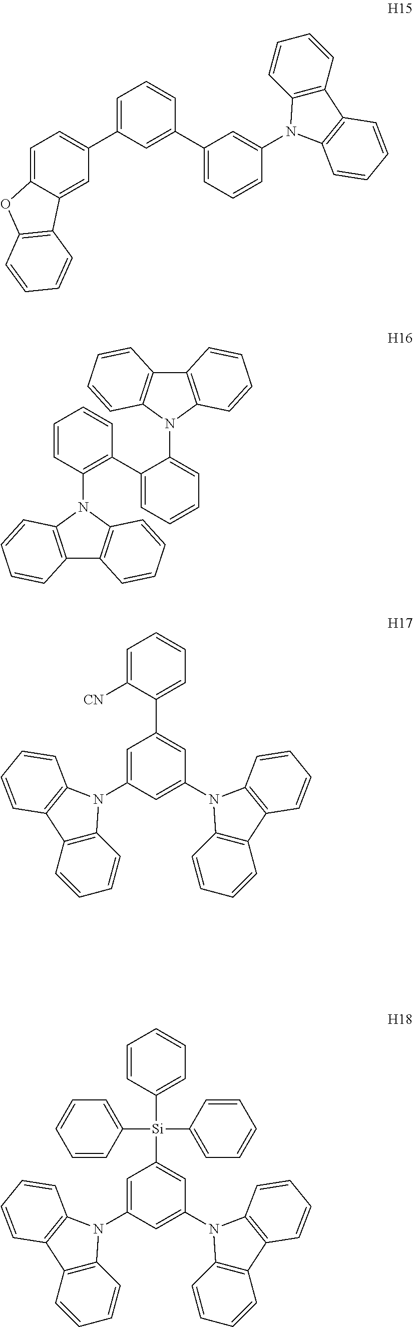

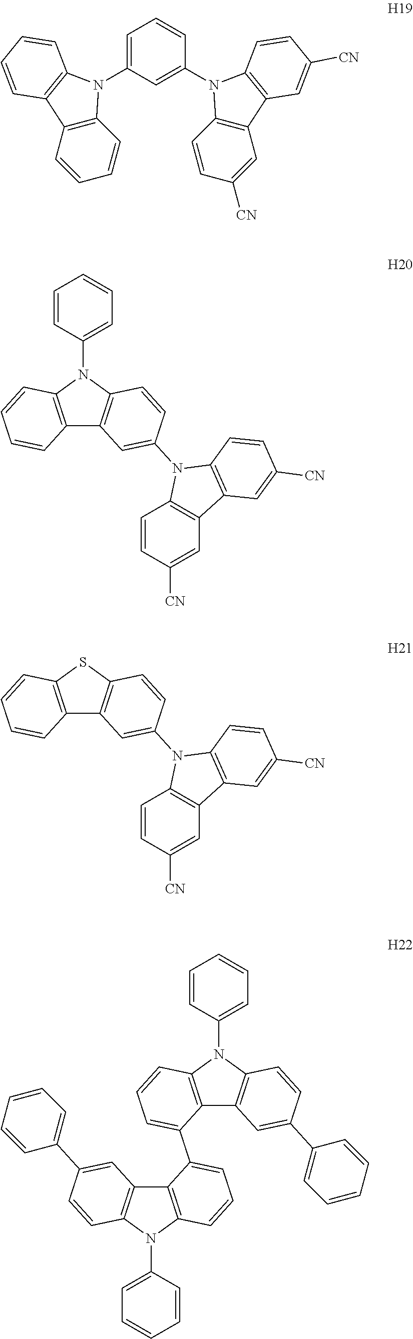 [SMILES: N#Cc1ccc2c(c1)c1cc(C#N)ccc1n2-c1cccc(-n2c3ccccc3c3ccccc32)c1 ; N#Cc1ccc2c(c1)c1cc(C#N)ccc1n2-c1ccc2c(c1)c1ccccc1n2-c1ccccc1 ; N#Cc1ccc2c(c1)c1cc(C#N)ccc1n2-c1ccc2sc3ccccc3c2c1 ; c1ccc(-c2ccc3c(c2)c2c(-c4cccc5c4c4cc(-c6ccccc6)ccc4n5-c4ccccc4)cccc2n3-c2ccccc2)cc1]

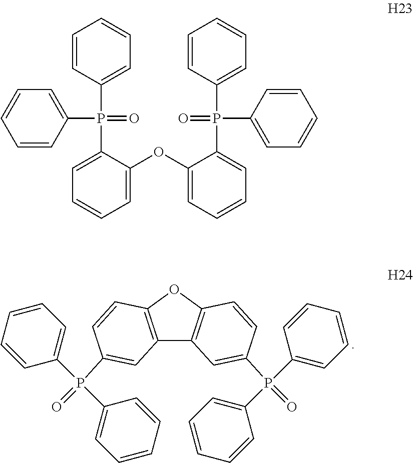 [SMILES: O=P(c1ccccc1)(c1ccccc1)c1ccccc1Oc1ccccc1P(=O)(c1ccccc1)c1ccccc1 ; O=P(c1ccccc1)(c1ccccc1)c1ccc2oc3ccc(P(=O)(c4ccccc4)c4ccccc4)cc3c2c1]

20. The organic light-emitting device of claim 1, wherein
a ratio of a delayed fluorescence component emitted from the TADF emitter with respect to a total emission component of the emission layer is 30% or more.

21. The organic light-emitting device of claim 1, wherein
an amount of the TADF emitter is smaller than an amount of the host.

22. The organic light-emitting device of claim 1, wherein
an amount of the TADF emitter in the emission layer is selected within a range of about 0.01 parts by weight to about 20 parts by weight based on 100 parts by weight of the emission layer.
